(19) United States
(12) Patent Application Publication
(10) Pub. No.: US 2026/0190522 A1
(43) Pub. Date: Jul. 2, 2026

(54) IMAGE-CAPTURING APPARATUS

(71) Applicant: SONY SEMICONDUCTOR SOLUTIONS CORPORATION, KANAGAWA (JP)

(72) Inventors: KAZUHIRO YONEDA, KANAGAWA (JP); AKIRA DAICHO, KANAGAWA (JP); HIROSHI FUKUNAGA, KANAGAWA (JP); YUTA NAKAMOTO, KANAGAWA (JP); JUNICHI MATSUO, KANAGAWA (JP); KYOSUKE ITO, KANAGAWA (JP); YUSUKE OTAKE, KANAGAWA (JP); TOSHIFUMI WAKANO, KANAGAWA (JP); RYUICHI ITOH, KANAGAWA (JP); MASAKI SAITO, KANAGAWA (JP)

(21) Appl. No.: 19/130,394

(22) PCT Filed: Nov. 14, 2023
(86) PCT No.: PCT/JP2023/040952

§ 371 Date: May 15, 2025

(30) Foreign Application Priority Data
Nov. 24, 2022 (JP) 2022-187547

(51) Int. Cl. H10F 39/00; H04N 25/778; H04N 25/79

(52) U.S. Cl. CPC H10F 39/80373; H04N 25/778; H04N 25/79

(57) ABSTRACT

Provided is an image-capturing apparatus that can reduce deterioration of the performance. An image-capturing apparatus includes a semiconductor layer, multiple pixels provided on the semiconductor layer, an inter-pixel separating section that is provided on the semiconductor layer and separates one pixel and another pixel that are adjacent to each other in the multiple pixels, and pixel transistors connected to the multiple pixels. The pixel transistors include a first transistor and a second transistor adjacent to the first transistor with the inter-pixel separating section being interposed therebetween. A gate electrode of the first transistor and a gate electrode of the second transistor are integrated via an upper portion of the inter-pixel separating section.

### TECHNICAL FIELD

The present disclosure relates to an image-capturing apparatus.

### BACKGROUND ART

As image-capturing apparatuses including photodiodes and transistors that read out charges photoelectrically converted at the photodiodes, CMOS image sensors are known. There is a known structure in which pixels in a CMOS image sensor are separated using an element separating section (e.g., refer to PTL 1 and PTL 2).

### CITATION LIST

### Patent Literature

### PTL 1

Japanese Patent Laid-open No. 2020-13817

### PTL 2

U.S. Patent Application Publication No. 2020/0219925

### SUMMARY

### Technical Problem

There is a tendency that, along with miniaturization of pixels, spaces for the arrangement of transistors, spaces for the arrangement of wires, spaces between adjacent transistors, and spaces between adjacent wires are reduced. If these spaces are reduced, there is a possibility that parasitic capacitance that is generated between adjacent vias (contacts) and between adjacent wires increases and the performance of the image-capturing apparatus is deteriorated.

The present disclosure has been made in view of such circumstances, and an object thereof is to provide an image-capturing apparatus that can reduce deterioration of the performance.

### Solution to Problem

An image-capturing apparatus according to one aspect of the present disclosure includes a semiconductor layer, multiple pixels provided on the semiconductor layer, an inter-pixel separating section that is provided on the semiconductor layer and separates one pixel and another pixel that are adjacent to each other in the multiple pixels, and pixel transistors connected to the multiple pixels. The pixel transistors include a first transistor and a second transistor adjacent to the first transistor with the inter-pixel separating section being interposed therebetween. A gate electrode of the first transistor and a gate electrode of the second transistor are integrated via an upper portion of the inter-pixel separating section.

According to this configuration, the gate electrode of the first transistor and the gate electrode of the second transistor can share a via (contact) and a wire connected thereto, the number of vias and the number of wires can be reduced, and the length of wires can be reduced. Accordingly, the distances between adjacent vias and between adjacent wires can be increased, and parasitic capacitance generated between the vias and between the wires can be reduced. Thus, deterioration of the performance of the image-capturing apparatus can be reduced.

### BRIEF DESCRIPTION OF DRAWINGS

FIG. 1 is a block diagram depicting a configuration example of an image-capturing apparatus according to a first embodiment of the present disclosure.

FIG. 2 is a circuit diagram depicting a configuration example of a sharing pixel unit of the image-capturing apparatus according to the first embodiment of the present disclosure.

FIG. 3 is a plan view schematically depicting a configuration example of a pixel area of the image-capturing apparatus according to the first embodiment of the present disclosure.

FIG. 4 is a plan view schematically depicting a configuration example of the pixel area of the image-capturing apparatus according to the first embodiment of the present disclosure.

FIG. 5 is a plan view schematically depicting a configuration example of the pixel area of the image-capturing apparatus according to the first embodiment of the present disclosure.

FIG. 6 is a plan view schematically depicting a configuration example of the pixel area of the image-capturing apparatus according to the first embodiment of the present disclosure.

FIG. 7 is a cross-sectional view depicting a configuration example of the image-capturing apparatus according to the first embodiment of the present disclosure.

FIG. 8 is a plan view depicting a pixel area according to a comparative example of the present disclosure.

FIG. 9 is a cross-sectional view depicting the pixel area according to the comparative example of the present disclosure.

FIG. 10A is a plan view schematically depicting a configuration of a pixel area according to a modification example 1-1 of the first embodiment of the present disclosure.

FIG. 10B is a plan view schematically depicting a configuration of a pixel area according to a modification example 1-2 of the first embodiment of the present disclosure.

FIG. 10C is a plan view schematically depicting a configuration of a pixel area according to a modification example 1-3 of the first embodiment of the present disclosure.

FIG. 11A is a plan view schematically depicting a configuration of a pixel area according to a modification example 2-1 of the first embodiment of the present disclosure.

FIG. 11B is a plan view schematically depicting a configuration of a pixel area according to a modification example 2-2 of the first embodiment of the present disclosure.

FIG. 11C is a plan view schematically depicting a configuration of a pixel area according to a modification example 2-3 of the first embodiment of the present disclosure.

FIG. 11D is a plan view schematically depicting a configuration of a pixel area according to a modification example 2-4 of the first embodiment of the present disclosure.

FIG. 12A is a plan view schematically depicting a configuration of a pixel area according to a modification example 3-1 of the first embodiment of the present disclosure.

FIG. 12B is a plan view schematically depicting a configuration of a pixel area according to a modification example 3-2 of the first embodiment of the present disclosure.

FIG. 13A is a plan view schematically depicting a configuration of a pixel area according to a modification example 4-1 of the first embodiment of the present disclosure.

FIG. 13B is a plan view schematically depicting a configuration of a pixel area according to a modification example 4-2 of the first embodiment of the present disclosure.

FIG. 13C is a plan view schematically depicting a configuration of a pixel area according to a modification example 4-3 of the first embodiment of the present disclosure.

FIG. 13D is a plan view schematically depicting a configuration of a pixel area according to a modification example 4-4 of the first embodiment of the present disclosure.

FIG. 13E is a plan view schematically depicting a configuration of a pixel area according to a modification example 4-5 of the first embodiment of the present disclosure.

FIG. 13F is a plan view schematically depicting a configuration of a pixel area according to a modification example 4-6 of the first embodiment of the present disclosure.

FIG. 14A is a plan view schematically depicting a configuration of a pixel area according to a modification example 5-1 of the first embodiment of the present disclosure.

FIG. 14B is a plan view schematically depicting a configuration of a pixel area according to a modification example 5-2 of the first embodiment of the present disclosure.

FIG. 14C is a plan view schematically depicting a configuration of a pixel area according to a modification example 5-3 of the first embodiment of the present disclosure.

FIG. 15A is a plan view schematically depicting a configuration of a pixel area according to a modification example 6-1 of the first embodiment of the present disclosure.

FIG. 15B is a plan view schematically depicting a configuration of a pixel area according to a modification example 6-2 of the first embodiment of the present disclosure.

FIG. 15C is a plan view schematically depicting a configuration of a pixel area according to a modification example 6-3 of the first embodiment of the present disclosure.

FIG. 15D is a plan view schematically depicting a configuration of a pixel area according to a modification example 6-4 of the first embodiment of the present disclosure.

FIG. 15E is a plan view schematically depicting a configuration of a pixel area according to a modification example 6-5 of the first embodiment of the present disclosure.

FIG. 15F is a plan view schematically depicting a configuration of a pixel area according to a modification example 6-6 of the first embodiment of the present disclosure.

FIG. 16A is a plan view schematically depicting a configuration example of a pixel area according to a second embodiment of the present disclosure.

FIG. 16B is a plan view schematically depicting a configuration example of the pixel area according to the second embodiment of the present disclosure.

FIG. 17A is a plan view schematically depicting a configuration of a pixel area according to a modification example 7-1 of the second embodiment of the present disclosure.

FIG. 17B is a plan view schematically depicting a configuration of a pixel area according to a modification example 7-2 of the second embodiment of the present disclosure.

FIG. 17C is a plan view schematically depicting a configuration of a pixel area according to a modification example 7-3 of the second embodiment of the present disclosure.

FIG. 17D is a plan view schematically depicting a configuration of a pixel area according to a modification example 7-4 of the second embodiment of the present disclosure.

FIG. 17E is a plan view schematically depicting a configuration of a pixel area according to a modification example 7-5 of the second embodiment of the present disclosure.

FIG. 17F is a plan view schematically depicting a configuration of a pixel area according to a modification example 7-6 of the second embodiment of the present disclosure.

FIG. 17G is a plan view schematically depicting a configuration of a pixel area according to a modification example 7-7 of the second embodiment of the present disclosure.

FIG. 17H is a plan view schematically depicting a configuration of a pixel area according to a modification example 7-8 of the second embodiment of the present disclosure.

FIG. 17I is a plan view schematically depicting a configuration of a pixel area according to a modification example 7-9 of the second embodiment of the present disclosure.

FIG. 17J is a plan view schematically depicting a configuration of a pixel area according to a modification example 7-10 of the second embodiment of the present disclosure.

FIG. 18 is a plan view schematically depicting a configuration example of a pixel area according to a third embodiment of the present disclosure.

FIG. 19A is a plan view schematically depicting a configuration of a pixel area according to a modification example 8-1 of the third embodiment of the present disclosure.

FIG. 19B is a plan view schematically depicting a configuration of a pixel area according to a modification example 8-2 of the third embodiment of the present disclosure.

FIG. 19C is a plan view schematically depicting a configuration of a pixel area according to a modification example 8-3 of the third embodiment of the present disclosure.

FIG. 19D is a plan view schematically depicting a configuration of a pixel area according to a modification example 8-4 of the third embodiment of the present disclosure.

FIG. 19E is a plan view schematically depicting a configuration of a pixel area according to a modification example 8-5 of the third embodiment of the present disclosure.

FIG. 19F is a plan view schematically depicting a configuration of a pixel area according to a modification example 8-6 of the third embodiment of the present disclosure.

FIG. 19G is a plan view schematically depicting a configuration of a pixel area according to a modification example 8-7 of the third embodiment of the present disclosure.

FIG. 19H is a plan view schematically depicting a configuration of a pixel area according to a modification example 8-8 of the third embodiment of the present disclosure.

FIG. 19I is a plan view schematically depicting a configuration of a pixel area according to a modification example 8-9 of the third embodiment of the present disclosure.

FIG. 20 is a plan view schematically depicting a configuration example of a pixel area according to a fourth embodiment of the present disclosure.

FIG. 21A is a plan view schematically depicting a configuration of a pixel area according to a modification example 9-1 of the fourth embodiment of the present disclosure.

FIG. 21B is a plan view schematically depicting a configuration of a pixel area according to a modification example 9-2 of the fourth embodiment of the present disclosure.

FIG. 22 is a circuit diagram depicting a configuration example 1 of a readout circuit according to a fifth embodiment of the present disclosure.

FIG. 23 is a circuit diagram depicting a configuration example 2 of the readout circuit according to the fifth embodiment of the present disclosure.

FIG. 24 is a circuit diagram depicting a configuration example 3 of the readout circuit according to the fifth embodiment of the present disclosure.

FIG. 25 is a circuit diagram depicting a configuration example 4 of the readout circuit according to the fifth embodiment of the present disclosure.

FIG. 26 is a circuit diagram depicting a configuration example 5 of the readout circuit according to the fifth embodiment of the present disclosure.

FIG. 27 is a circuit diagram depicting a configuration example 6 of the readout circuit according to the fifth embodiment of the present disclosure.

FIG. 28 is a circuit diagram depicting a configuration example 7 of the readout circuit according to the fifth embodiment of the present disclosure.

FIG. 29 is a circuit diagram depicting a configuration example 8 of the readout circuit according to the fifth embodiment of the present disclosure.

FIG. 30 is a circuit diagram depicting a configuration example 9 of the readout circuit according to the fifth embodiment of the present disclosure.

FIG. 31 is a circuit diagram depicting a configuration example 10 of the readout circuit according to the fifth embodiment of the present disclosure.

FIG. 32 is a circuit diagram depicting a configuration example 11 of a readout circuit according to the fifth embodiment of the present disclosure.

FIG. 33 is a circuit diagram depicting a configuration example 12 of the readout circuit according to the fifth embodiment of the present disclosure.

FIG. 34 is a circuit diagram depicting a configuration example 13 of the readout circuit according to the fifth embodiment of the present disclosure.

FIG. 35 is a circuit diagram depicting a configuration example 14 of the readout circuit according to the fifth embodiment of the present disclosure.

FIG. 36 is a cross-sectional view depicting an image-capturing apparatus according to a configuration example 1 of a sixth embodiment of the present disclosure.

FIG. 37 is a cross-sectional view depicting an image-capturing apparatus according to a configuration example 2 of the sixth embodiment of the present disclosure.

FIG. 38 is a plan view schematically depicting a pixel area 12M according to a configuration example 1 of another embodiment of the present disclosure.

FIG. 39 is a plan view schematically depicting a pixel area 12N according to a configuration example 2 of another embodiment of the present disclosure.

FIG. 40 is a plan view schematically depicting a pixel area 12P according to a configuration example 3 of another embodiment of the present disclosure.

### DESCRIPTION OF EMBODIMENTS

Hereinbelow, embodiments of the present disclosure are explained with reference to the figures. In the descriptions of the figures that are referred to in the following explanation, identical or similar portions are given identical or similar reference signs. It should be noted however that the figures are schematic figures, and that the relations between thicknesses and plane dimensions, the rates of the thicknesses of respective layers, and the like are different from actual ones. Accordingly, specific thicknesses and dimensions should be determined by taking the following explanation into consideration. In addition, needless to say, dimensions in different figures have different relations and rates.

Definitions of directions such as the up-down direction in the following explanation are definitions that are used simply for convenience of explanation, and do not limit the technical idea of the present disclosure. For example, needless to say, if a target object is observed after being rotated 90°, the up-down direction described in an explanation of the target object is interpreted as meaning the left-right direction, and if the target object is observed after being rotated 180°, the up-down direction described in the explanation is interpreted as meaning an inverted direction.

In some cases in the following explanation, directions are explained by using phrases “X-axis direction,” “Y-axis direction,” and “Z-axis direction.” For example, the X-axis direction and the Y-axis direction are directions parallel to a front surface 11a of a semiconductor substrate 11. The X-axis direction and the Y-axis direction are also referred to as horizontal directions. The Z-axis direction is the thickness direction of the semiconductor substrate 11 (i.e., the normal direction of the front surface 11a of the semiconductor substrate 11). The X-axis direction, the Y-axis direction, and the Z-axis direction are orthogonal to each other.

In addition, in the following explanation, a “plan view” means a view as seen in the thickness direction of the semiconductor substrate 11 (i.e., the normal direction of the front surface 11a of the semiconductor substrate 11, and the Z-axis direction), for example.

In the following explanation, a case where a first conductivity is P type and a second conductivity is N type is explained as an example. However, there are no problems even if conductivities are selected to have an opposite relation, in which the first conductivity is the N type and the second conductivity is the P type. In addition, + attached to P or N means that a semiconductor layer indicated by the sign is a semiconductor layer having an impurity concentration which is relatively high as compared to a semiconductor layer indicated by P or N to which + is not attached. However, semiconductor layers being indicated by the same P and P does not mean that the impurity concentrations of the respective semiconductor layers are the same in a strict sense.

### First Embodiment

### Overall Configuration Example of Image-Capturing Apparatus

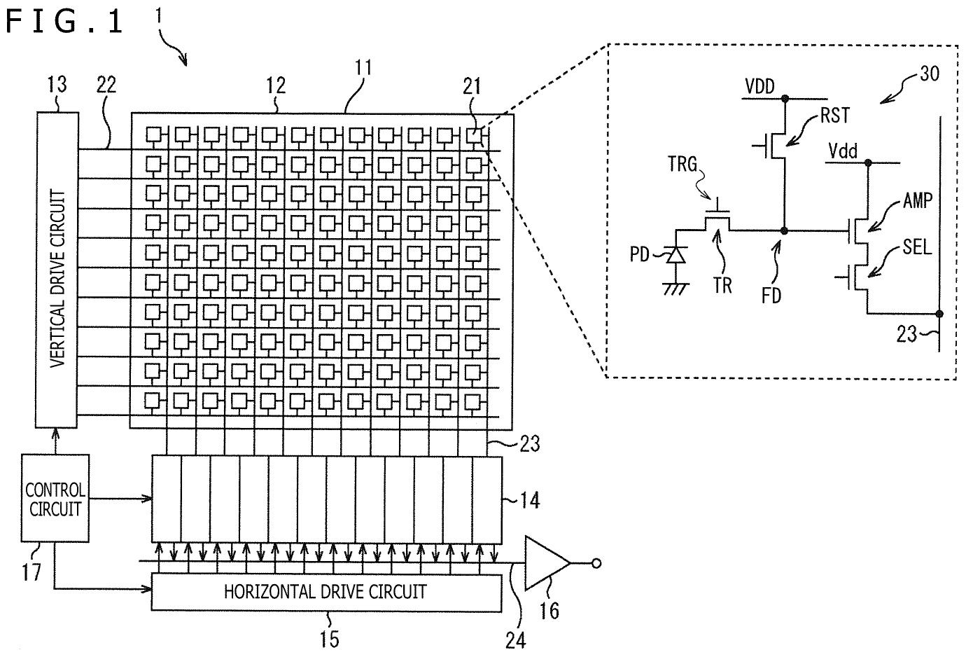

FIG. 1 is a block diagram depicting a configuration example of an image-capturing apparatus 1 according to a first embodiment of the present disclosure. As depicted in FIG. 1, the image-capturing apparatus 1 includes the semiconductor substrate 11 (an example of the “semiconductor layer” of the present disclosure), a pixel area 12 provided on the semiconductor substrate 11, a vertical drive circuit 13, column signal processing circuits 14, a horizontal drive circuit 15, an output circuit 16, and a control circuit 17. The vertical drive circuit 13, the column signal processing circuits 14, the horizontal drive circuit 15, the output circuit 16, and the control circuit 17 may be provided on the semiconductor substrate 11, or may be provided on a second semiconductor substrate (not depicted) arranged on the front-surface side of the (first) semiconductor substrate 11 with a multilayer wiring layer (not depicted) including a wiring layer and an interlayer dielectric film being interposed therebetween.

The pixel area 12 is a light reception area that receives light condensed by an undepicted optical system, and has multiple pixels 21. The multiple pixels 21 are arranged in a matrix. The multiple pixels 21 are connected to the vertical drive circuit 13 in units of rows via horizontal signal lines 22, and are also connected to the column signal processing circuits 14 in units of columns via vertical signal lines 23.

Each of the multiple pixels 21 outputs a pixel signal at a level according to the amount of light that the pixel receives. From those pixel signals, an image of a subject is constructed.

The vertical drive circuit 13 supplies, to the pixels 21 via the horizontal signal lines 22, drive signals for sequentially driving (transferring, selecting, resetting, etc.) the respective pixels 21, in units of rows of the multiple pixels 21. The column signal processing circuits 14 perform AD conversion on pixel signals output from the multiple pixels 21 via the vertical signal lines 23 and also remove reset noise by implementing a CDS (Correlated Double Sampling) process on the pixel signals.

The horizontal drive circuit 15 supplies, to the column signal processing circuits 14, drive signals for sequentially causing the column signal processing circuits 14 to output pixel signals to a data output signal line 24, in units of columns of the multiple pixels 21. The output circuit 16 amplifies the pixel signals supplied from the column signal processing circuits 14 via the data output signal line 24 at timings according to the drive signals of the horizontal drive circuit 15, and outputs the pixel signals to a downstream signal processing circuit. The control circuit 17 controls driving of each block inside the image-capturing apparatus 1. For example, the control circuit 17 generates a clock signal according to the drive cycle of each block, and supplies the clock signals to the respective blocks.

Each pixel 21 includes a photodiode PD (an example of a “photoelectric converting section” of the present disclosure), a transfer transistor TR, a floating diffusion FD, an amplification transistor AMP, a selection transistor SEL, and a reset transistor RST. The transfer transistor TR, the floating diffusion FD, the amplification transistor AMP, the selection transistor SEL, and the reset transistor RST form a readout circuit 30 that reads out a charge (pixel signal) photoelectrically converted at the photodiode PD.

The photodiode PD is the photoelectric converting section that converts incident light into a charge by photoelectric conversion and stores the charge. The photodiode PD has an anode terminal connected to the ground and also has a cathode terminal connected to the transfer transistor TR. A transfer signal is supplied from the vertical drive circuit 13 to a gate electrode TRG of the transfer transistor TR. The transfer transistor TR is driven according to the transfer signal supplied to the gate electrode TRG. Hereinbelow, the gate electrode TRG is also referred to as a transfer gate. When the transfer transistor TR is turned on, the charge stored in the photodiode PD is transferred to the floating diffusion FD. The floating diffusion FD is a floating diffusion area that is connected to the gate electrode of the amplification transistor AMP and that has predetermined storage capacitance, and temporarily stores the charge transferred from the photodiode PD.

The amplification transistor AMP outputs a pixel signal at a level according to the charge stored in the floating diffusion FD (i.e., the potential of the floating diffusion FD) to the vertical signal line 23 via the selection transistor SEL. That is, with a configuration in which the floating diffusion FD is connected to the gate electrode of the amplification transistor AMP, the floating diffusion FD and the amplification transistor AMP function as a converting section that amplifies the charge generated at the photodiode PD and that converts the charge into a pixel signal at a level according to the charge.

The selection transistor SEL is driven according to a selection signal supplied from the vertical drive circuit 13, and, when the selection transistor SEL is turned on, it becomes possible for the pixel signal output from the amplification transistor AMP to be output to the vertical signal line 23. The reset transistor RST is driven according to a reset signal supplied from the vertical drive circuit 13, and, when the reset transistor RST is turned on, the charge stored in the floating diffusion FD is drained to a wire 63, and the potential of the floating diffusion FD is reset. The wire 63 is connected to a power supply potential VDD.

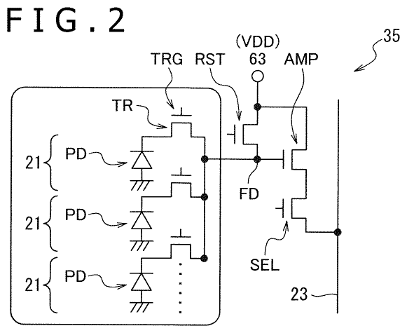

FIG. 2 is a circuit diagram depicting a configuration example of a sharing pixel unit 35 of the image-capturing apparatus 1 according to the first embodiment of the present disclosure. As depicted in FIG. 2, in the image-capturing apparatus 1, the photodiodes PD and the transfer transistors TR of multiple pixels 21 are connected in parallel to form the sharing pixel unit 35. In the sharing pixel unit 35, for example, the photodiode PD of each pixel 21 included in the sharing pixel unit 35 is connected to one floating diffusion FD via the transfer transistor TR of each pixel 21.

### Configuration Examples of Pixels

### (1) Configurations Seen in Plan Views

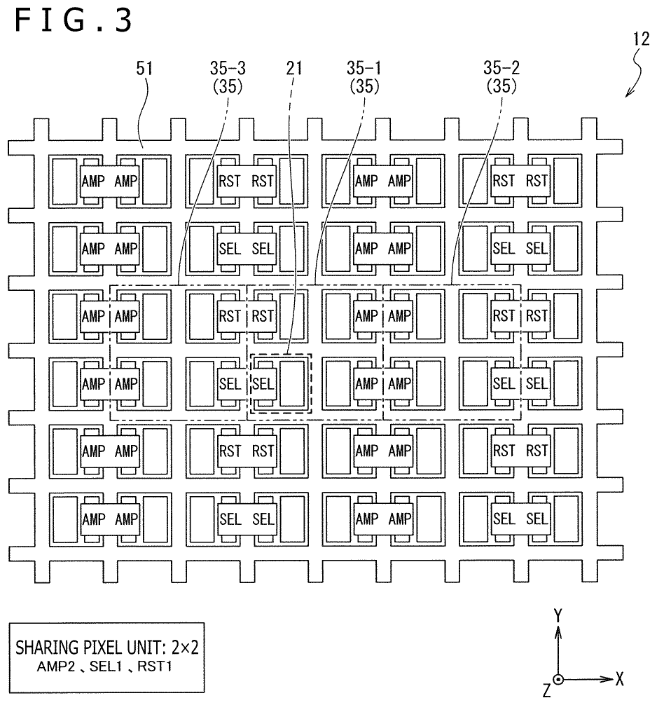

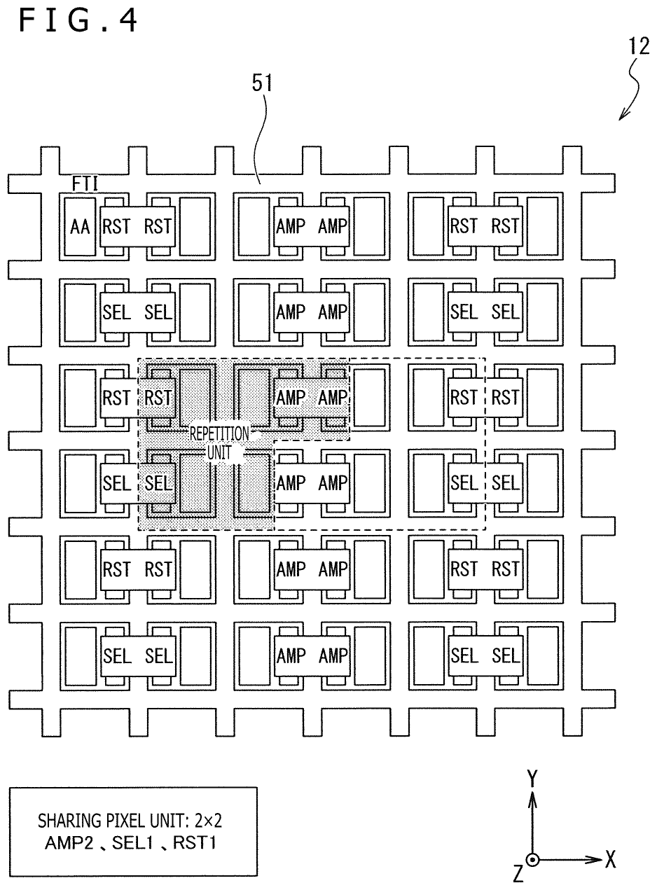

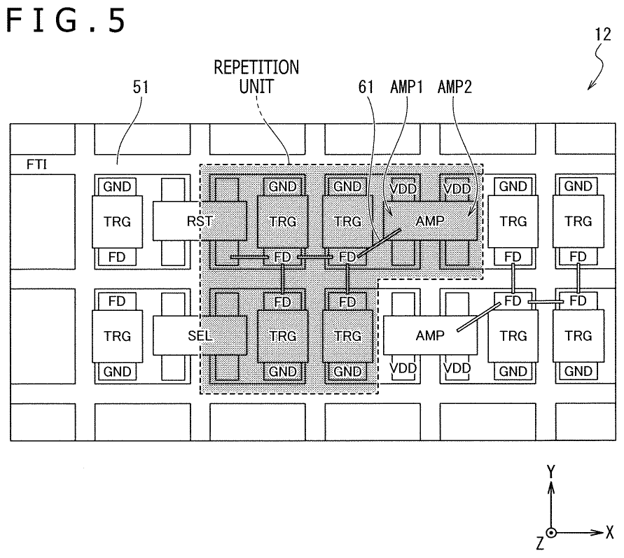

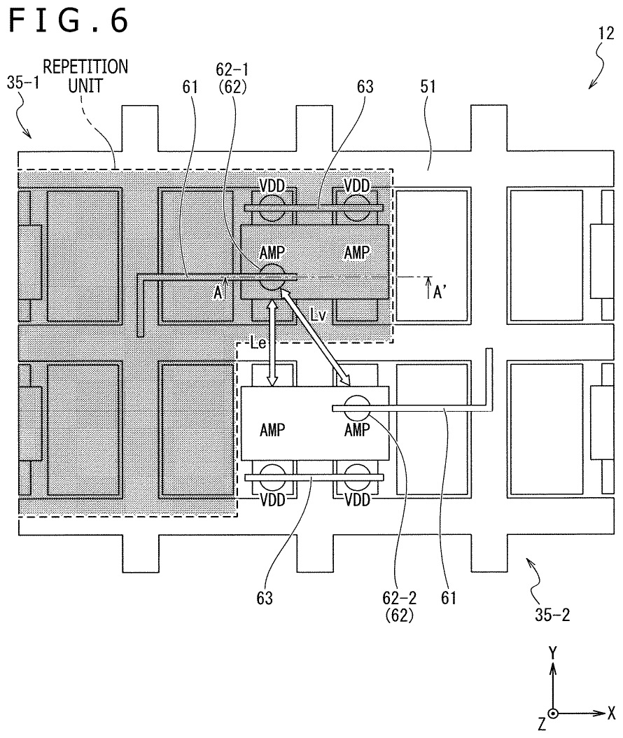

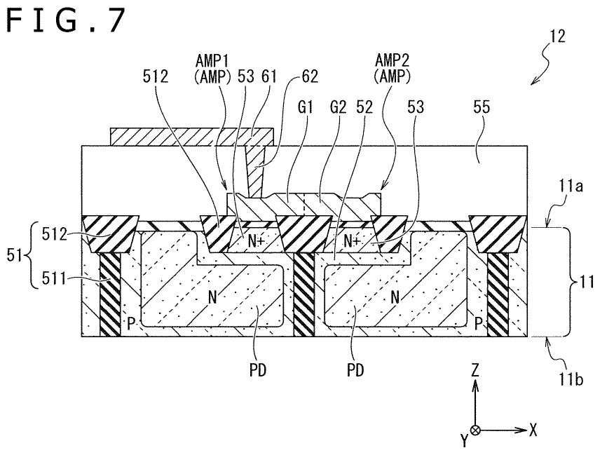

FIG. 3 to FIG. 6 are plan views schematically depicting configuration examples of the pixel area 12 of the image-capturing apparatus 1 according to the first embodiment of the present disclosure. FIG. 3 illustrates an example of sharing pixel units 35. FIG. 4 illustrates an example of a repetition unit of the arrangement of pixel transistors connected to one sharing pixel unit 35. FIG. 5 is an enlarged view of FIG. 3 and FIG. 4, and is a plan view illustrating examples of a first amplification transistor AMP1 and a second amplification transistor AMP2 that are adjacent to each other with an inter-pixel separating section 51 being interposed therebetween. FIG. 6 is a figure illustrating examples of wires 61 and vias 62 connected to amplification transistors AMP. Note that, in order to avoid complexity of the figures, floating diffusions FD (refer to FIG. 5), transfer transistors TR including transfer gates TRG (refer to FIG. 2 and FIG. 5), and photodiodes PD (refer to FIG. 7 described later) are not depicted and omitted in FIG. 3 and FIG. 4.

As depicted in FIG. 3, four pixels 21 in total that are arrayed in two lines in each of the horizontal direction (e.g., the X-axis direction) and the vertical direction (e.g., the Y-axis direction) in a plan view form one sharing pixel unit 35 in the image-capturing apparatus 1. The sharing pixel unit 35 depicted in FIG. 3 is also referred to as a 2×2-type sharing pixel unit for the number of sharing pixels and the arrangement thereof.

The 2×2-type sharing pixel unit 35 includes four photodiodes PD, four transfer transistors TR, four floating diffusions FD, and shared pixel transistors.

As depicted in FIG. 3 to FIG. 6, each of multiple pixels 21 is individually surrounded by the inter-pixel separating section 51 in a plan view. One pixel 21 and another pixel 21 that are adjacent to each other are separated by the inter-pixel separating section 51. In the 2×2-type sharing pixel unit 35, the four floating diffusions FD are not integrated, and are individually separated by the inter-pixel separating section 51. In the sharing pixel unit 35, the four floating diffusions FD are connected with each other via wires 61, and are connected to the gate electrodes of the amplification transistors AMP.

Note that, in FIG. 3 and FIG. 4, the reference sign “AA” denotes active areas such as the source and drain areas of photodiodes PD, floating diffusions FD, and pixel transistors.

For example, an area on the front surface 11a (refer to FIG. 7 described later) of the semiconductor substrate 11 where neither the inter-pixel separating section 51 nor a second trench isolation 512 (refer to FIG. 7 described later) is arranged is equivalent to an active area AA depicted in FIG. 3 and FIG. 4.

Pixel transistors include selection transistors SEL, reset transistors RST, and amplification transistors AMP. For example, the 2×2-type sharing pixel unit 35 has one selection transistor, one reset transistor RST, and two amplification transistors AMP (a first amplification transistor AMP1 and a second amplification transistor AMP2), as pixel transistors. The first amplification transistor AMP1 is an example of a “first transistor” of the present disclosure. The second amplification transistor AMP2 is an example of a “second transistor” of the present disclosure.

In addition, in the image-capturing apparatus 1, one pixel transistor is arranged at a position overlapping one pixel 21 in the plan view. For example, in four pixels 21 that the 2×2-type sharing pixel unit 35 has, the selection transistor SEL is arranged at a position overlapping a first pixel 21 in a plan view. The reset transistor RST is arranged at a position overlapping a second pixel 21 in the plan view. The first amplification transistor AMP1 is arranged at a position overlapping a third pixel 21 in the plan view. The second amplification transistor AMP2 is arranged at a position overlapping a fourth pixel 21 in the plan view.

It should be noted that, as can be understood from comparison of FIG. 3 and FIG. 4, in the image-capturing apparatus 1, a first amplification transistor AMP1 (or a second amplification transistor AMP2) included in one sharing pixel unit 35 is arranged at a position overlapping, in a plan view, a pixel 21 of another sharing pixel unit 35 adjacent to the one sharing pixel unit 35.

Explained specifically, in the image-capturing apparatus 1, 2×2-type sharing pixel units 35 are arrayed in both the horizontal direction (e.g., the X-axis direction) and the vertical direction (e.g., the Y-axis direction) in a plan view. The sharing pixel units 35 include a first sharing pixel unit 35-1 and a second sharing pixel unit 35-2 adjacent to the first sharing pixel unit 35-1 in the horizontal direction (X-axis direction). A second amplification transistor AMP2 that the first sharing pixel unit 35-1 has is arranged at a position overlapping one pixel 21 of the second sharing pixel unit 35-2 in the plan view. In addition, a first amplification transistor AMP1 that the second sharing pixel unit 35-2 has is arranged at a position overlapping one pixel 21 of the first sharing pixel unit 35-1 in the plan view.

Note that multiple sharing pixel units 35 have common constituent elements. In FIG. 3, in order to make distinctions between adjacent sharing pixel units 35, identification numbers (−1, −2, −3) are given to the ends of reference signs of the sharing pixel units 35, and the sharing pixel units 35 are called the first sharing pixel unit 35-1, the second sharing pixel unit 35-2, and a third sharing pixel unit 35-3. In addition, in a case where it is not necessary to make distinctions between them, the identification numbers at the ends are omitted, and the sharing pixel units 35 are simply referred to as sharing pixel units 35.

Similarly, a first amplification transistor AMP1 and a second amplification transistor AMP2 have common constituent elements. In FIG. 5 to FIG. 7, in order to make distinctions between two adjacent amplification transistors AMP (a first amplification transistor AMP1 and a second amplification transistor AMP2), identification numbers (1, 2) are given to the ends of reference signs of the two amplification transistors AMP. In a case where it is not necessary to make distinctions between them, the identification numbers at the ends are omitted, and the amplification transistors AMP are simply referred to as amplification transistors AMP.

As depicted in FIG. 3 to FIG. 6, in the image-capturing apparatus 1, a gate electrode G1 (refer to FIG. 7 described later) of a first amplification transistor AMP1 and a gate electrode G2 (refer to FIG. 7 described later) of a second amplification transistor AMP2 adjacent to the first amplification transistor AMP1 with the inter-pixel separating section 51 being interposed therebetween are integrated via an upper portion of the inter-pixel separating section 51 in each of the multiple sharing pixel units 35.

For example, the gate electrode G1 of the first amplification transistor AMP1 included in the first sharing pixel unit 35-1 and the gate electrode G2 of the second amplification transistor AMP2 included in the first sharing pixel unit 35-1 are integrated via an upper portion of the inter-pixel separating section 51. Similarly, the gate electrode G1 of the first amplification transistor AMP1 included in the second sharing pixel unit 35-2 and the gate electrode G2 of the second amplification transistor AMP2 included in the second sharing pixel unit 35-2 are integrated via an upper portion of the inter-pixel separating section 51.

In addition, these integrated gate electrodes are arranged next to each other at constant intervals in one direction (e.g., the Y-axis direction). For example, the integrated gate electrodes of the first amplification transistor AMP1 and the second amplification transistor AMP2 in the first sharing pixel unit 35-1 are treated as a first gate electrode. The integrated gate electrodes of the first amplification transistor AMP1 and the second amplification transistor in the second sharing pixel unit 35-2 are treated as a second gate electrode. In this case, the first gate electrode and the second gate electrode are adjacent to each other in the Y-axis direction with the inter-pixel separating section 51 being interposed therebetween.

In addition, as depicted in FIG. 6, the first sharing pixel unit 35-1 has a first via 62-1 provided on the first gate electrode described above and connected to the first gate electrode. The second sharing pixel unit 35-2 has a second via 62-2 provided on the second gate electrode described above and connected to the second gate electrode. Assuming that a shortest distance between the first via 62-1 and the second via 62-2 is Lv and that a shortest distance between the first gate electrode and the second gate electrode is Le, the direction of the shortest distance Lv crosses the direction of the shortest distance Le.

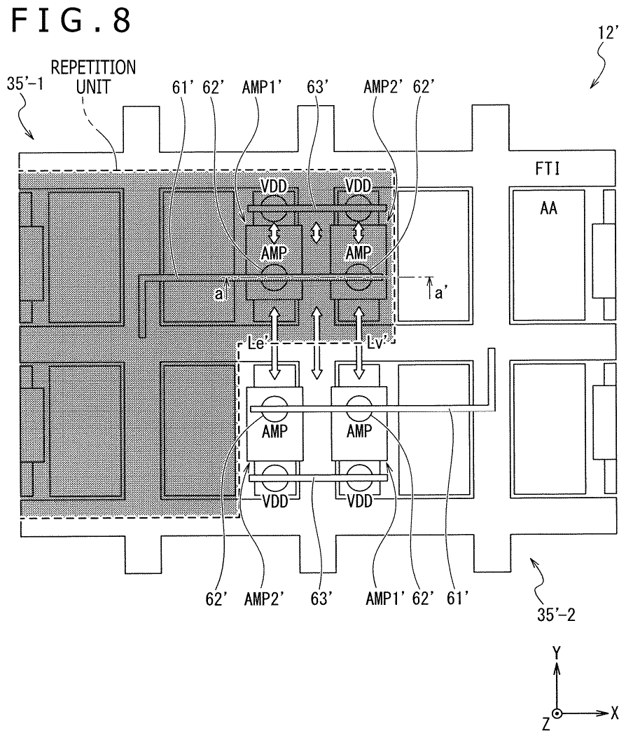

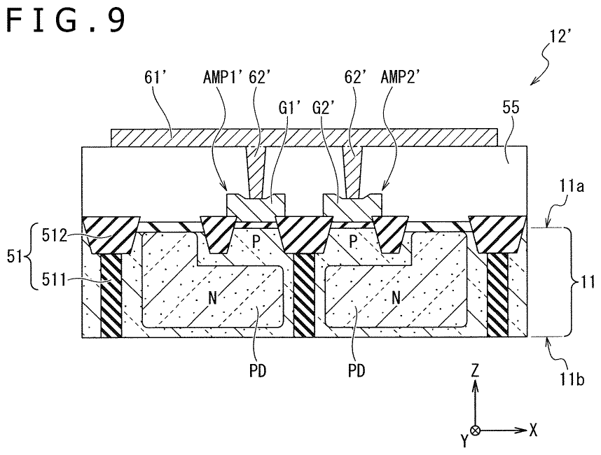

For example, the direction of the shortest distance Le is the Y-axis direction. The direction of the shortest distance Lv crosses both the Y-axis direction and the X-axis direction. The direction of the shortest distance Lv crosses the direction of the shortest distance Le obliquely in a plan view. Accordingly, as compared with a case where the direction of the shortest distance Lv coincides with the direction of the shortest distance Le (i.e., a comparative example described later ((refer to FIG. 8 and FIG. 9)), parasitic capacitance (i.e., unintended capacitive coupling) between the first via 62-1 and the second via 62-2 can be reduced.

In addition, the number of the first vias 62-1 provided on the first gate electrode is one. Since the number of the first vias 62-1 and the second vias 62-2 is small as compared with the comparative example described later ((refer to FIG. 8 and FIG. 9), the length of parallel portions of the wire 61 connected to the first via 62-1 and the wire 61 connected to the second via 62-2 can be reduced (i.e., a state where the wires 61 are kept away from each other as much as possible can be created), and parasitic capacitance between these wires 61 can be reduced.

It should be noted that the number of the first vias 62-1 provided on the first gate electrode is not limited to one in embodiments of the present disclosure. Whereas the one first via 62-1 is provided on the one first gate electrode in the aspect depicted in this example, this is merely an example. The number of vias provided at each location is not necessarily one in embodiments of the present disclosure.

Note that the first via 62-1 and the second via 62-2 have common constituent elements. Although the reference signs “62” of these are given identification numbers (−1, −2) at their ends in order to make distinctions therebetween in FIG. 6, in a case where it is not necessary to make distinctions therebetween, the identification numbers at the ends are omitted, and they are simply referred to as vias 62.

A drain of the first amplification transistor AMP1 and a drain of the second amplification transistor AMP2 are connected with each other via the wire 63 in each of the first sharing pixel unit 35-1 and the second sharing pixel unit 35-2. In addition, each drain is connected to the power supply potential VDD via the wire 63. In the image-capturing apparatus 1, the gate electrodes G1 and G2 are integrated, and the number of the vias 62 connected to the gate electrodes G1 and G2 is one. Owing to this, as compared with the comparative example described later (refer to FIG. 8 and FIG. 9), the length of parallel portions of the wires 61 and 63 can be reduced (i.e., a state where the wires 61 and 63 are kept away from each other as much as possible can be created), and parasitic capacitance between wires 61 and 63 can be reduced.

In the image-capturing apparatus 1, not only the gate electrodes of the amplification transistors AMP but also a gate electrode of a selection transistor SEL included in one sharing pixel unit and a gate electrode of a selection transistor SEL of another sharing pixel unit 35 adjacent to the one sharing pixel unit 35 are integrated via an upper portion of the inter-pixel separating section 51. Accordingly, in the image-capturing apparatus 1, the selection transistor SEL included in the one sharing pixel unit may be treated as an example of the “first transistor” of the present disclosure, and the selection transistor SEL of the other sharing pixel unit 35 adjacent to the one sharing pixel unit 35 may be treated as an example of the “second transistor” of the present disclosure. In this case, parasitic capacitance formed between vias and wires of the selection transistors SEL that are adjacent to each other with the inter-pixel separating section 51 being interposed therebetween can be reduced.

Similarly, in the image-capturing apparatus 1, a gate electrode of a reset transistor RST included in the one sharing pixel unit and a gate electrode of a reset transistor RST of the other sharing pixel unit 35 adjacent to the one sharing pixel unit 35 are also integrated via an upper portion of the inter-pixel separating section 51. Accordingly, in the image-capturing apparatus 1, the reset transistor RST included in the one sharing pixel unit may be treated as an example of the “first transistor” of the present disclosure, and the reset transistor RST of the other sharing pixel unit 35 adjacent to the one sharing pixel unit 35 may be treated as an example of the “second transistor” of the present disclosure. In this case, parasitic capacitance formed between vias and wires of the reset transistors RST that are adjacent to each other with the inter-pixel separating section 51 being interposed therebetween can be reduced.

### (2) Configuration When Seen in Cross-Sectional View

Next, a configuration of each pixel 21 when seen in a cross-sectional view is explained. FIG. 7 is a cross-sectional view depicting a configuration example of the image-capturing apparatus 1 according to the first embodiment of the present disclosure. FIG. 7 depicts a cross-section taken along a line A-A′ in the plan view depicted in FIG. 6.

As depicted in FIG. 7, the semiconductor substrate 11 has the front surface 11a and a back surface 11b positioned on a side opposite to the front surface 11a. Pixel transistors such as amplification transistors AMP are arranged on the side of the front surface 11a of the semiconductor substrate 11. In addition, a multilayer wiring layer including multiple wires and multiple interlayer dielectric films that are stacked alternately is provided on the front-surface side of the semiconductor substrate 11. FIG. 7 depicts a wire 61 as part of multiple wires included in the multilayer wiring layer and an interlayer dielectric film 55 as part of the multiple interlayer dielectric films.

As depicted in FIG. 7, for example, the inter-pixel separating section 51 surrounding the outer circumference of each pixel 21 has a first trench isolation 511 provided to extend from the side of the back surface 11b of the semiconductor substrate 11 toward the side of the front surface 11a of the semiconductor substrate 11 and the second trench isolation 512 provided on the side of the front surface 11a of the semiconductor substrate 11. The second trench isolation 512 is arranged on the first trench isolation 511, thereby forming the inter-pixel separating section 51. In addition, the second trench isolation 512 is partially provided in each pixel 21, and separates elements in the pixel 21 (e.g., separates a pixel transistor from a floating diffusion, etc.).

For example, a pixel transistor is an N-type MOS transistor provided in a P-type well area 52. The type of a channel section 53 of the N-type MOS transistor is an N type (e.g., an N+ type) different from the type of the photodiode PD. For example, the potential of the P-type well area 52 is fixed at a reference potential (e.g., the ground potential (0 V) ) via a P-type contact area (not depicted) provided on the side of the front surface 11a of the semiconductor substrate 11.

For example, the side of the back surface 11b of the semiconductor substrate 11 is a light incidence surface on which light is incident, and is provided with on-chip lenses, color filters, and the like (none of which are depicted). For example, the image-capturing apparatus 1 is a backside illumination CMOS image sensor that photoelectrically converts light incident from the side of the back surface 11b of the semiconductor substrate 11.

### Comparative Example

Next, the comparative example is explained. FIG. 8 is a plan view depicting a pixel area 12′ according to the comparative example of the present disclosure. FIG. 9 is a cross-sectional view depicting the pixel area 12′ according to the comparative example of the present disclosure. FIG. 7 depicts a cross-section taken along a line a-a′ in the plan view depicted in FIG. 6.

As depicted in FIG. 8 and FIG. 9, in the comparative example, a gate electrode G1′ of a first amplification transistor AMP1′ included in a first sharing pixel unit 35′-1 and a gate electrode G2′ of a second amplification transistor AMP2′ included in the first sharing pixel unit 35′-1 are not integrated. A via 62′ is provided on each of the gate electrode G1′ of the first amplification transistor AMP1′ and the gate electrode G2′ of the second amplification transistor AMP2′. In addition, a wire 61′ is provided to connect the vias 62′ to each other. A second sharing pixel unit 35′-2 adjacent to the first sharing pixel unit 35′-1 also has a configuration similar to that of the first sharing pixel unit 35′-1.

In the comparative example, the direction of a shortest distance Lv′ between the via 62′ included in the first sharing pixel unit 35′-1 and the via 62′ included in the second sharing pixel unit 35′-2 coincides with the direction of a shortest distance Le′ between the gate electrode G1′ of the first amplification transistor AMP1′ included in the first sharing pixel unit 35′-1 and the gate electrode G2′ of the second amplification transistor AMP2′ included in the second sharing pixel unit 35′-2. Accordingly, it becomes easier for parasitic capacitance to be generated between the via 62′ of the first sharing pixel unit 35′-1 and the via 62′ of the second sharing pixel unit 35′-2.

As depicted in FIG. 8, it becomes easier for parasitic capacitance to be generated also between the wires 61′ of the first sharing pixel unit 35′-1 and the second sharing pixel unit 35′-2 since the length of parallel portions of the wires 61′ is short.

A drain of the first amplification transistor AMP1′ and a drain of the second amplification transistor AMP2′ are connected to the power supply potential VDD via a wire 63′ in each of the first sharing pixel unit 35′-1 and the second sharing pixel unit 35′-2. In the comparative example, the wire 61′ is connected to each of the gate electrodes G1′ and G2′ via the vias 62′, and the length of parallel portions of the wires 61′ and 63′ is long. Accordingly, it becomes easier for parasitic capacitance to be generated also between the wires 61′ and 63′.

### Advantages of First Embodiment

As explained above, the image-capturing apparatus 1 according to the first embodiment of the present disclosure includes the semiconductor substrate 11, the multiple pixels 21 provided on the semiconductor substrate 11, the inter-pixel separating section 51 that is provided on the semiconductor substrate 11 and separates one pixel 21 and another pixel 21 that are adjacent to each other in the multiple pixels 21, and pixel transistors connected to the multiple pixels 21. The pixel transistors include the first amplification transistor AMP1 and the second amplification transistor AMP2 adjacent to the first amplification transistor AMP1 with the inter-pixel separating section 51 being interposed therebetween. The gate electrode G1 of the first amplification transistor AMP1 and the gate electrode G2 of the second amplification transistor AMP2 are integrated via an upper portion of the inter-pixel separating section 51.

According to this configuration, the gate electrode G1 of the first amplification transistor AMP1 and the gate electrode G2 of the second amplification transistor AMP2 can share a via (contact) and a wire connected thereto, the number of vias and wires can be reduced, and the length of wires can be reduced.

Accordingly, the distances between adjacent vias 62 and between adjacent wires 61 can be increased, and parasitic capacitance generated between vias 62 and between wires 61 (e.g., refer to FIG. 6) can be reduced.

For example, capacitive signal coupling (VDD-FD coupling) generated between a wire 63 having the power supply potential VDD and a wire 61 having the potential of a floating diffusion FD and capacitive signal coupling (FD-FD coupling) generated between adjacent wires 61 can be reduced. As a result, deterioration of the performance of the image-capturing apparatus 1 can be reduced.

### Modification Examples of First Embodiment

### (1) Modification Example 1

For example, as depicted in FIG. 3 and FIG. 4, the gate electrodes of selection transistors SEL in one sharing pixel unit 35 and another sharing pixel unit 35 that are adjacent to each other in the X-axis direction are integrated via an upper portion of the inter-pixel separating section 51 in the aspect depicted in the first embodiment described above. Similarly, the gate electrodes of reset transistors RST in one sharing pixel unit 35 and another sharing pixel unit 35 that are adjacent to each other in the X-axis direction are integrated via an upper portion of the inter-pixel separating section 51 in the aspect depicted.

However, embodiments of the present disclosure are not limited to this. For example, configurations like ones in modification examples 1-1 to 1-3 depicted below may be adopted.

The configuration of each sharing pixel unit 35 in the modification examples 1-1 to 1-3 depicted below is a 2×2-type configuration in which two pixels are next to each other in the X-axis direction and two pixels are next to each other in the Y-axis direction. Each sharing pixel unit 35 has two amplification transistors AMP, one selection transistor SEL, and one reset transistor RST, as pixel transistors. Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

### (1-1) Modification Example 1-1

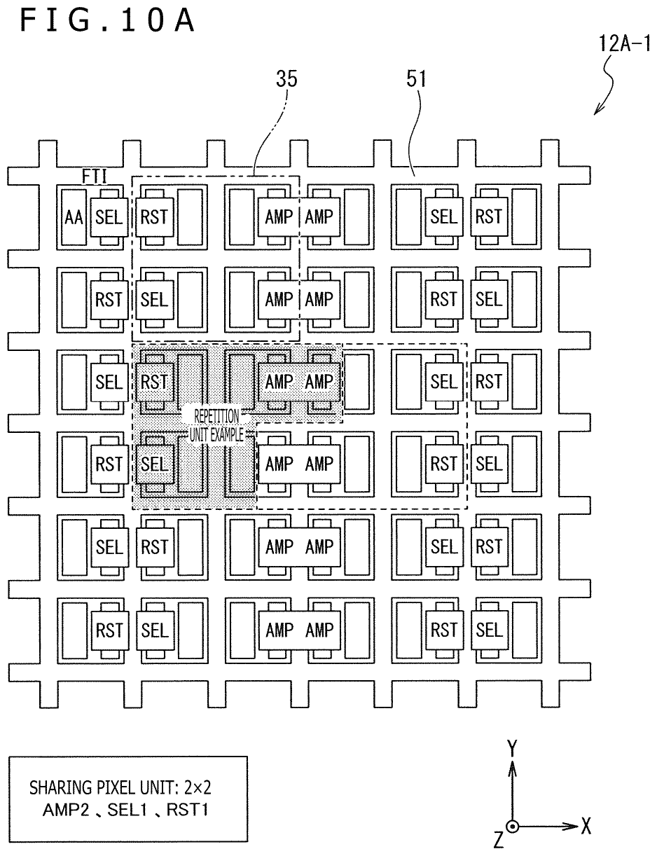

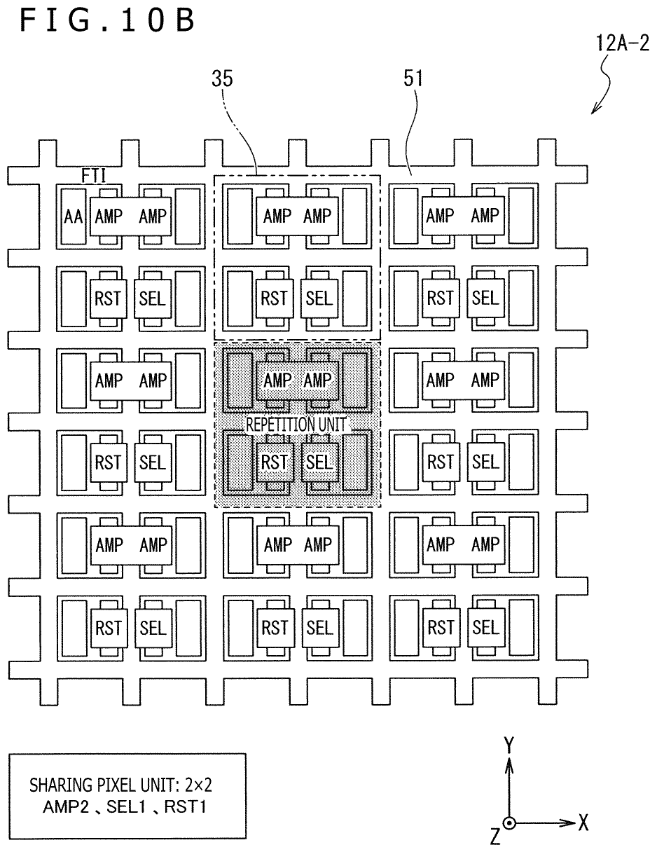

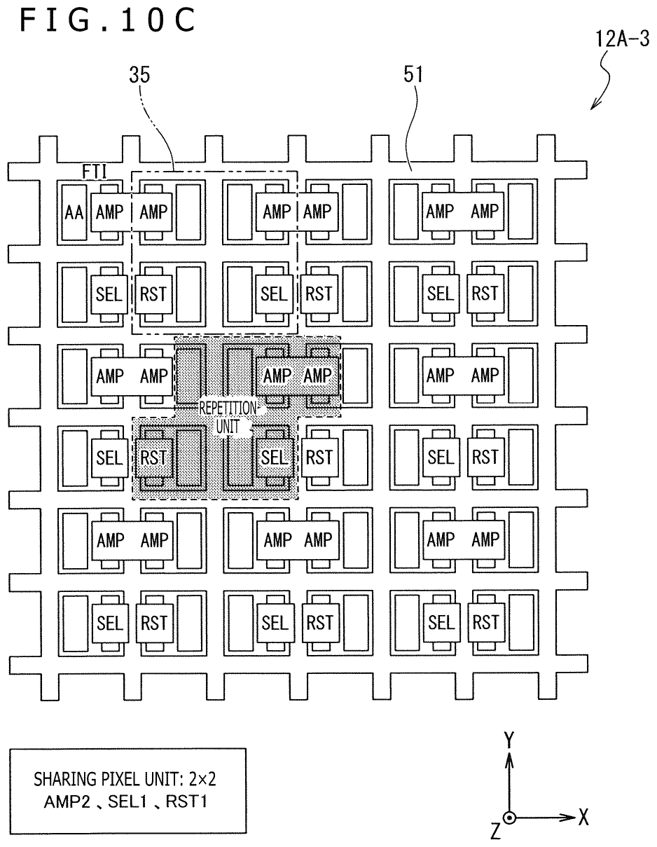

FIG. 10A is a plan view schematically depicting a configuration of a pixel area 12A-1 according to the modification example 1-1 of the first embodiment of the present disclosure. As depicted in FIG. 10A, in the pixel area 12A-1 according to the modification example 1-1, the gate electrodes of each pair of amplification transistors AMP that are adjacent to each other in the X-axis direction are integrated.

In addition, the gate electrodes of selection transistors SEL in one sharing pixel unit 35 and another sharing pixel unit 35 that are adjacent to each other in the X-axis direction are not integrated, and also the gate electrodes of reset transistors RST of the one sharing pixel unit 35 and the other sharing pixel unit 35 are not integrated.

In the pixel area 12A-1, a reset transistor RST in one sharing pixel unit 35 and a selection transistor SEL in another sharing pixel unit 35 adjacent to the one sharing pixel unit 35 in the X-axis direction are arranged adjacent to each other with the inter-pixel separating section 51 being interposed therebetween. Note that, in the pixel area 12A-1, the external shape (double-dotted line) of each sharing pixel unit 35 in a plan view and the external shape (dotted line) of each repetition unit of the arrangement of pixel transistors in the plan view do not match.

### (1-2) Modification Example 1-2

FIG. 10B is a plan view schematically depicting a configuration of a pixel area 12A-2 according to the modification example 1-2 of the first embodiment of the present disclosure. As depicted in FIG. 10B, in the pixel area 12A-2 according to the modification example 1-2, the gate electrodes of each pair of amplification transistors AMP that are adjacent to each other in the X-axis direction are integrated.

As depicted in FIG. 10B, also in the pixel area 12A-2, the gate electrodes of selection transistors SEL in one sharing pixel unit 35 and another sharing pixel unit 35 that are adjacent to each other in the X-axis direction are not integrated, and also the gate electrodes of reset transistors RST of the one sharing pixel unit 35 and the other sharing pixel unit 35 are not integrated. In the pixel area 12A-2, a selection transistor SEL and a reset transistor RST are arranged adjacent to each other with the inter-pixel separating section 51 being interposed therebetween in each sharing pixel unit 35. Note that, in the pixel area 12A-2, the external shape (double-dotted line) of each sharing pixel unit 35 in a plan view and the external shape (dotted line) of each repetition unit of the arrangement of pixel transistors in the plan view match.

### (1-3) Modification Example 1-3

FIG. 10C is a plan view schematically depicting a configuration of a pixel area 12A-3 according to the modification example 1-3 of the first embodiment of the present disclosure. As depicted in FIG. 10C, in the pixel area 12A-3 according to the modification example 1-3, the gate electrodes of each pair of amplification transistors AMP that are adjacent to each other in the X-axis direction are integrated.

As depicted in FIG. 10C, also in the pixel area 12A-3, the gate electrodes of selection transistors SEL in one sharing pixel unit 35 and another sharing pixel unit 35 that are adjacent to each other in the X-axis direction are not integrated, and also the gate electrodes of reset transistors RST of the one sharing pixel unit 35 and the other sharing pixel unit 35 are not integrated. In the pixel area 12A-3, a reset transistor RST in one sharing pixel unit 35 and a selection transistor SEL in another sharing pixel unit 35 adjacent to the one sharing pixel unit 35 in the X-axis direction are arranged adjacent to each other with the inter-pixel separating section 51 being interposed therebetween.

In addition, amplification transistors AMP and other pixel transistors (selection transistors SEL, reset transistors RST) are arranged next to each other alternately in the Y-axis direction (column direction).

### (2) Modification Example 2

For example, as depicted in FIG. 3 and FIG. 4, amplification transistors AMP are arranged next to each other in the Y-axis direction (column direction) in the aspect depicted in the first embodiment described above. In addition, selection transistors SEL and reset transistors RST are arranged next to each other alternately in the Y-axis direction (column direction) in the aspect depicted. However, embodiments of the present disclosure are not limited to this. For example, configurations like ones in modification examples 2-1 to 2-4 depicted below may be adopted. Also with such configurations, as in the first embodiment described above, parasitic capacitance generated between vias 62 and between wires 61 (e.g., refer to FIG. 6) can be reduced, and deterioration of the performance of the image-capturing apparatus 1 can be reduced.

Note that the configuration of each sharing pixel unit 35 in the modification examples 2-1 to 2-4 are 2×2-type configurations. Each sharing pixel unit 35 has two amplification transistors AMP, one selection transistor SEL, and one reset transistor RST, as pixel transistors.

### (2-1) Modification Example 2-1

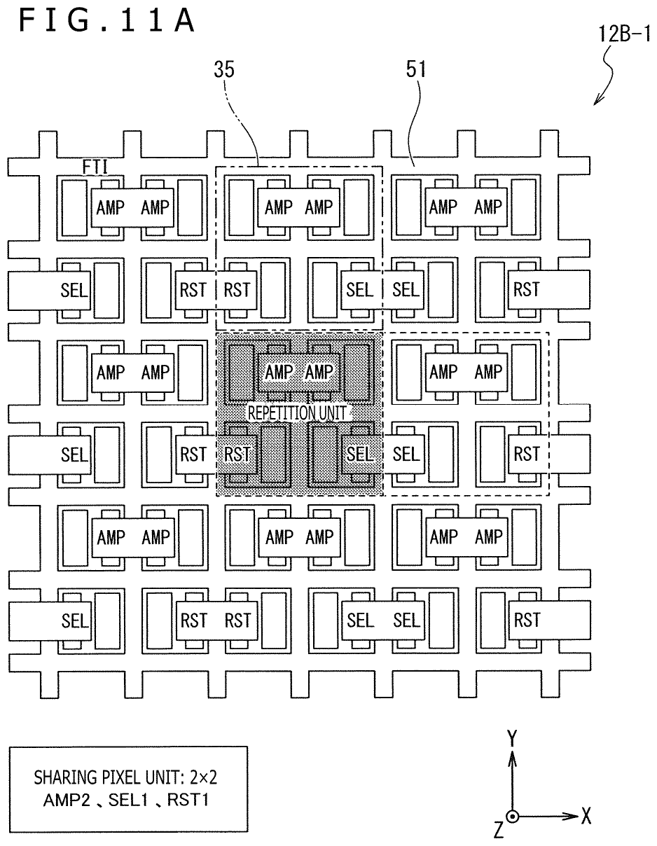

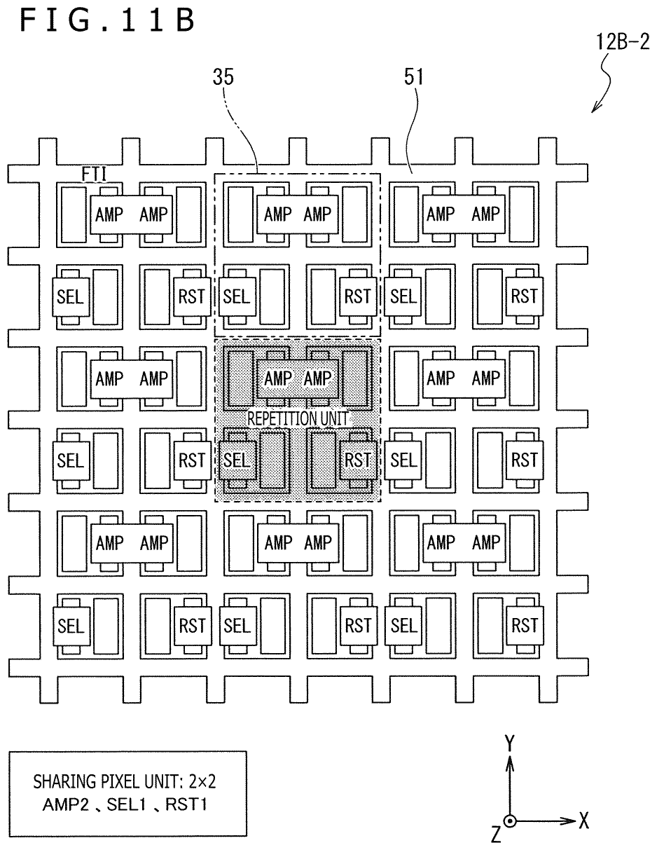

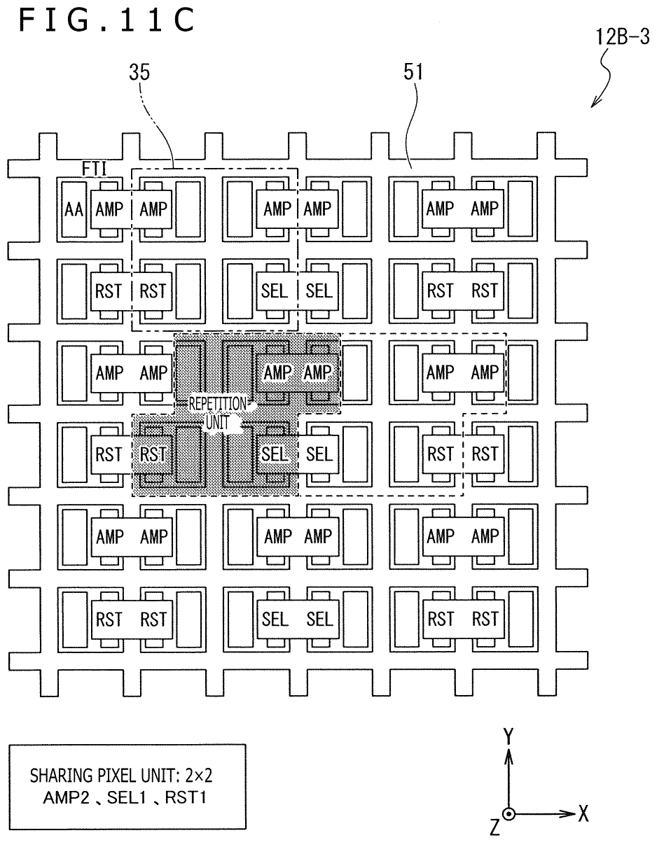

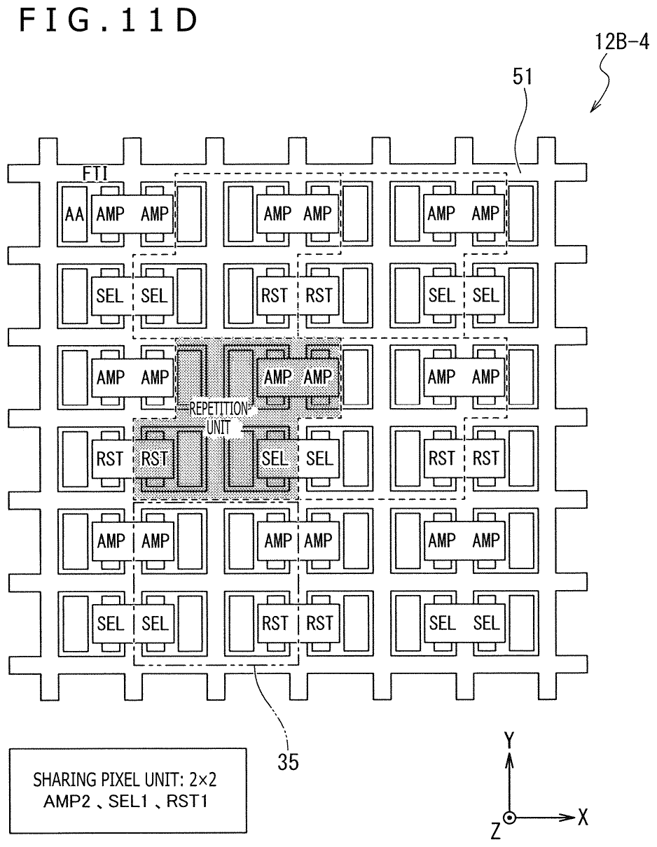

FIG. 11A is a plan view schematically depicting a configuration of a pixel area 12B-1 according to the modification example 2-1 of the first embodiment of the present disclosure. As depicted in FIG. 11A, in the pixel area 12B-1 according to the modification example 2-1, the gate electrodes of each pair of pixel transistors (each pair of amplification transistors AMP, each pair of selection transistors SEL, each pair of reset transistors RST) that are adjacent to each other in the X-axis direction are integrated.

As depicted in FIG. 11A, in the pixel area 12B-1, columns in which amplification transistors AMP are next to each other in the Y-axis direction, columns in which selection transistors SEL are next to each other in the Y-axis direction, and columns in which reset transistors RST are next to each other in the Y-axis direction are provided. The columns in which selection transistors SEL are next to each other in the Y-axis direction and the columns in which reset transistors RST are next to each other in the Y-axis direction are arranged being displaced by one line relative to the columns in which amplification transistors AMP are next to each other in the Y-axis direction.

### (2-2) Modification Example 2-2

FIG. 11B is a plan view schematically depicting a configuration of a pixel area 12B-2 according to the modification example 2-2 of the first embodiment of the present disclosure. As depicted in FIG. 11B, in the pixel area 12B-2 according to the modification example 2-2, the gate electrodes of each pair of amplification transistors AMP that are adjacent to each other in the X-axis direction are integrated.

As depicted in FIG. 11B, in the pixel area 12B-2, the gate electrodes of one pixel transistor (e.g., a selection transistor SEL) and another pixel transistor (e.g., a reset transistor RST) that are adjacent to each other in the X-axis direction, except for the gate electrodes of amplification transistors AMP, are arranged adjacent to each other but not integrated.

### (2-3) Modification Example 2-3

FIG. 11C is a plan view schematically depicting a configuration of a pixel area 12B-3 according to the modification example 2-3 of the first embodiment of the present disclosure. As depicted in FIG. 11C, in the pixel area 12B-3 according to the modification example 2-3, the gate electrodes of each pair of pixel transistors (each pair of amplification transistors AMP, each pair of selection transistors SEL, each pair of reset transistors RST) that are adjacent to each other in the X-axis direction are integrated.

As depicted in FIG. 11C, in the pixel area 12B-3, columns in which amplification transistors AMP and selection transistors SEL are next to each other alternately in the Y-axis direction and columns in which amplification transistors AMP and reset transistors RST are next to each other alternately in the Y-axis direction are provided. Accordingly, the external shape of each repetition unit of the arrangement of pixel transistors is a shape different from that of the repetition units in the pixel areas 12B-1 and 12B-2.

### (2-4) Modification Example 2-4

FIG. 11D is a plan view schematically depicting a configuration of a pixel area 12B-4 according to the modification example 2-4 of the first embodiment of the present disclosure. As depicted in FIG. 11D, in the pixel area 12B-4 according to the modification example 2-4, the gate electrodes of each pair of pixel transistors (each pair of amplification transistors AMP, each pair of selection transistors SEL, each pair of reset transistors RST) that are adjacent to each other in the X-axis direction are integrated.

As depicted in FIG. 11D, in the pixel area 12B-4, amplification transistors AMP, selection transistors SEL, amplification transistors AMP, and reset transistors RST are arranged next to each other in this order in the Y-axis direction. Accordingly, the external shape of each repetition unit of the arrangement of pixel transistors is a shape different from that of the repetition units in the pixel areas 12B-1 and 12B-2 depicted in FIG. 11A and FIG. 11B.

### (3) Modification Example 3

In embodiments of the present disclosure, pixel transistors may have switch transistors FDG that switch the charge conversion efficiency of amplification transistors AMP. For example, configurations like ones in modification examples 3-1 and 3-2 depicted below may be adopted. The configuration of each sharing pixel unit 35 in the modification examples 3-1 and 3-2 is a 2×2-type configuration. Each sharing pixel unit 35 has one amplification transistor AMP, one selection transistor SEL, one reset transistor RST, and one switch transistor FDG, as pixel transistors.

Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

### (3-1) Modification Example 3-1

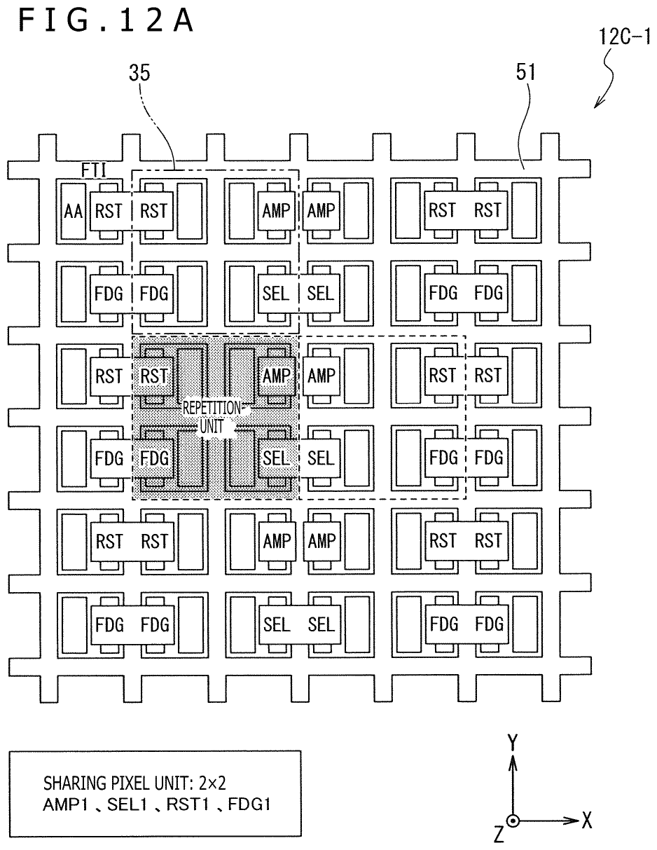

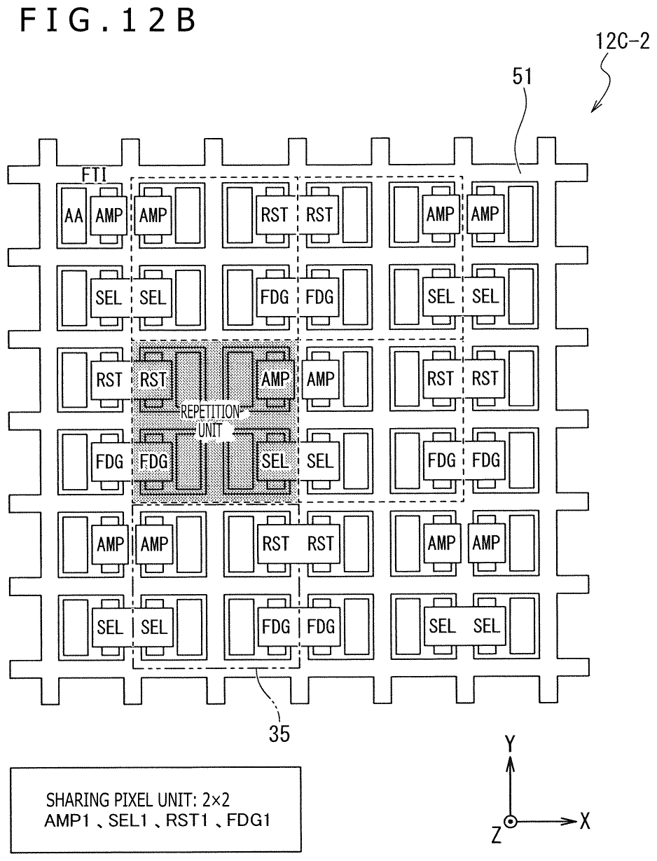

FIG. 12A is a plan view schematically depicting a configuration of a pixel area 12C-1 according to the modification example 3-1 of the first embodiment of the present disclosure. As depicted in FIG. 12A, in the pixel area 12C-1 according to the modification example 3-1, the gate electrodes of each pair of selection transistors SEL that are adjacent to each other in the X-axis direction, the gate electrodes of each pair of reset transistors RST that are adjacent to each other in the X-axis direction, and the gate electrodes of each pair of switch transistors FDG that are adjacent to each other in the X-axis direction are integrated.

In addition, in the pixel area 12C-1, the gate electrodes of switch transistors FDG in one sharing pixel unit 35 and another sharing pixel unit 35 that are adjacent to each other in the X-axis direction are integrated via an upper portion of the inter-pixel separating section 51.

Meanwhile, the gate electrodes of amplification transistors AMP in one sharing pixel unit 35 and another sharing pixel unit 35 that are adjacent to each other in the X-axis direction are not integrated.

As depicted in FIG. 12A, in the pixel area 12C-1, columns in which amplification transistors AMP and selection transistors SEL are next to each other alternately in the Y-axis direction and columns in which reset transistors RST and switch transistors FDG are next to each other alternately in the Y-axis direction are provided.

### (3-2) Modification Example 3-2

FIG. 12B is a plan view schematically depicting a configuration of a pixel area 12C-2 according to the modification example 3-2 of the first embodiment of the present disclosure. As depicted in FIG. 12B, in the pixel area 12C-2 according to the modification example 3-2, the gate electrodes of each pair of selection transistors SEL that are adjacent to each other in the X-axis direction, the gate electrodes of each pair of reset transistors RST that are adjacent to each other in the X-axis direction, and the gate electrodes of each pair of switch transistors FDG that adjacent to each other in the X-axis direction are integrated. The gate electrodes of each pair of amplification transistors AMP that are adjacent to each other in the X-axis direction are not integrated.

As depicted in FIG. 12B, in the pixel area 12C-2, amplification transistors AMP, selection transistors SEL, reset transistors RST, and switch transistors FDG are arranged next to each other in this order in the Y-axis direction. Accordingly, the external shape of each repetition unit of the arrangement of pixel transistors is a shape different from that of the repetition units in the pixel area 12C-1 depicted in FIG. 12A.

### (4) Modification Example 4

In embodiments of the present disclosure, the configuration of each sharing pixel unit 35 is not limited to a 2×2-type configuration. For example, each sharing pixel unit 35 may share eight pixel transistors in total including amplification transistors AMP, selection transistors SEL, and reset transistors RST.

For example, in modification examples 4-1 to 4-6 depicted below, each sharing pixel unit 35 has eight pixel transistors in total, which are four amplification transistors AMP, two selection transistors SEL, and two reset transistors RST. The configuration of each sharing pixel unit 35 is a 4×2-type configuration in which these eight pixel transistors in total are arranged in four lines in the horizontal direction (e.g., the X-axis direction) in a plan view and are arranged in two lines in the vertical direction (e.g., the Y-axis direction) in the plan view. Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

Note that, whereas all eight pixel transistors in total included in each sharing pixel unit 35 are incorporated into a circuit in examples depicted in the following modification examples 4-1 to 4-6, some of the eight pixel transistors in total may not be incorporated into a circuit, and may be dummy transistors.

### (4-1) Modification Example 4-1

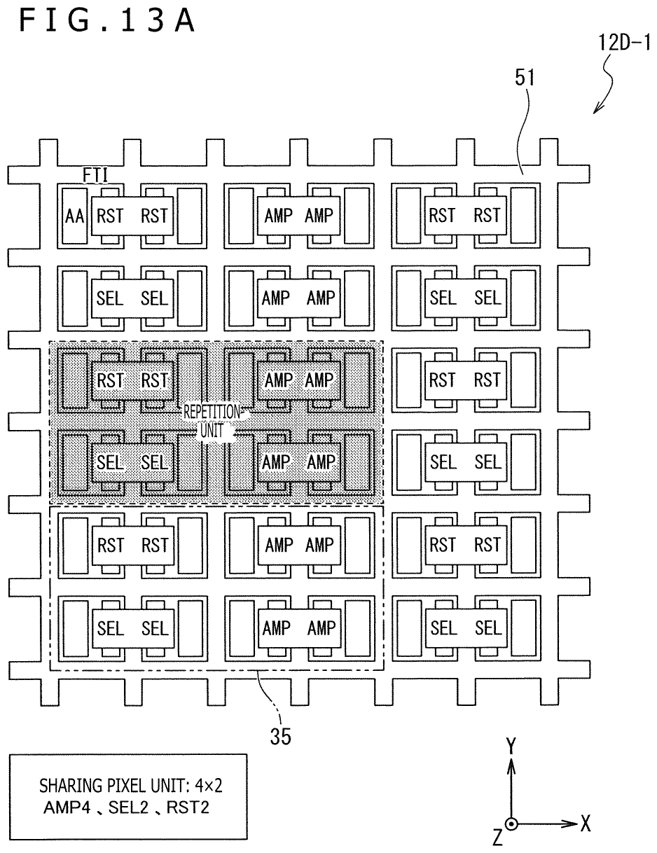

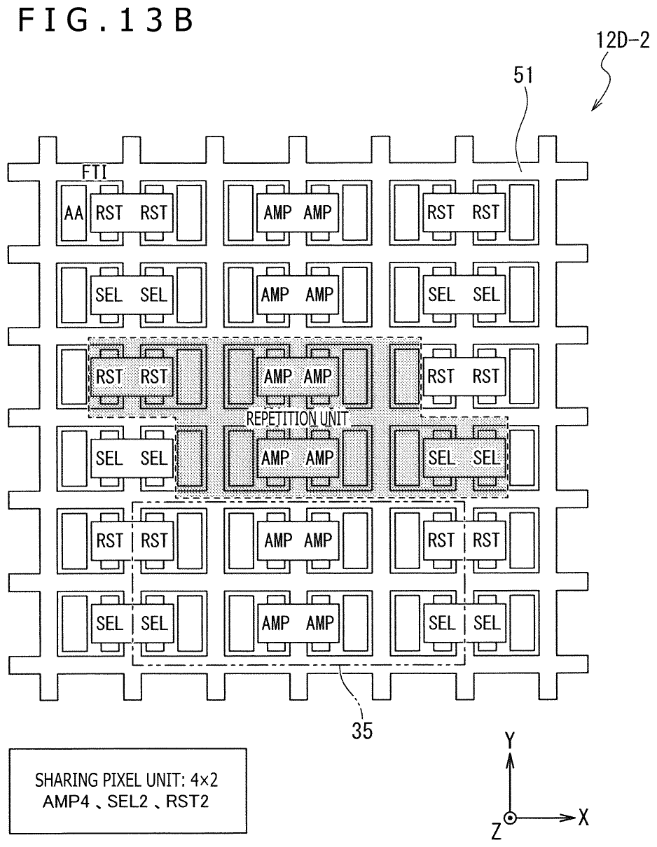

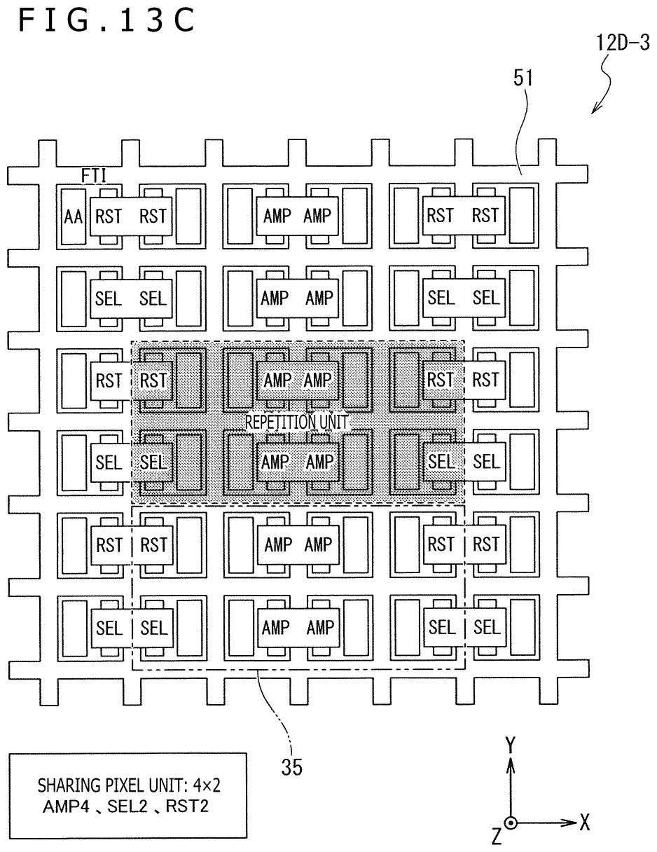

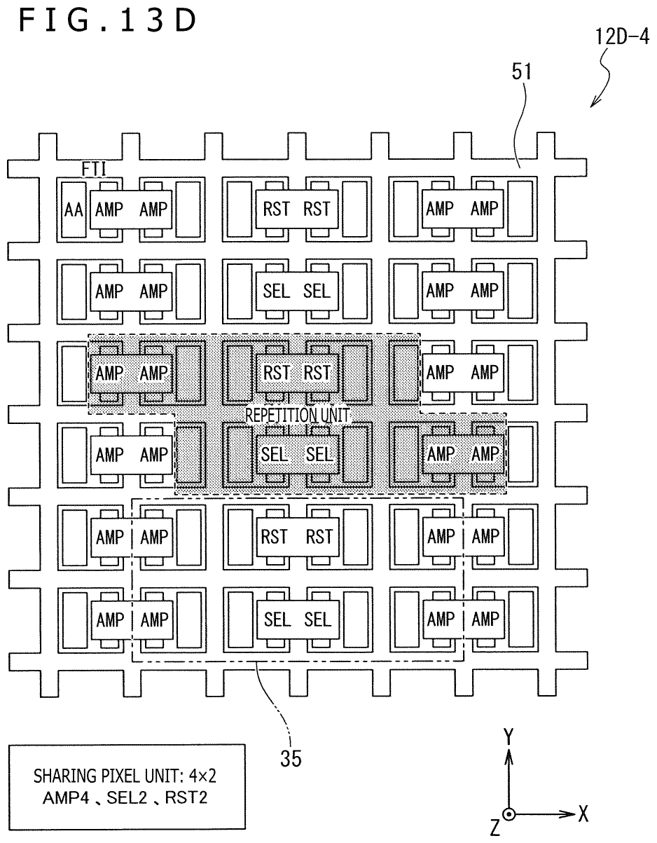

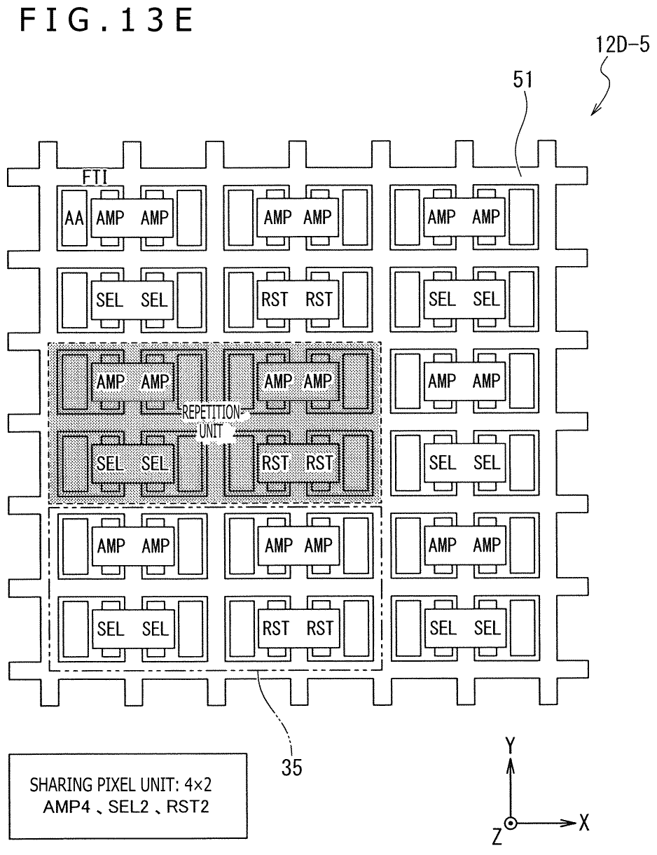

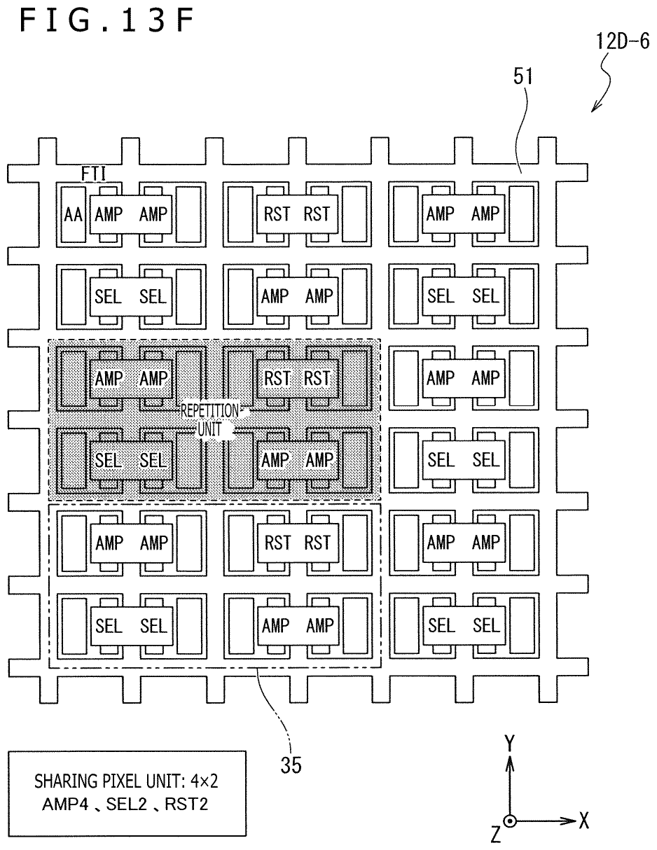

FIG. 13A is a plan view schematically depicting a configuration of a pixel area 12D-1 according to the modification example 4-1 of the first embodiment of the present disclosure. As depicted in FIG. 13A, in the pixel area 12D-1 according to the modification example 4-1, the gate electrodes of each pair of pixel transistors (each pair of amplification transistors AMP, each pair of selection transistors SEL, each pair of reset transistors RST) that are adjacent to each other in the X-axis direction are integrated.

### (4-2) Modification Example 4-2

FIG. 13B is a plan view schematically depicting a configuration of a pixel area 12D-2 according to the modification example 4-2 of the first embodiment of the present disclosure. As depicted in FIG. 13B, in the pixel area 12D-2 according to the modification example 4-2, the external shape of each repetition unit of the arrangement of pixel transistors is a shape different from that of the pixel area 12D-1 depicted in FIG. 13A.

### (4-3) Modification Example 4-3

FIG. 13C is a plan view schematically depicting a configuration of a pixel area 12D-3 according to the modification example 4-3 of the first embodiment of the present disclosure. As depicted in FIG. 13C, in the pixel area 12D-3 according to the modification example 4-3, the external shape of each repetition unit of the arrangement of pixel transistors is a shape different from that of the pixel area 12D-1 depicted in FIG. 13A.

### (4-4) Modification Example 4-4

FIG. 13D is a plan view schematically depicting a configuration of a pixel area 12D-4 according to the modification example 4-4 of the first embodiment of the present disclosure. As depicted in FIG. 13D, in the pixel area 12D-4 according to the modification example 4-4, the external shape of each repetition unit of the arrangement of pixel transistors is a shape different from that of the pixel area 12D-1 depicted in FIG. 13A.

### (4-5) Modification Example 4-5

FIG. 13E is a plan view schematically depicting a configuration of a pixel area 12D-5 according to the modification example 4-5 of the first embodiment of the present disclosure. As depicted in FIG. 13E, in the pixel area 12D-5 according to the modification example 4-5, columns in which amplification transistors AMP and selection transistors SEL are next to each other alternately in the Y-axis direction and columns in which amplification transistors AMP and reset transistors RST are next to each other alternately in the Y-axis direction are provided. With attention paid to the arrangement in the X-axis direction (rows), rows in which only amplification transistors AMP are next to each other and rows in which selection transistors SEL and reset transistors RST are next to each other alternately are provided.

### (4-6) Modification Example 4-6

FIG. 13F is a plan view schematically depicting a configuration of a pixel area 12D-6 according to the modification example 4-6 of the first embodiment of the present disclosure. As depicted in FIG. 13F, in the pixel area 12D-6 according to the modification example 4-6, columns in which amplification transistors AMP and selection transistors SEL are next to each other alternately in the Y-axis direction and columns in which amplification transistors AMP and reset transistors RST are next to each other alternately in the Y-axis direction are provided. With attention paid to the arrangement in the X-axis direction (rows), rows in which amplification transistors AMP and selection transistors SEL are next to each other alternately and rows in which amplification transistors AMP and reset transistors RST are next to each other alternately are provided.

### (5) Modification Example 5

Also in a case where the configuration of each sharing pixel unit 35 is a 4×2-type configuration, an (n+1)-th column (n is an integer equal to or greater than one) of pixel transistors that are next to each other in the Y-axis direction may be arranged being displaced by one line relative to an n-th column of pixel transistors that are next to each other in the Y-axis direction. For example, configurations like ones in modification examples 5-1 to 5-3 depicted below may be adopted. The configuration of each sharing pixel unit 35 in the modification examples 5-1 to 5-3 is a 4×2-type configuration. Each sharing pixel unit 35 has four amplification transistors AMP, two selection transistors SEL, and two reset transistors RST, as pixel transistors. Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

### (5-1) Modification Example 5-1

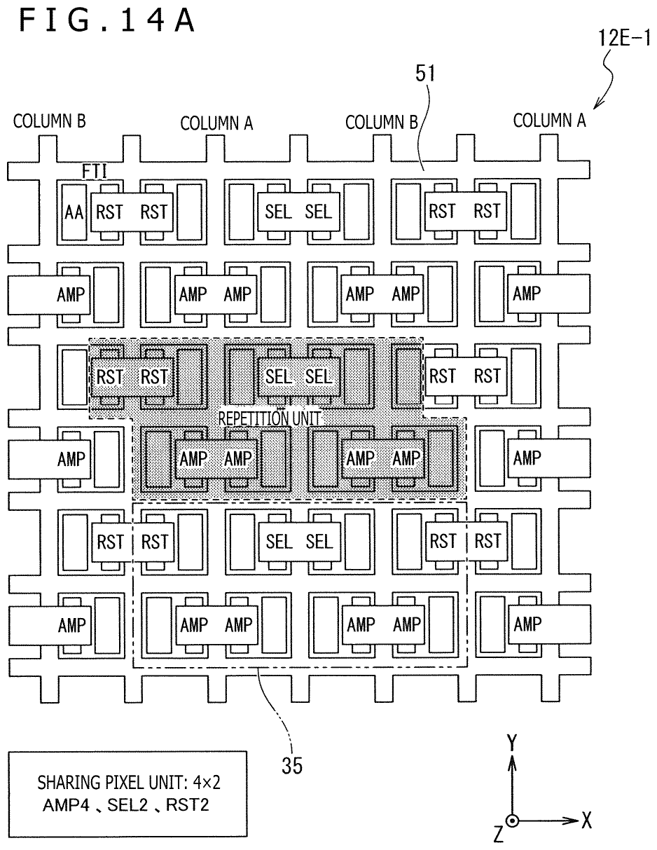

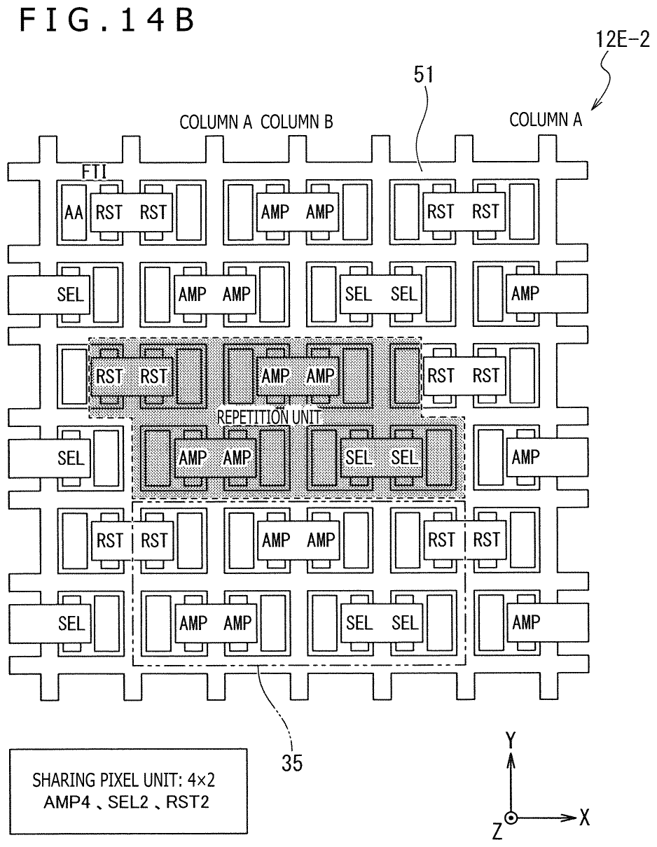

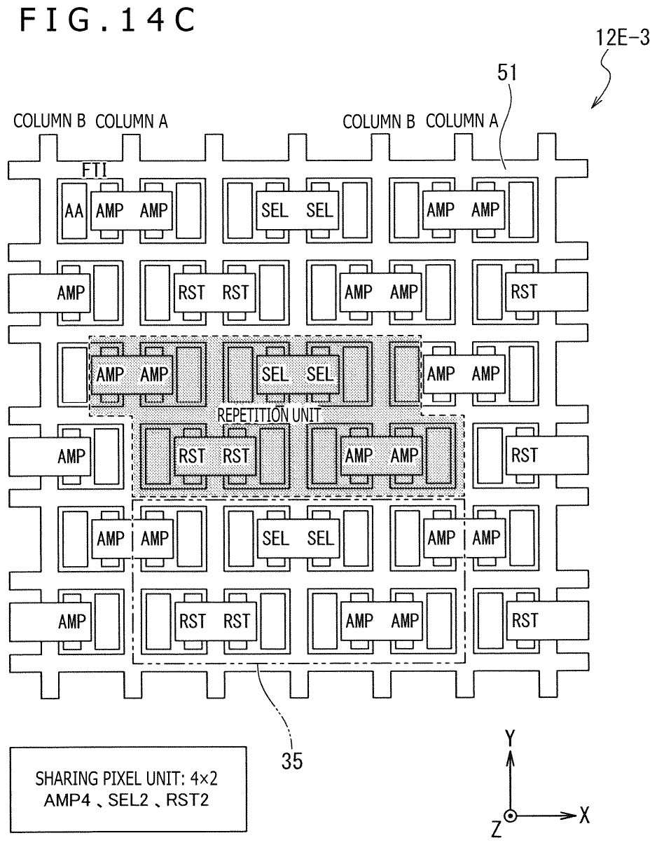

FIG. 14A is a plan view schematically depicting a configuration of a pixel area 12E-1 according to the modification example 5-1 of the first embodiment of the present disclosure. As depicted in FIG. 14A, in the pixel area 12E-1 according to the modification example 5-1, the gate electrodes of each pair of pixel transistors (each pair of amplification transistors AMP, each pair of selection transistors SEL, each pair of reset transistors RST) that are adjacent to each other in the X-axis direction are integrated.

As depicted in FIG. 14A, in the pixel area 12E-1, columns A and columns B in which amplification transistors AMP are next to each other in the Y-axis direction, columns in which selection transistors SEL are next to each other in the Y-axis direction, and columns in which reset transistors RST are next to each other in the Y-axis direction are provided. The columns in which selection transistors SEL are next to each other in the Y-axis direction and the columns in which reset transistors RST are next to each other in the Y-axis direction are arranged being displaced by one line relative to the columns A and columns B in which amplification transistors AMP are next to each other in the Y-axis direction.

In addition, the columns A in which amplification transistors AMP are next to each other in the Y-axis direction, the columns in which selection transistors SEL are next to each other in the Y-axis direction, the columns B in which amplification transistors AMP are next to each other in the Y-axis direction, and the columns in which reset transistors RST are next to each other in the Y-axis direction are arranged next to each other repeatedly in this order in the X-axis direction.

### (5-2) Modification Example 5-2

FIG. 14B is a plan view schematically depicting a configuration of a pixel area 12E-2 according to the modification example 5-2 of the first embodiment of the present disclosure. As depicted in FIG. 14B, in the pixel area 12E-2 according to the modification example 5-2, the columns B in which amplification transistors AMP are next to each other in the Y-axis direction and the columns in which reset transistors RST are next to each other in the Y-axis direction are arranged being displaced by one line relative to the columns A in which amplification transistors AMP are next to each other in the Y-axis direction and the columns in which selection transistors SEL are next to each other in the Y-axis direction.

In addition, the columns A in which amplification transistors AMP are next to each other in the Y-axis direction, the columns B in which amplification transistors AMP are next to each other in the Y-axis direction, the columns in which selection transistors SEL are next to each other in the Y-axis direction, and the columns in which reset transistors RST are next to each other in the Y-axis direction are arranged next to each other repeatedly in this order in the X-axis direction.

### (5-3) Modification Example 5-3

FIG. 14C is a plan view schematically depicting a configuration of a pixel area 12E-3 according to the modification example 5-3 of the first embodiment of the present disclosure. As depicted in FIG. 14C, in the pixel area 12E-3 according to the modification example 5-3, the columns B in which amplification transistors AMP are next to each other in the Y-axis direction and the columns in which reset transistors RST are next to each other in the Y-axis direction are arranged being displaced by one line relative to the columns A in which amplification transistors AMP are next to each other in the Y-axis direction and the columns in which selection transistors SEL are next to each other in the Y-axis direction.

In addition, the columns A in which amplification transistors AMP are next to each other in the Y-axis direction, the columns in which reset transistors RST are next to each other in the Y-axis direction, the columns in which selection transistors SEL are next to each other in the Y-axis direction, and the columns B in which amplification transistors AMP are next to each other in the Y-axis direction are arranged next to each other repeatedly in this order in the X-axis direction.

### (6) Modification Example 6

Also in a case where the configuration of each sharing pixel unit 35 is a 4×2-type configuration, pixel transistors may have switch transistors FDG that switch the charge conversion efficiency of amplification transistors AMP. For example, configurations like ones in modification examples 6-1 to 6-6 depicted below may be adopted.

The configuration of each sharing pixel unit 35 in the modification examples 6-1 to 6-6 is a 4×2-type configuration. In the modification examples 6-1 and 6-2, each sharing pixel unit 35 has two amplification transistors AMP, two selection transistors SEL, two reset transistors RST, and two switch transistors FDG, as pixel transistors. In the modification examples 6-3 to 6-6, each sharing pixel unit 35 has four amplification transistors AMP, two selection transistors SEL, one reset transistor RST, and one switch transistor FDG, as pixel transistors. Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

### (6-1) Modification Example 6-1

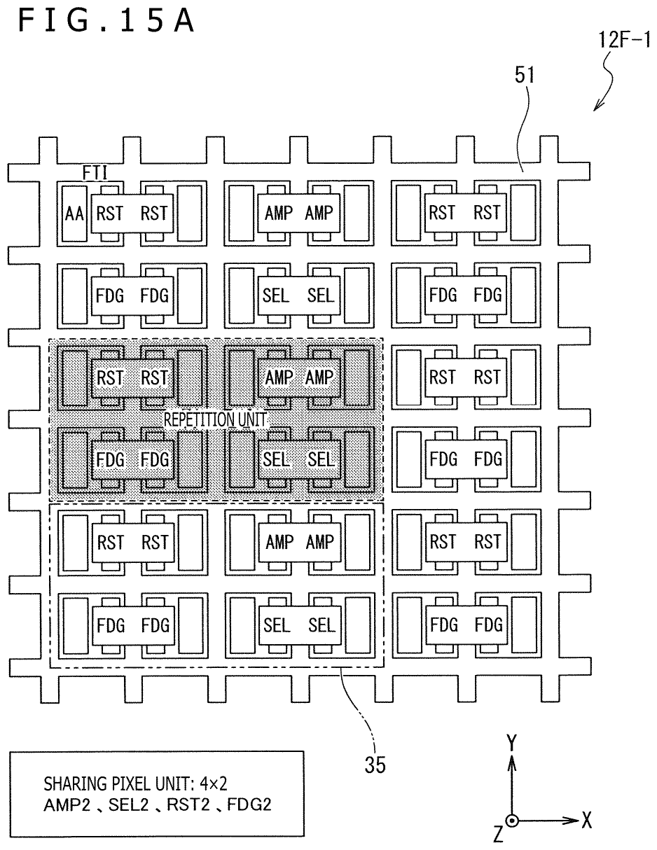

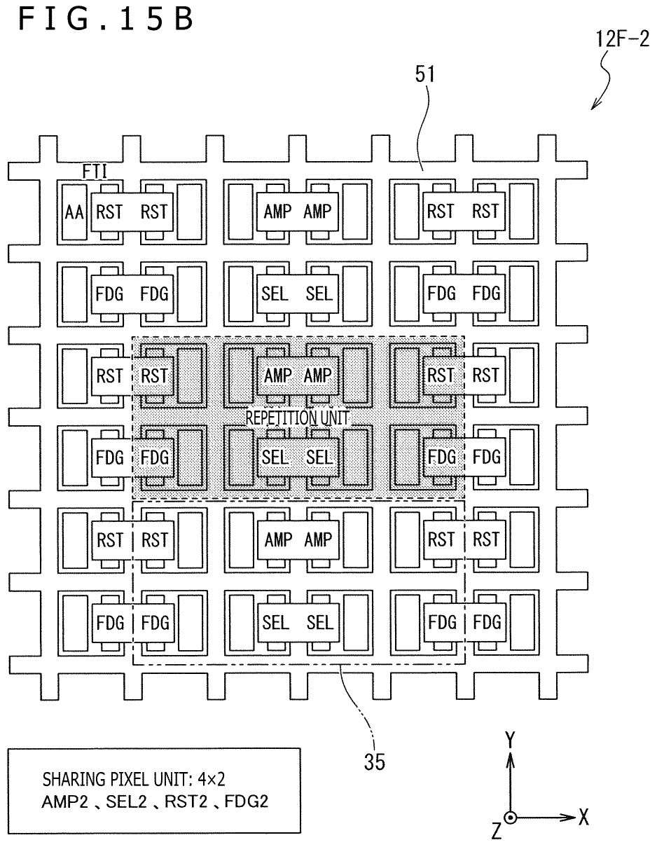

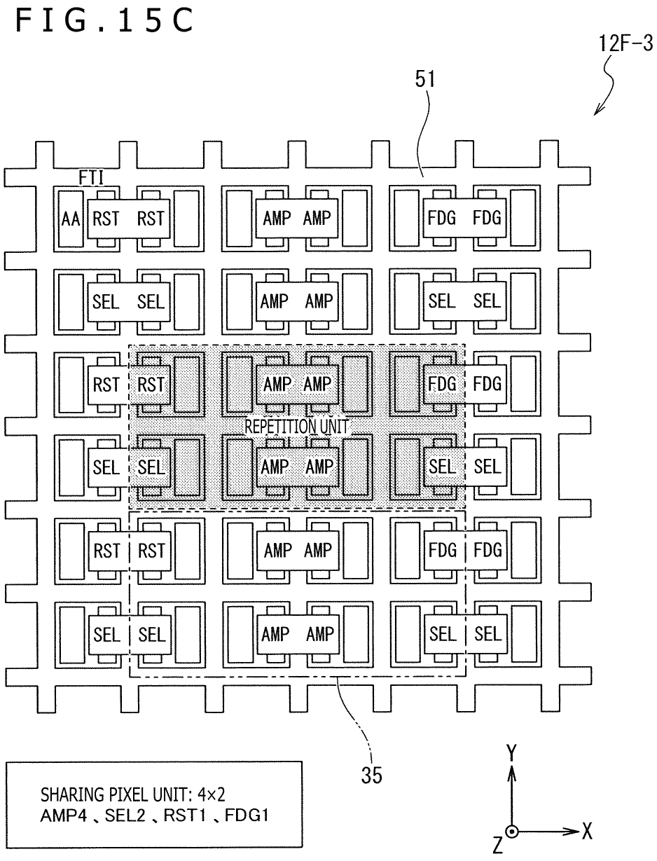

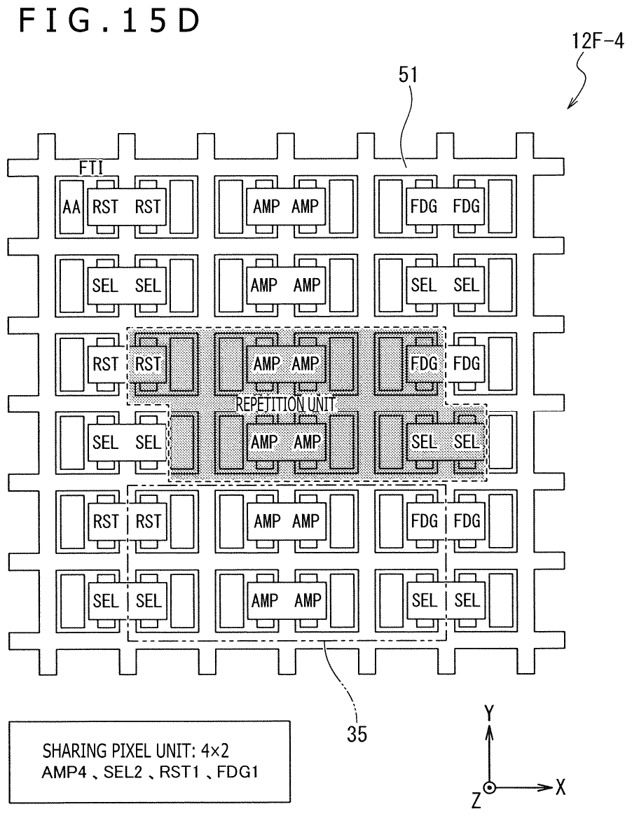

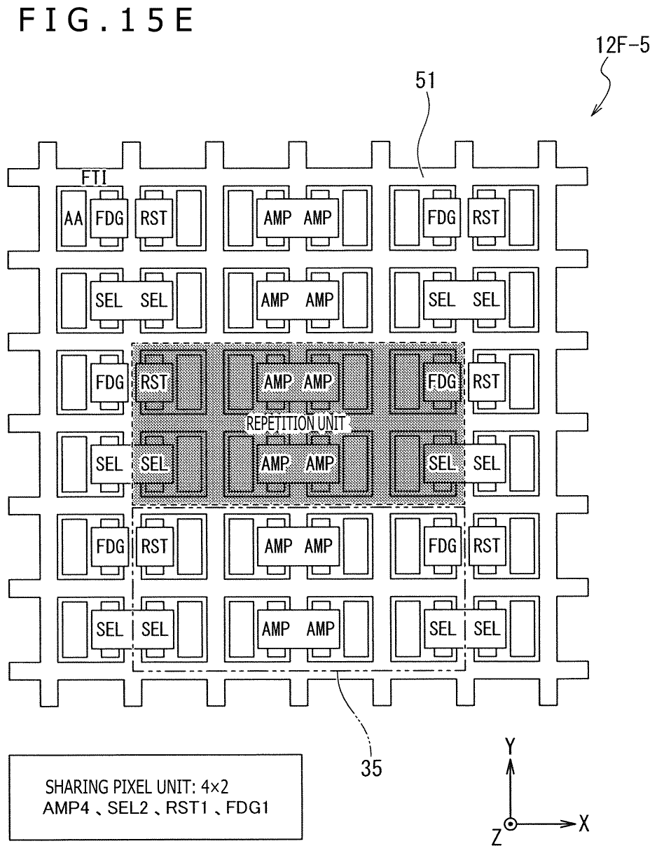

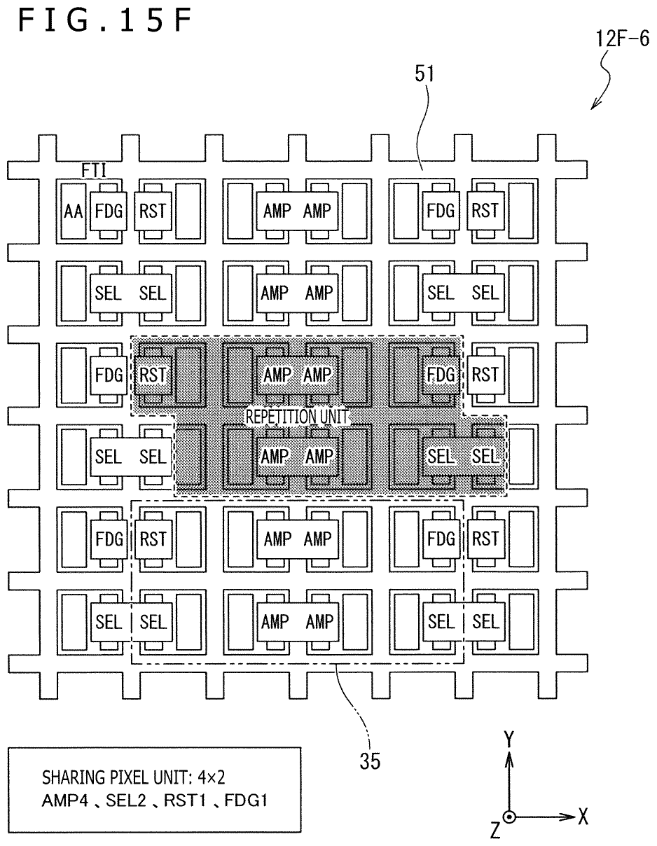

FIG. 15A is a plan view schematically depicting a configuration of a pixel area 12F-1 according to the modification example 6-1 of the first embodiment of the present disclosure. As depicted in FIG. 15A, in the pixel area 12F-1 according to the modification example 6-1, the gate electrodes of each pair of pixel transistors (each pair of amplification transistors AMP, each pair of selection transistors SEL, each pair of reset transistors RST, each pair of switch transistors FDG) that are adjacent to each other in the X-axis direction are integrated.

### (6-2) Modification Example 6-2

FIG. 15B is a plan view schematically depicting a configuration of a pixel area 12F-2 according to the modification example 6-2 of the first embodiment of the present disclosure. As depicted in FIG. 15B, in the pixel area 12F-2 according to the modification example 6-2, the external shape of each repetition unit of the arrangement of pixel transistors is a shape different from that of the pixel area 12F-1 depicted in FIG. 15A.

### (6-3) Modification Example 6-3

FIG. 15C is a plan view schematically depicting a configuration of a pixel area 12F-3 according to the modification example 6-3 of the first embodiment of the present disclosure. As depicted in FIG. 15C, in the pixel area 12F-3 according to the modification example 6-3, the gate electrodes of each pair of pixel transistors (each pair of amplification transistors AMP, each pair of selection transistors SEL, each pair of reset transistors RST, each pair of switch transistors FDG) that are adjacent to each other in the X-axis direction are integrated.

In addition, in the pixel area 12F-3, one repetition unit and another repetition unit that are adjacent to each other in the X-axis direction have layouts that are left-right symmetric about the Y-axis.

### (6-4) Modification Example 6-4

FIG. 15D is a plan view schematically depicting a configuration of a pixel area 12F-4 according to the modification example 6-4 of the first embodiment of the present disclosure. As depicted in FIG. 15D, in the pixel area 12F-4 according to the modification example 6-4, the external shape of each repetition unit of the arrangement of pixel transistors is a shape different from that of the pixel area 12F-3 depicted in FIG. 15C. For example, in the pixel area 12F-3, one repetition unit and another repetition unit that are adjacent to each other in the X-axis direction have layouts in which a reset transistor RST and a switch transistor FDG are replaced with each other.

### (6-5) Modification Example 6-5

FIG. 15E is a plan view schematically depicting a configuration of a pixel area 12F-5 according to the modification example 6-5 of the first embodiment of the present disclosure. As depicted in FIG. 15E, in the pixel area 12F-5 according to the modification example 6-5, reset transistors RST and switch transistors FDG are adjacent to each other in the X-axis direction with the inter-pixel separating section 51 being interposed therebetween. The gate electrodes of a reset transistor RST and a switch transistor FDG that are adjacent to each other in the X-axis direction are not integrated. The gate electrodes of each pair of amplification transistors AMP that are adjacent to each other in the X-axis direction are integrated, and the gate electrodes of each pair of selection transistors that are adjacent to each other in the X-axis direction are integrated.

### (6-6) Modification Example 6-6

FIG. 15F is a plan view schematically depicting a configuration of a pixel area 12F-6 according to the modification example 6-6 of the first embodiment of the present disclosure. As depicted in FIG. 15F, in the pixel area 12F-6 according to the modification example 6-6, the external shape of each repetition unit of the arrangement of pixel transistors is a shape different from that of the pixel area 12F-6 depicted in FIG. 15E.

### Second Embodiment

The configuration of each sharing pixel unit 35 is a 2×2-type configuration or a 4×2-type configuration in the cases explained in the first embodiment and modification examples thereof described above. However, the configuration of each sharing pixel unit 35 is not limited to them in embodiments of the present disclosure.

### Configuration Example

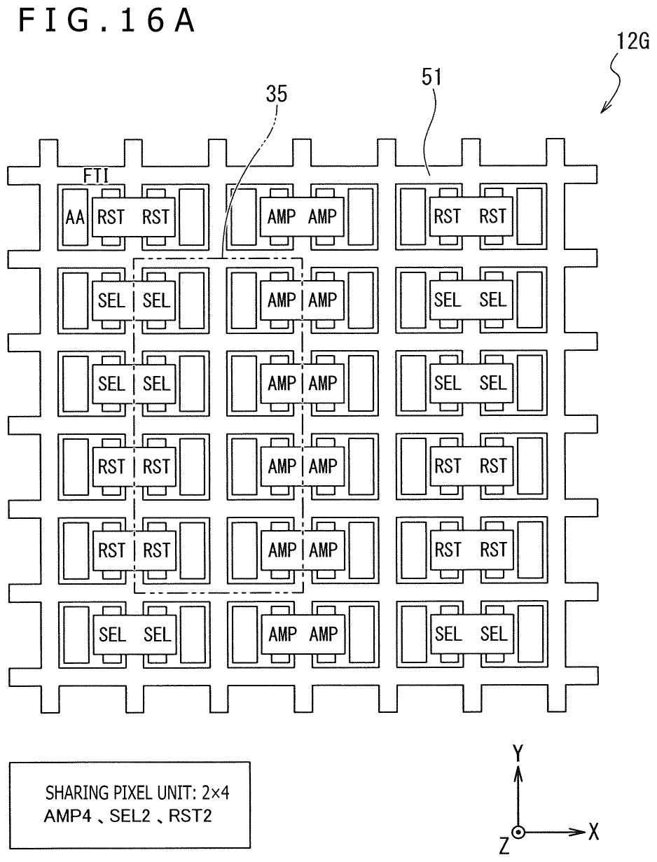

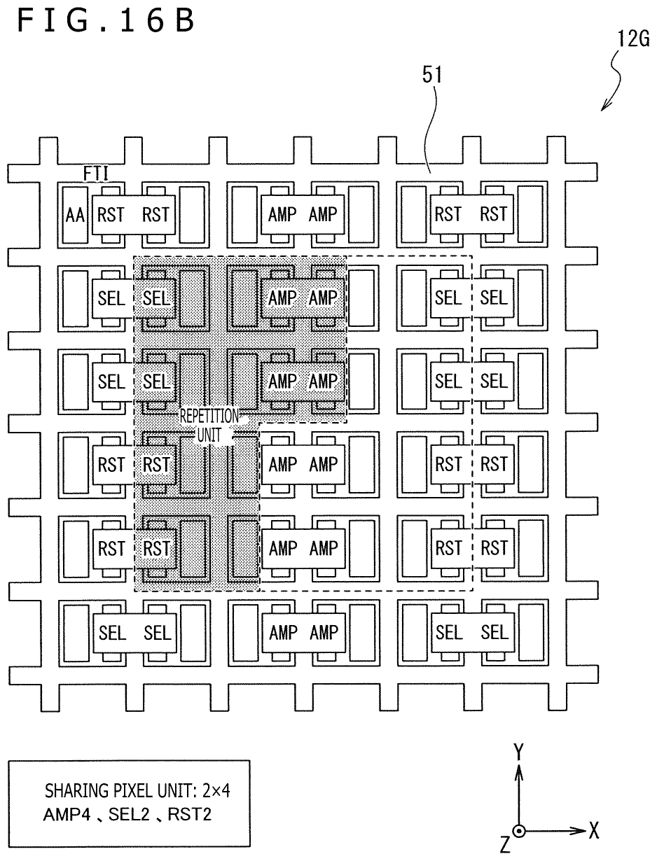

FIG. 16A and FIG. 16B are plan views schematically depicting a configuration example of a pixel area 12G according to the second embodiment of the present disclosure. FIG. 16A illustrates an example of sharing pixel units 35. FIG. 16B illustrates an example of a repetition unit of the arrangement of pixel transistors connected to one sharing pixel unit 35.

As depicted in FIG. 16A, in the pixel area 12G according to the second embodiment, each sharing pixel unit 35 has eight pixel transistors in total, which are four amplification transistors AMP, two selection transistors SEL, and two reset transistors RST. The configuration of each sharing pixel unit 35 may be a 2×4-type configuration in which these eight pixel transistors in total are arranged in two lines in the horizontal direction (e.g., the X-axis direction) in a plan view and are arranged in four lines in the vertical direction (e.g., the Y-axis direction) in the plan view.

As depicted in FIG. 16A and FIG. 16B, in the pixel area 12G, columns in which reset transistors RST, selection transistors SEL, selection transistors SEL, and reset transistors RST are next to each other repeatedly in this order in the Y-axis direction and columns in which amplification transistors AMP are next to each other in the Y-axis direction are provided.

In addition, in the pixel area 12G, the gate electrodes of each pair of pixel transistors (each pair of amplification transistors AMP, each pair of selection transistors SEL, each pair of reset transistors RST) that are adjacent to each other in the X-axis direction are integrated.

### Advantages of Second Embodiment

Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

Note that, also in the pixel area 12G, some of eight pixel transistors in total included in each sharing pixel unit 35 may not be incorporated in a circuit, and may be dummy transistors.

### Modification Examples of Second Embodiment

### (7) Modification Example 7

Configurations like ones in modification examples 7-1 to 7-10 depicted below may be adopted in the second embodiment. The configuration of each sharing pixel unit 35 in the modification examples 7-1 to 7-10 is a 2×4-type configuration. Each sharing pixel unit 35 has four amplification transistors AMP, two selection transistors SEL, and two reset transistors RST, as pixel transistors. Also with such a configuration, as in the first and second embodiments described above, parasitic capacitance generated between vias 62 and between wires 61 (e.g., refer to FIG. 6) can be reduced, and deterioration of the performance of the image-capturing apparatus 1 can be reduced.

Note that, also in the modification examples 7-1 to 7-10 depicted below, some of eight pixel transistors in total included in each sharing pixel unit 35 may not be incorporated in a circuit, and may be dummy transistors.

### (7-1) Modification Example 7-1

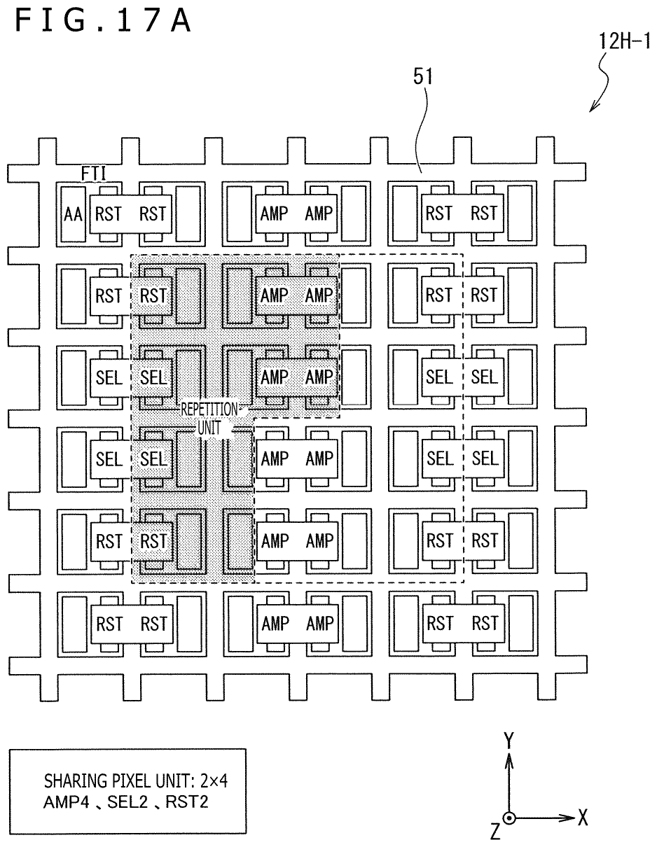

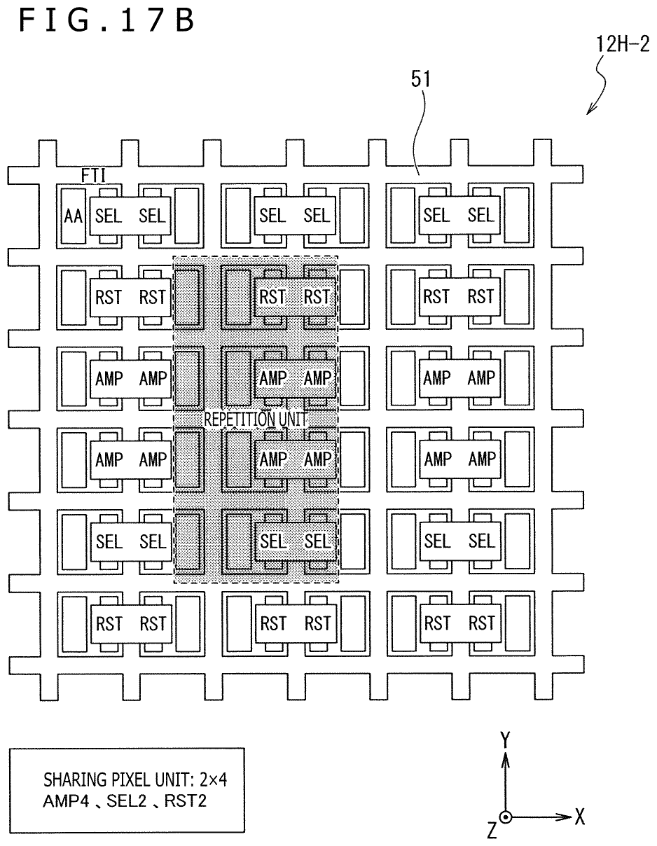

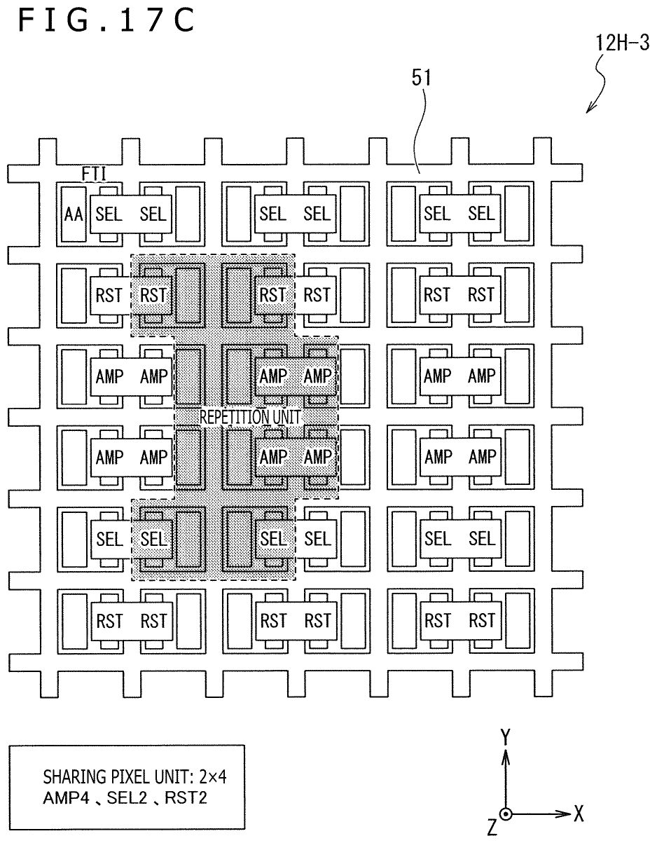

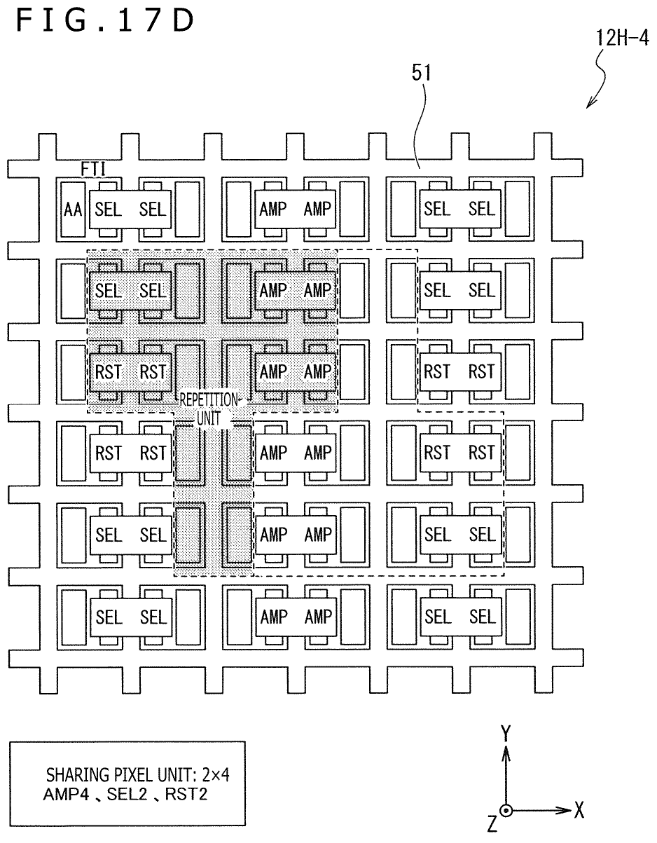

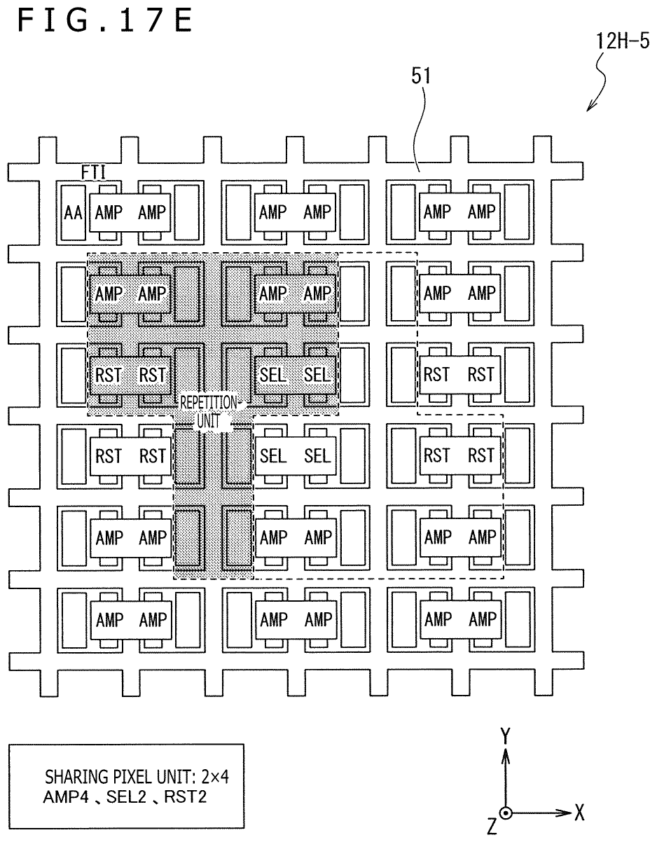

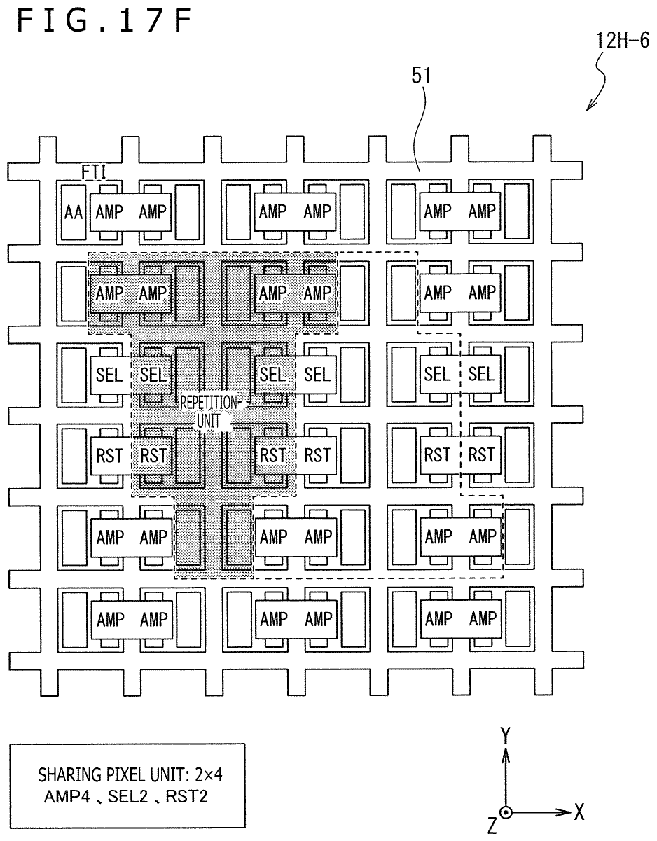

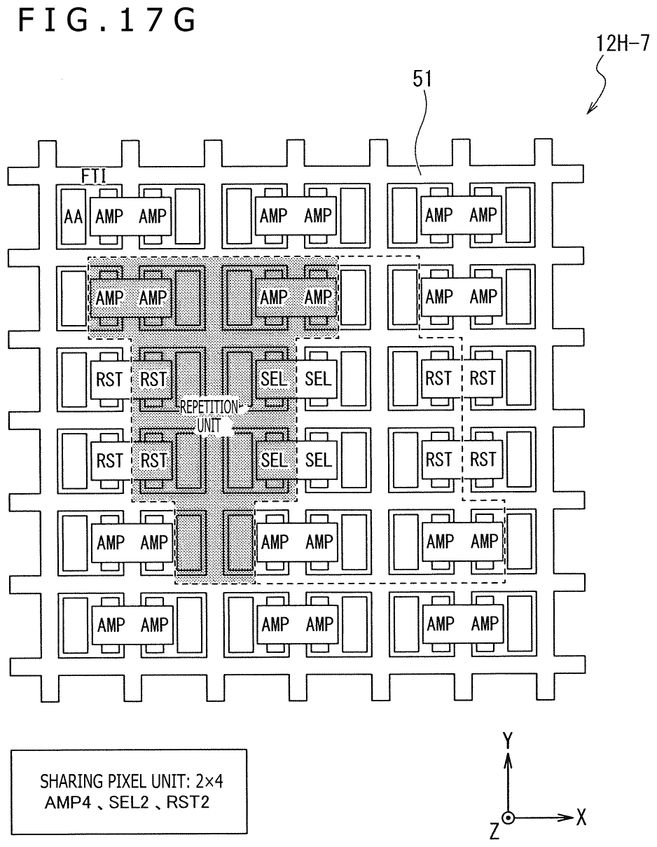

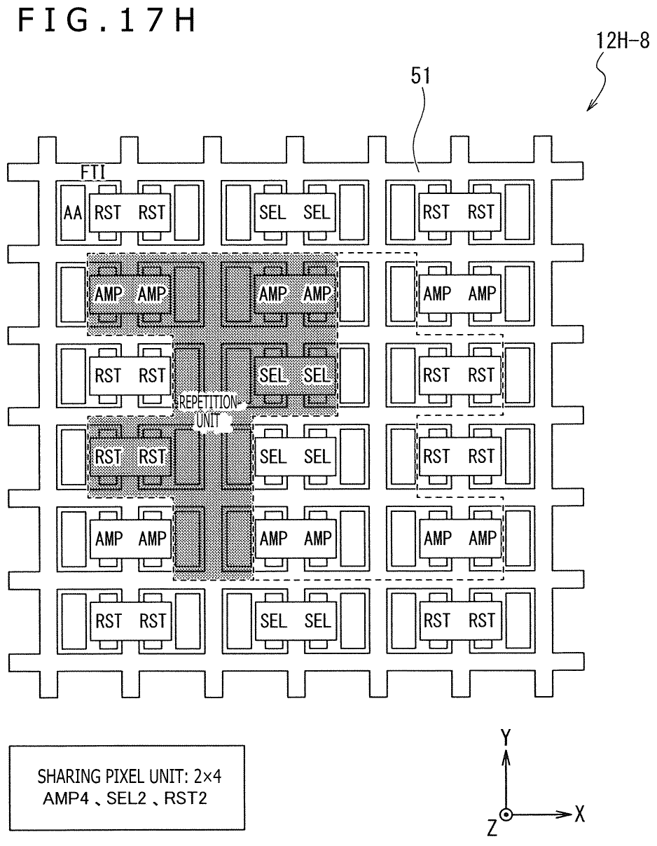

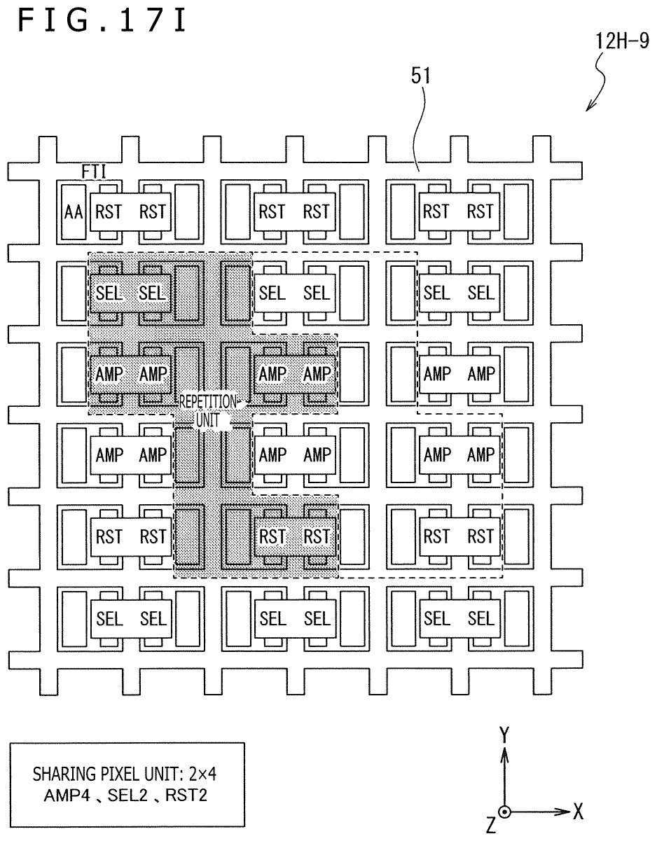

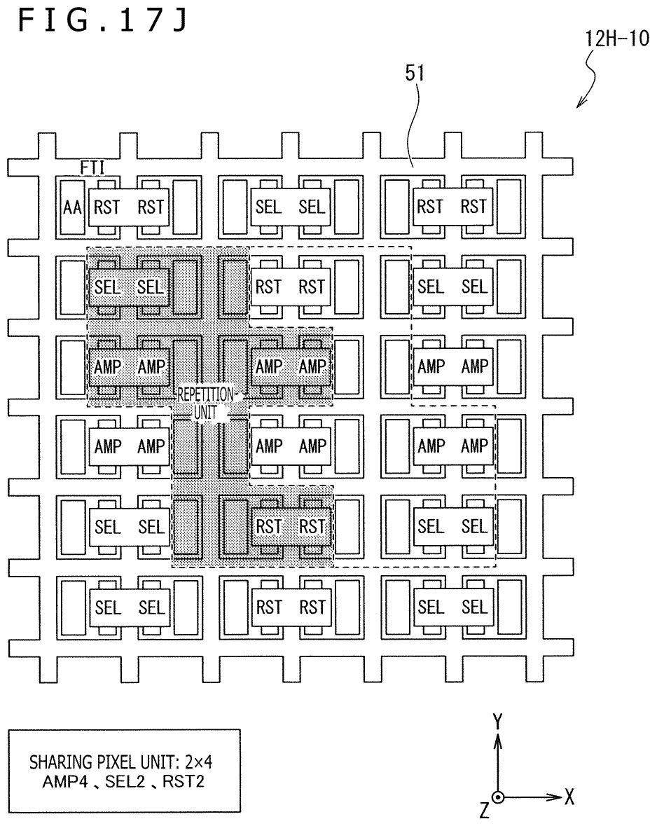

FIG. 17A is a plan view schematically depicting a configuration of a pixel area 12H-1 according to the modification example 7-1 of the second embodiment of the present disclosure. As depicted in FIG. 17A, in the pixel area 12H-1 according to the modification example 7-1, some of the positions of reset transistors RST and selection transistors SEL in each repetition unit are replaced with each other as compared with the pixel area 12G depicted in FIG. 16. The external shape of each repetition unit of the arrangement of pixel transistors is a shape which is the same as that of the pixel area 12G depicted in FIG. 16.

### (7-2) Modification Example 7-2

FIG. 17B is a plan view schematically depicting a configuration of a pixel area 12H-2 according to the modification example 7-2 of the second embodiment of the present disclosure. As depicted in FIG. 17B, in the pixel area 12H-2 according to the modification example 7-2, columns in which reset transistors RST, amplification transistors AMP, amplification transistors AMP, and selection transistors SEL are next to each other repeatedly in this order in the Y-axis direction are provided. The external shape of each repetition unit of the arrangement of pixel transistors is a shape different from that of the pixel area 12H-1 depicted in FIG. 17A.

### (7-3) Modification Example 7-3

FIG. 17C is a plan view schematically depicting a configuration of a pixel area 12H-3 according to the modification example 7-3 of the second embodiment of the present disclosure. As depicted in FIG. 17C, in the pixel area 12H-3 according to the modification example 7-3, the external shape of each repetition unit of the arrangement of pixel transistors is a shape different from that of the pixel area 12H-2 depicted in FIG. 17B.

### (7-4) Modification Example 7-4

FIG. 17D is a plan view schematically depicting a configuration of a pixel area 12H-4 according to the modification example 7-4 of the second embodiment of the present disclosure. As depicted in FIG. 17D, in the pixel area 12H-4 according to the modification example 7-4, the external shape of each repetition unit of the arrangement of pixel transistors is a shape different from those of the pixel area 12H-1 depicted in FIG. 17A, the pixel area 12H-2 depicted in FIG. 17B, and the pixel area 12H-3 depicted in FIG. 17C.

### (7-5) Modification Example 7-5

FIG. 17E is a plan view schematically depicting a configuration of a pixel area 12H-5 according to the modification example 7-5 of the second embodiment of the present disclosure. As depicted in FIG. 17E, in the pixel area 12H-5 according to the modification example 7-5, the positions of selection transistors SEL and amplification transistors AMP in each repetition unit are replaced with each other as compared with the pixel area 12H-4 depicted in FIG. 17D. The external shape of each repetition unit of the arrangement of pixel transistors is a shape which is the same as that of the pixel area 12H-4 depicted in FIG. 17D.

### (7-6) Modification Example 7-6

FIG. 17F is a plan view schematically depicting a configuration of a pixel area 12H-6 according to the modification example 7-6 of the second embodiment of the present disclosure. As depicted in FIG. 17F, in the pixel area 12H-6 according to the modification example 7-6, the external shape of each repetition unit of the arrangement of pixel transistors is a shape different from those of the pixel areas 12H-1 to 12H-5 depicted in FIG. 17A to FIG. 17E.

### (7-7) Modification Example 7-7

FIG. 17G is a plan view schematically depicting a configuration of a pixel area 12H-7 according to the modification example 7-7 of the second embodiment of the present disclosure. As depicted in FIG. 17G, in the pixel area 12H-7 according to the modification example 7-7, some of the positions of selection transistors SEL and amplification transistors AMP in each repetition unit are replaced with each other as compared with the pixel area 12H-6 depicted in FIG. 17F. The external shape of each repetition unit of the arrangement of pixel transistors is a shape which is the same as that of the pixel area 12H-5 depicted in FIG. 17F.

### (7-8) Modification Example 7-8

FIG. 17H is a plan view schematically depicting a configuration of a pixel area 12H-8 according to the modification example 7-8 of the second embodiment of the present disclosure. As depicted in FIG. 17H, in the pixel area 12H-8 according to the modification example 7-8, the external shape of each repetition unit of the arrangement of pixel transistors is a shape different from that of the pixel area 12H-7 depicted in FIG. 17G. As depicted in FIG. 17H, in the pixel area 12H-8 according to the modification example 7-8, the external shape of each repetition unit of the arrangement of pixel transistors is a shape different from those of the pixel areas 12H-1 to 12H-7 depicted in FIG. 17A to FIG. 17G.

### (7-9) Modification Example 7-9

FIG. 17I is a plan view schematically depicting a configuration of a pixel area 12H-9 according to the modification example 7-9 of the second embodiment of the present disclosure. As depicted in FIG. 17I, in the pixel area 12H-9 according to the modification example 7-9, the external shape of each repetition unit of the arrangement of pixel transistors is a shape different from those of the pixel areas 12H-1 to 12H-8 depicted in FIG. 17A to FIG. 17H.

### (7-10) Modification Example 7-10

FIG. 17J is a plan view schematically depicting a configuration of a pixel area 12H-10 according to the modification example 7-10 of the second embodiment of the present disclosure. As depicted in FIG. 17J, in the pixel area 12H-10 according to the modification example 7-10, some of the positions of selection transistors SEL and amplification transistors AMP in each repetition unit are replaced with each other as compared with the pixel area 12H-9 depicted in FIG. 17I. The external shape of each repetition unit of the arrangement of pixel transistors is a shape which is the same as that of the pixel area 12H-9 depicted in FIG. 17I.

### Third Embodiment

Also in a case where the configuration of each sharing pixel unit 35 is a 2×4-type configuration, pixel transistors may have switch transistors FDG that switch the charge conversion efficiency of amplification transistors AMP.

### Configuration Example

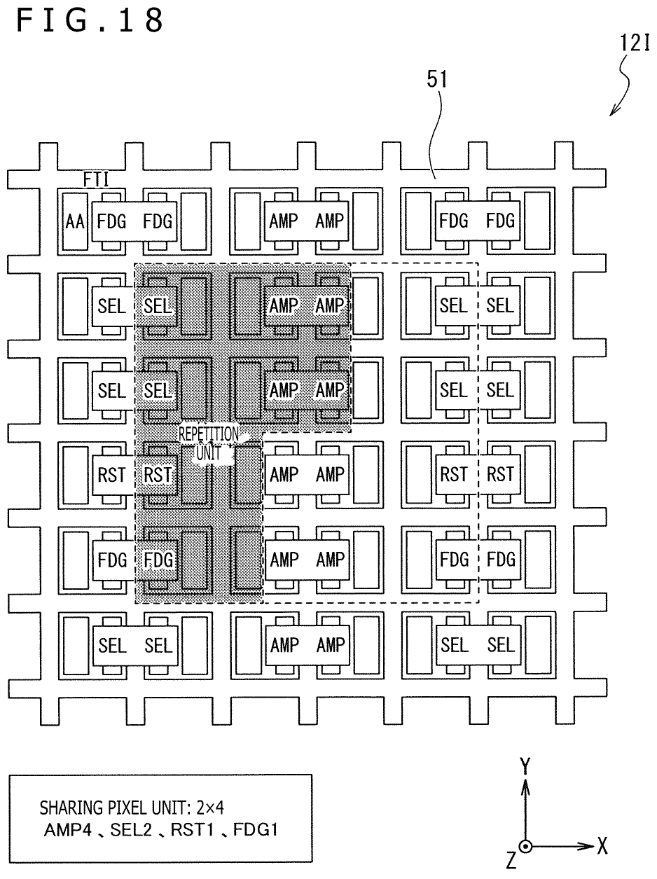

FIG. 18 is a plan view schematically depicting a configuration example of a pixel area 12I according to a third embodiment of the present disclosure. As depicted in FIG. 18, the configuration of each sharing pixel unit 35 in the pixel area 12I is a 2×4-type configuration. Each sharing pixel unit 35 has four amplification transistors AMP, two selection transistors SEL, one reset transistor RST, and one switch transistor FDG, as pixel transistors.

As depicted in FIG. 18, in the pixel area 12I, columns in which switch transistors FDG, selection transistors SEL, selection transistors SEL, and reset transistors RST are next to each other repeatedly in this order in the Y-axis direction and columns in which amplification transistors AMP are next to each other in the Y-axis direction are provided.

In the pixel area 12I, the gate electrodes of each pair of pixel transistors (each pair of amplification transistors AMP, each pair of selection transistors SEL, each pair of reset transistors RST, each pair of switch transistors FDG) that are adjacent to each other in the X-axis direction are integrated.

### Advantages of Third Embodiment

Also with such a configuration, as in the first embodiment described above, parasitic capacitance generated between vias 62 and between wires 61 (e.g., refer to FIG. 6) can be reduced, and deterioration of the performance of the image-capturing apparatus 1 can be reduced.

Note that, also in the pixel area 121, some of eight pixel transistors in total included in each sharing pixel unit 35 may not be incorporated in a circuit, and may be dummy transistors.

### (8) Modification Examples 8

Configurations like ones in modification examples 8-1 to 8-9 depicted below may be adopted in the third embodiment. The configuration of each sharing pixel unit 35 in the modification examples 8-1 to 8-9 is a 2×4-type configuration. Each sharing pixel unit 35 has four amplification transistors AMP, two selection transistors SEL, one reset transistor RST, and one switch transistor FDG, as pixel transistors. Also with such a configuration, as in the first and second embodiments described above, parasitic capacitance generated between vias 62 and between wires 61 (e.g., refer to FIG. 6) can be reduced, and deterioration of the performance of the image-capturing apparatus 1 can be reduced.

Note that, also in the modification examples 8-1 to 8-9 depicted below, some of eight pixel transistors in total included in each sharing pixel unit 35 may not be incorporated in a circuit, and may be dummy transistors.

### (8-1) Modification Example 8-1

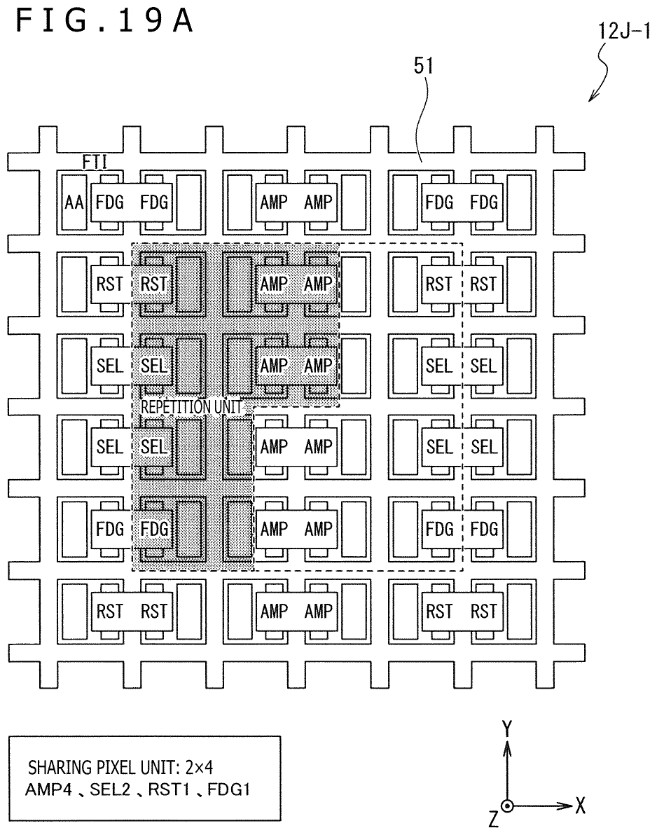

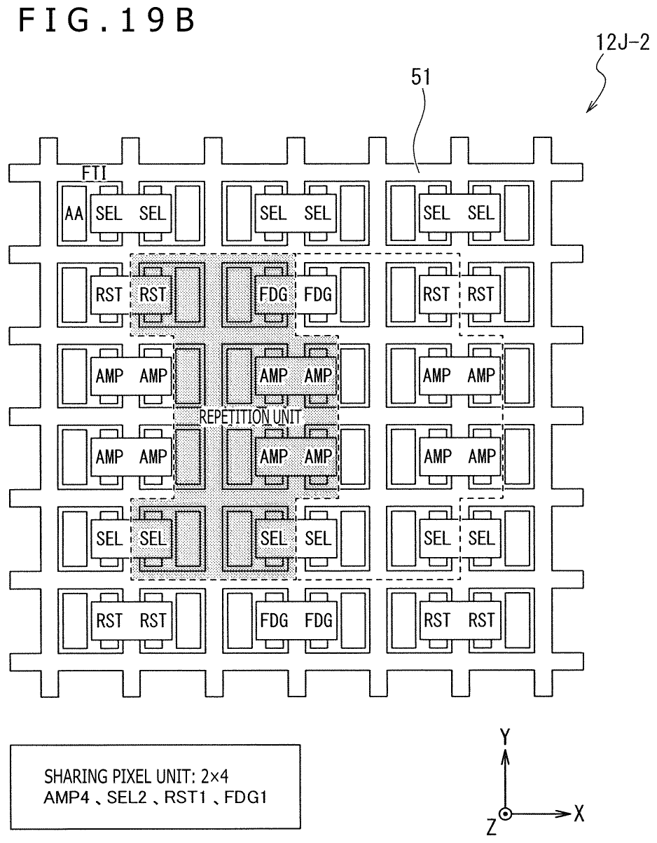

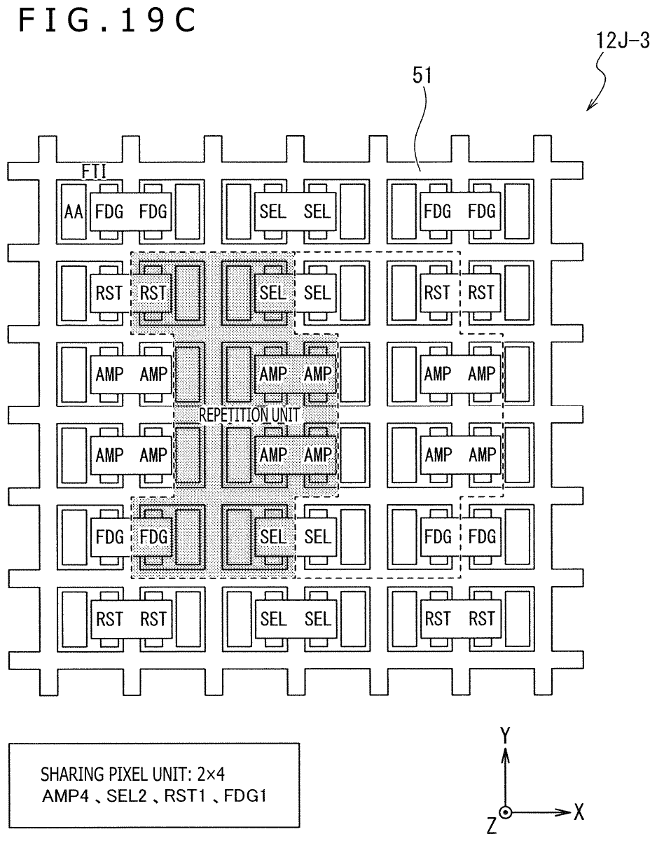

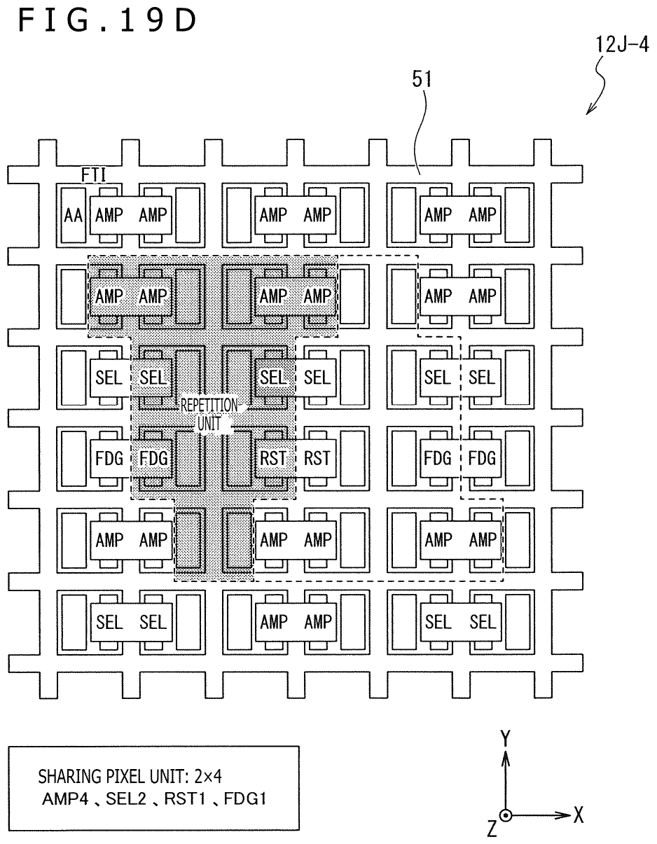

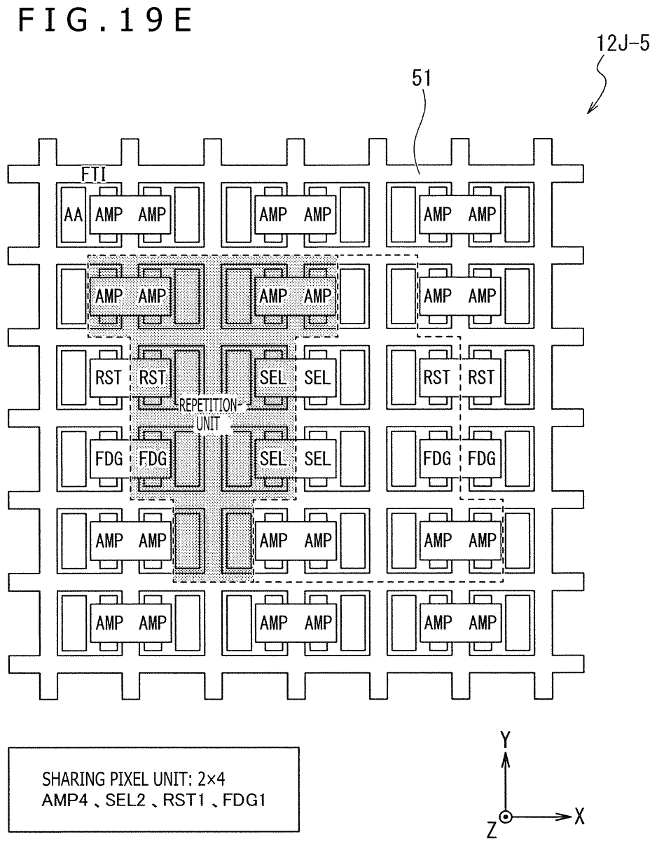

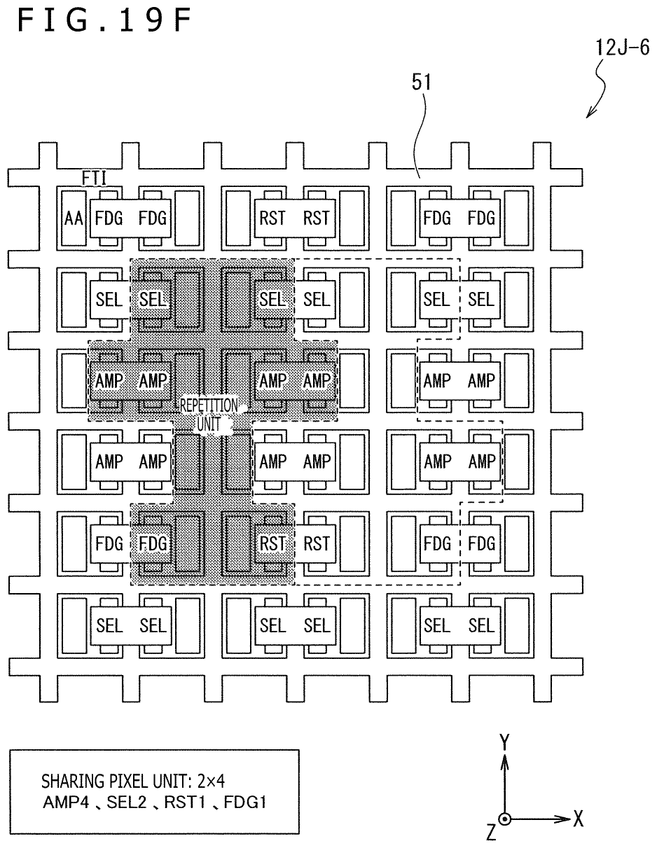

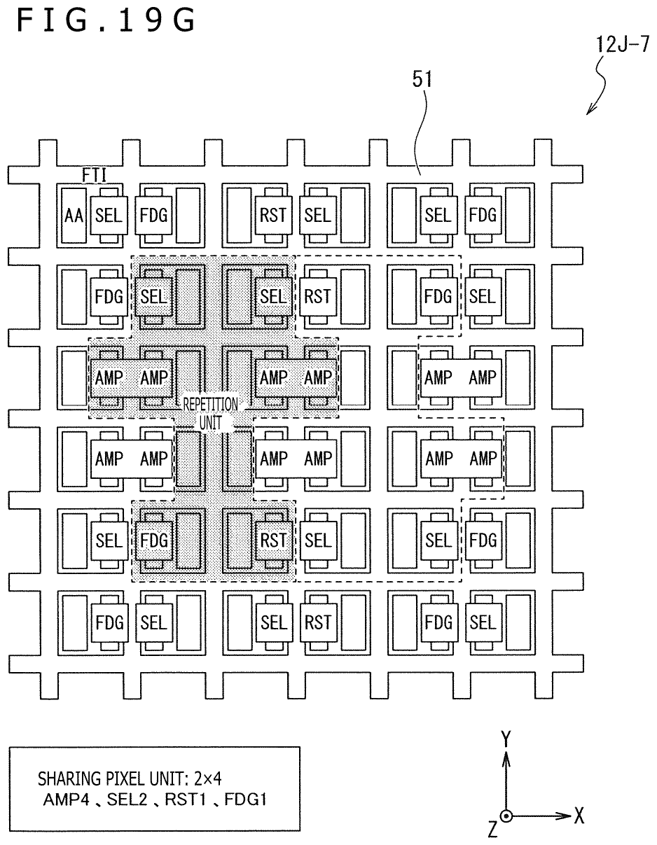

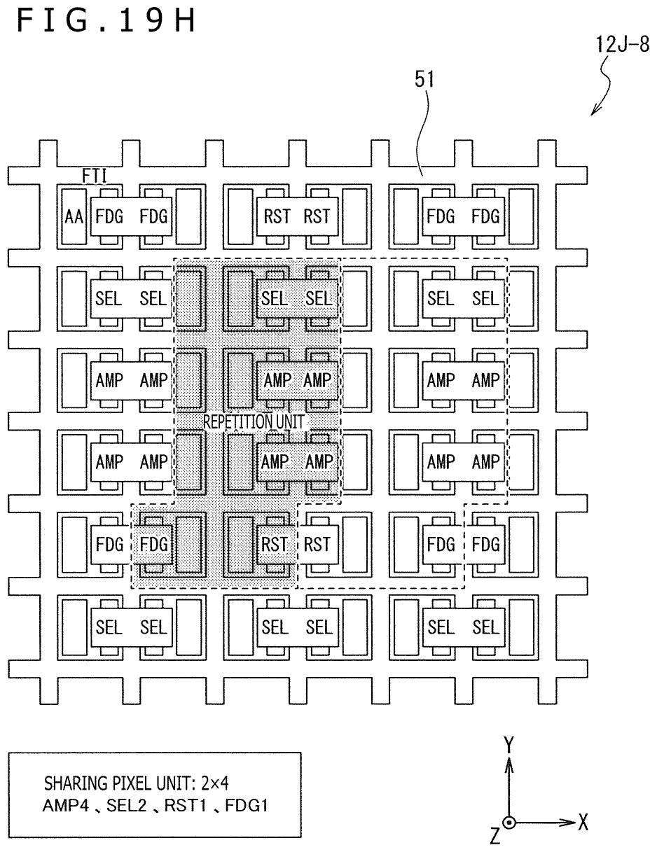

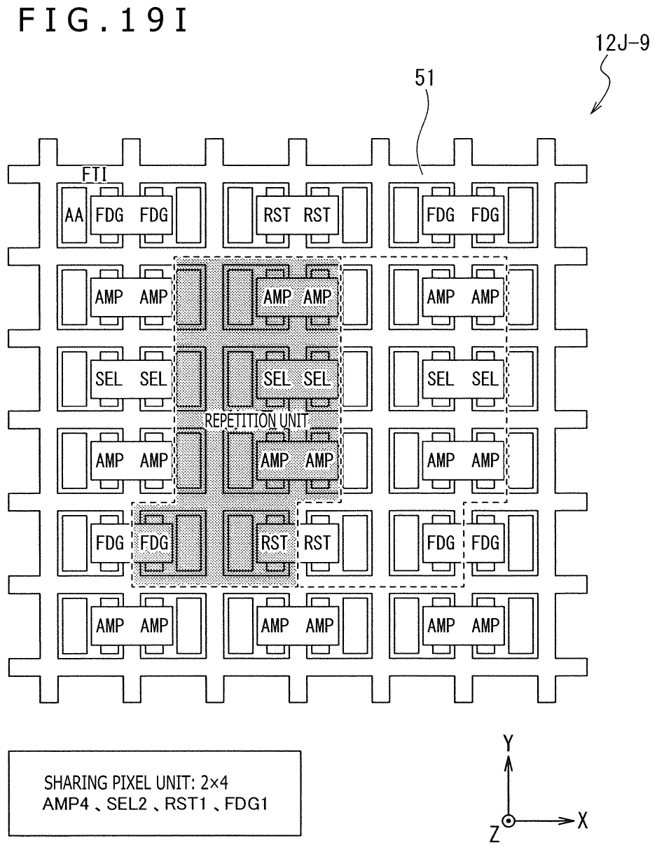

FIG. 19A is a plan view schematically depicting a configuration of a pixel area 12J-1 according to the modification example 8-1 of the third embodiment of the present disclosure. As depicted in FIG. 19A, in the pixel area 12J-1 according to the modification example 8-1, columns in which switch transistors FDG, reset transistors RST, selection transistor SEL, and selection transistors SEL are next to each other repeatedly in this order in the Y-axis direction and columns in which amplification transistors AMP are next to each other in the Y-axis direction are provided. The external shape of each repetition unit of the arrangement of pixel transistors is a shape which is the same as that of the pixel area 12I depicted in FIG. 18.

### (8-2) Modification Example 8-2

FIG. 19B is a plan view schematically depicting a configuration of a pixel area 12J-2 according to the modification example 8-2 of the third embodiment of the present disclosure. As depicted in FIG. 19B, in the pixel area 12J-2 according to the modification example 8-2, columns in which selection transistors SEL, reset transistors RST, amplification transistors AMP, and amplification transistors AMP are next to each other repeatedly in this order in the Y-axis direction and columns in which selection transistors SEL, switch transistors FDG, amplification transistors AMP, and amplification transistors AMP are next to each other repeatedly in this order in the Y-axis direction are provided. The external shape of each repetition unit of the arrangement of pixel transistors is a shape different from that of the pixel area 12I depicted in FIG. 18.

### (8-3) Modification Example 8-3

FIG. 19C is a plan view schematically depicting a configuration of a pixel area 12J-3 according to the modification example 8-3 of the third embodiment of the present disclosure. As depicted in FIG. 19C, in the pixel area 12J-3 according to the modification example 8-3, columns in which switch transistors FDG, reset transistors RST, amplification transistors AMP, and amplification transistors AMP are next to each other repeatedly in this order in the Y-axis direction and columns in which selection transistors SEL, selection transistors SEL, amplification transistors AMP, and amplification transistors AMP are next to each other repeatedly in this order in the Y-axis direction are provided. The external shape of each repetition unit of the arrangement of pixel transistors is a shape which is the same as that of the pixel area 12J-2 depicted in FIG. 19B.

### (8-4) Modification Example 8-4

FIG. 19D is a plan view schematically depicting a configuration of a pixel area 12J-4 according to the modification example 8-4 of the third embodiment of the present disclosure. As depicted in FIG. 19D, in the pixel area 12J-4 according to the modification example 8-4, the external shape of each repetition unit of the arrangement of pixel transistors is a shape different from that of the pixel area 12J-3 depicted in FIG. 19C.

### (8-5) Modification Example 8-5

FIG. 19E is a plan view schematically depicting a configuration of a pixel area 12J-5 according to the modification example 8-5 of the third embodiment of the present disclosure. As depicted in FIG. 19E, in the pixel area 12J-5 according to the modification example 8-5, some of the positions of a reset transistor RST and selection transistors SEL in each repetition unit are replaced with each other as compared with the pixel area 12J-4 depicted in FIG. 19D. The external shape of each repetition unit of the arrangement of pixel transistors is a shape which is the same as that of the pixel area 12J-4 depicted in FIG. 19D.

### (8-6) Modification Example 8-6

FIG. 19F is a plan view schematically depicting a configuration of a pixel area 12J-6 according to the modification example 8-6 of the third embodiment of the present disclosure. As depicted in FIG. 19F, in the pixel area 12J-6 according to the modification example 8-6, the external shape of each repetition unit of the arrangement of pixel transistors is a shape different from that of the pixel area 12J-5 depicted in FIG. 19E.

### (8-7) Modification Example 8-7

FIG. 19G is a plan view schematically depicting a configuration of a pixel area 12J-7 according to the modification example 8-7 of the third embodiment of the present disclosure. As depicted in FIG. 19G, in the pixel area 12J-7 according to the modification example 8-7, some of the positions of reset transistors RST and selection transistors SEL in each repetition unit are replaced with each other as compared with the pixel area 12J-6 depicted in FIG. 19F. In addition, the gate electrodes of a selection transistor SEL and a reset transistor RST that are adjacent to each other in the X-axis direction and the gate electrodes of a selection transistor SEL and a switch transistor FDG that are adjacent to each other in the X-axis direction are not integrated. The gate electrodes of each pair of amplification transistors AMP that are adjacent to each other in the X-axis direction are integrated.

The external shape of each repetition unit of the arrangement of pixel transistors is a shape which is the same as that of the pixel area 12J-6 depicted in FIG. 19F.

### (8-8) Modification Example 8-8

FIG. 19H is a plan view schematically depicting a configuration of a pixel area 12J-8 according to the modification example 8-8 of the third embodiment of the present disclosure. As depicted in FIG. 19H, in the pixel area 12J-8 according to the modification example 8-8, the external shape of each repetition unit of the arrangement of pixel transistors is a shape different from that of the pixel area 12J-7 depicted in FIG. 19G.

### (8-9) Modification Example 8-9

FIG. 19I is a plan view schematically depicting a configuration of a pixel area 12J-9 according to the modification example 8-9 of the third embodiment of the present disclosure. As depicted in FIG. 19I, in the pixel area 12J-9 according to the modification example 8-9, some of the positions of amplification transistors AMP and selection transistors SEL in each repetition unit are replaced with each other as compared with the pixel area 12J-8 depicted in FIG. 19H. The external shape of each repetition unit of the arrangement of pixel transistors is a shape which is the same as that of the pixel area 12J-8 depicted in FIG. 19H.

### Fourth Embodiment

In embodiments of the present disclosure, the number of amplification transistors AMP that each sharing pixel unit 35 has is not limited to two or four, and may be equal to or greater than six, for example.

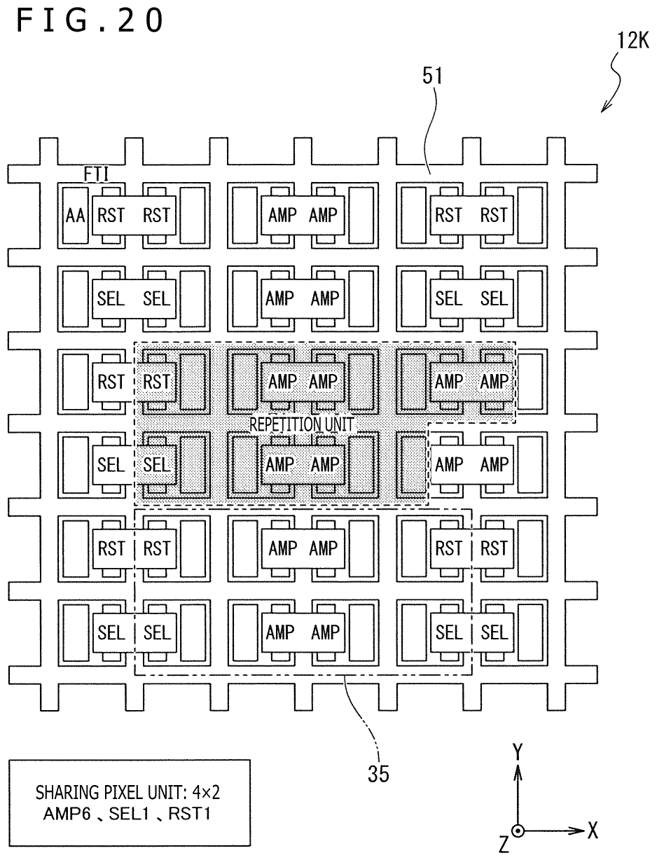

FIG. 20 is a plan view schematically depicting a configuration example of a pixel area 12K according to a fourth embodiment of the present disclosure. As depicted in FIG. 20, in the pixel area 12K according to the fourth embodiment, the configuration of each sharing pixel unit 35 is a 4×2-type configuration, and each sharing pixel unit 35 has six amplification transistors AMP, one selection transistor SEL, and one reset transistor RST, as pixel transistors. Also with such a configuration, as in the first to third embodiments described above, parasitic capacitance generated between vias 62 and between wires 61 (e.g., refer to FIG. 6) can be reduced, and deterioration of the performance of the image-capturing apparatus 1 can be reduced.

### (9) Modification Examples 9

For example, configurations like ones in modification examples 9-1 and 9-2 depicted below may be adopted in the fourth embodiment. The configuration of each sharing pixel unit 35 in the modification examples 9-1 and 9-2 is a 2×4-type configuration. Each sharing pixel unit 35 has four amplification transistors AMP, two selection transistors SEL, one reset transistor RST, and one switch transistor FDG, as pixel transistors. Also with such a configuration, as in the first to third embodiments described above, parasitic capacitance generated between vias 62 and between wires 61 (e.g., refer to FIG. 6) can be reduced, and deterioration of the performance of the image-capturing apparatus 1 can be reduced.

### (9-1) Modification Example 9-1

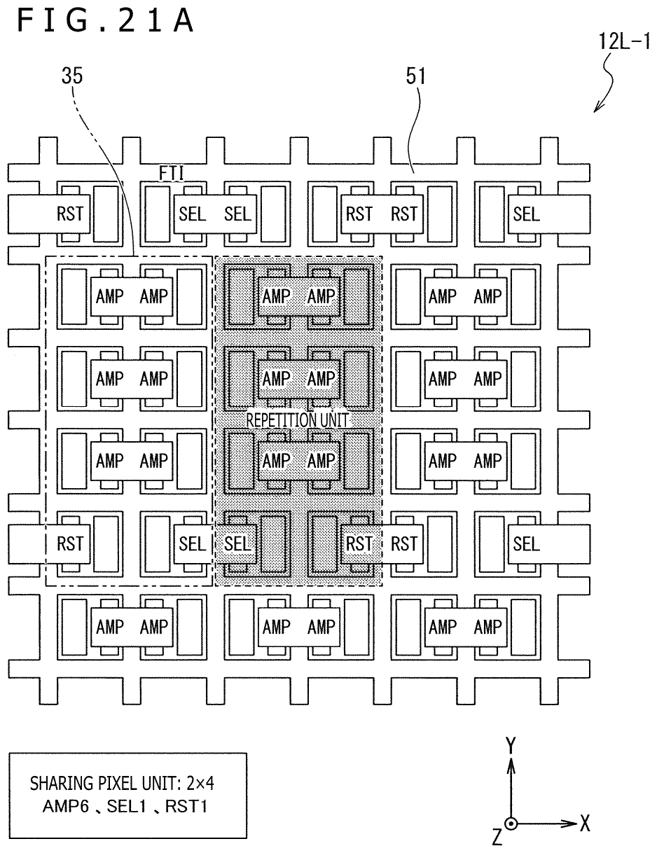

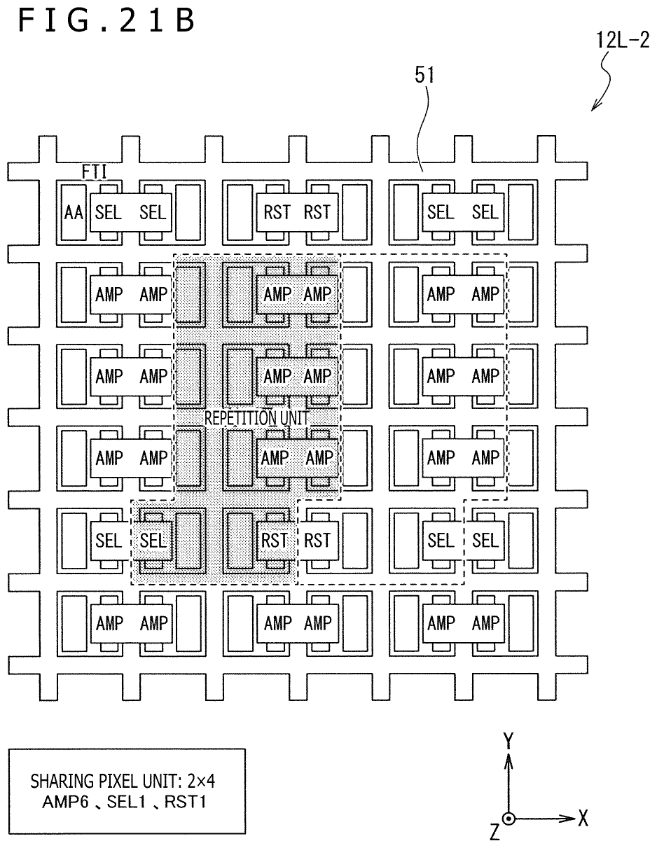

FIG. 21A is a plan view schematically depicting a configuration of a pixel area 12L-1 according to the modification example 9-1 of the fourth embodiment of the present disclosure. As depicted in FIG. 21A, in the pixel area 12L-1 according to the modification example 9-1, the external shape of each repetition unit of the arrangement of pixel transistors is a shape different from that of the pixel area 12K depicted in FIG. 20.

### (9-2) Modification Example 9-2

FIG. 21B is a plan view schematically depicting a configuration of a pixel area 12L-2 according to the modification example 9-2 of the fourth embodiment of the present disclosure. As depicted in FIG. 21B, in the pixel area 12L-2 according to the modification example 9-2, the external shape of each repetition unit of the arrangement of pixel transistors is a shape different from that of the pixel area 12L-1 depicted in FIG. 21A.

### Fifth Embodiment

Next, configuration examples of the readout circuit 30 to be applied to the first to fourth embodiments and modification examples thereof described above are depicted.

### Configuration Example 1

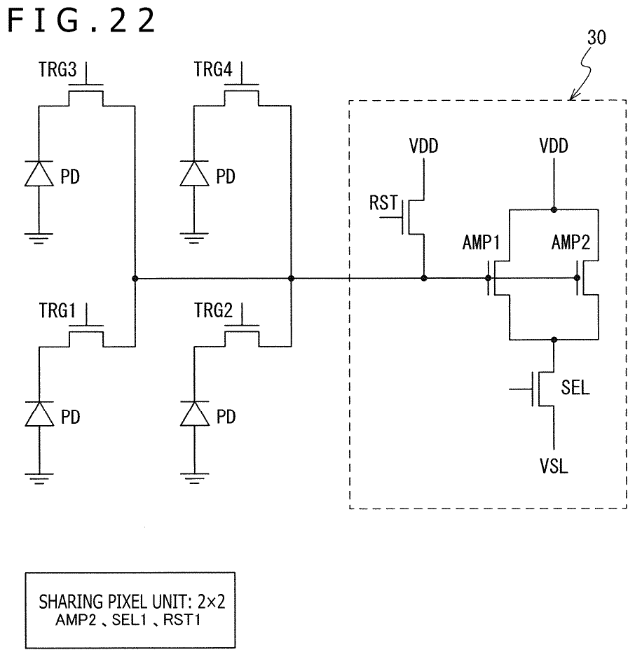

FIG. 22 is a circuit diagram depicting a configuration example 1 of the readout circuit 30 according to the fifth embodiment of the present disclosure. The configuration example 1 of the readout circuit 30 depicted in FIG. 22 is applied to a case where the configuration of each sharing pixel unit 35 is a 2×2-type configuration and each sharing pixel unit 35 has two amplification transistors AMP, one selection transistor SEL, and one reset transistor RST, as pixel transistors. For example, the configuration example 1 depicted in FIG. 22 can be applied to the first embodiment, the modification examples 1-1 to 1-3, and the modification examples 2-1 to 2-4 described above.

### Configuration Examples 2 and 3

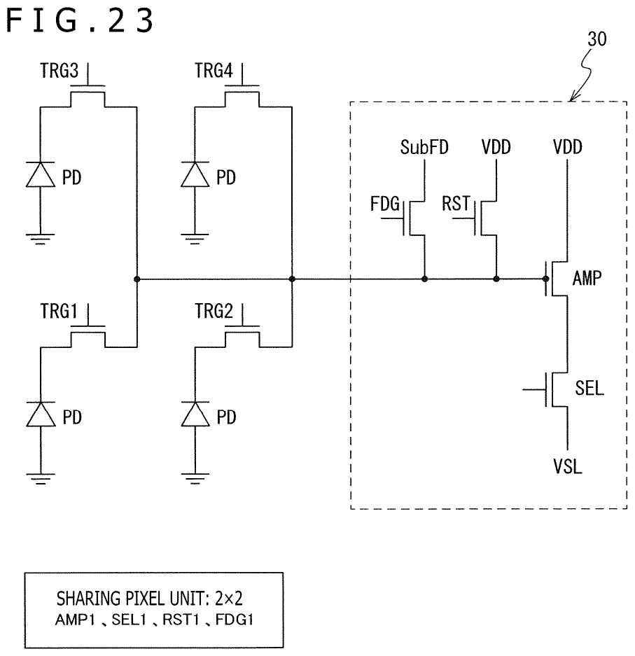

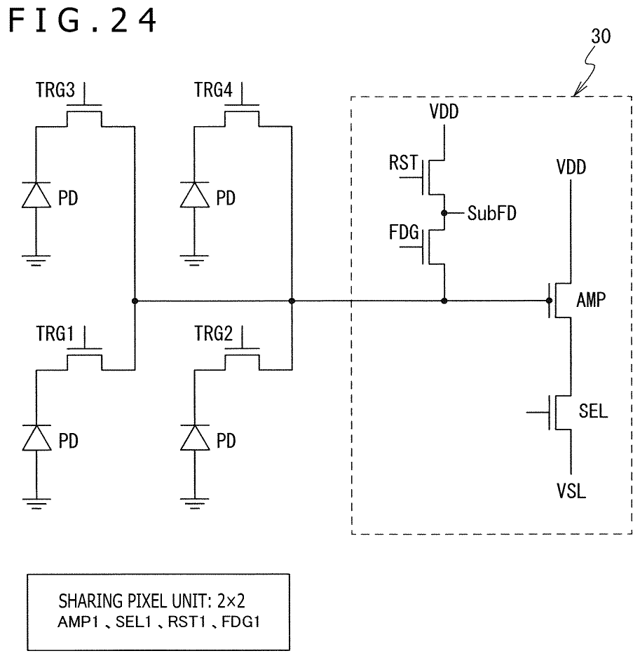

FIG. 23 and FIG. 24 are circuit diagrams depicting configuration examples 2 and 3 of the readout circuit 30 according to the fifth embodiment of the present disclosure. The configuration examples 2 and 3 of the readout circuit 30 depicted in FIG. 23 and FIG. 24 are applied to a case where the configuration of each sharing pixel unit 35 is a 2×2-type configuration and each sharing pixel unit 35 has one amplification transistor AMP, one selection transistor SEL, one reset transistor RST, and one switch transistor FDG, as pixel transistors. For example, the configuration examples 2 and 3 depicted in FIG. 23 and FIG. 24 can be applied to the modification examples 3-1 and 3-2 described above.

### Configuration Examples 4 and 5

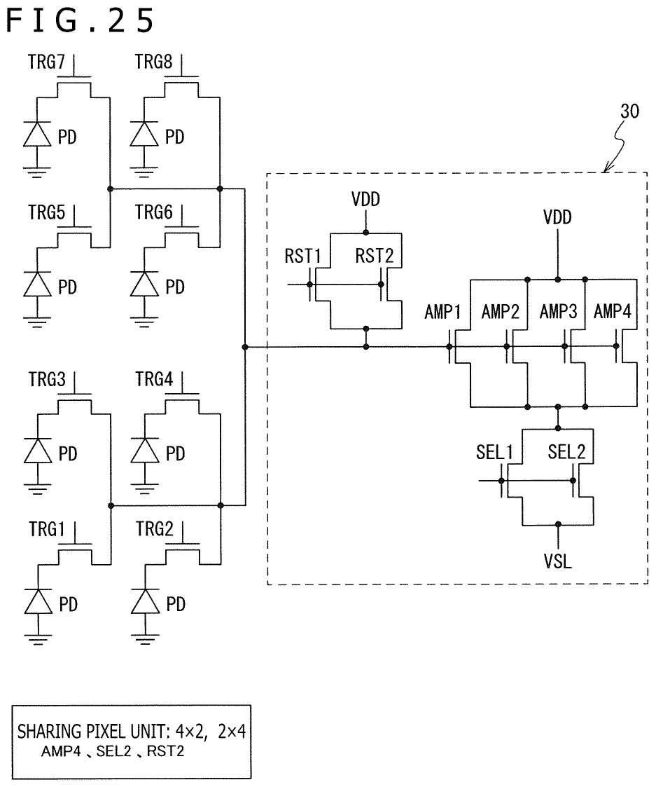

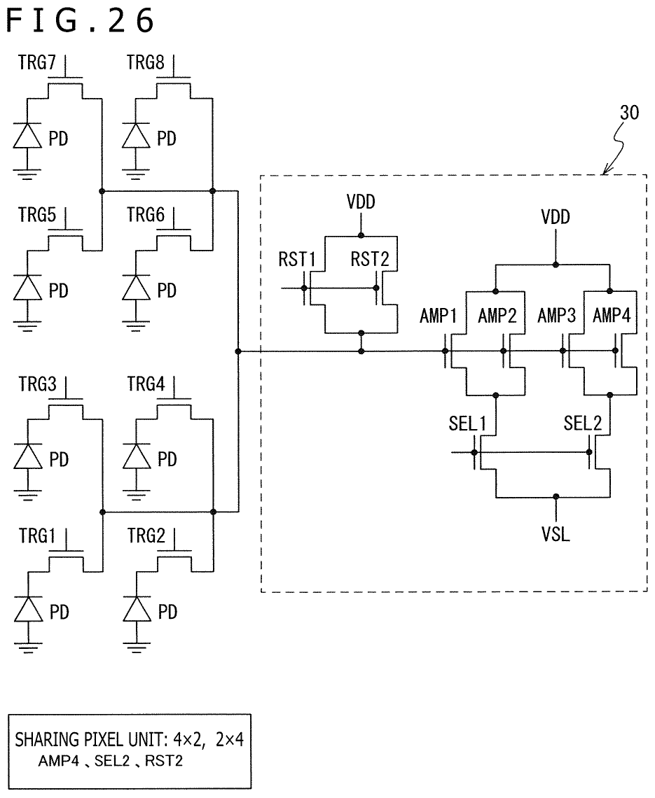

FIG. 25 and FIG. 26 are circuit diagrams depicting configuration examples 4 and 5 of the readout circuit 30 according to the fifth embodiment of the present disclosure. The configuration examples 4 and 5 of the readout circuit 30 depicted in FIG. 25 and FIG. 26 are applied to a case where the configuration of each sharing pixel unit 35 is a 4×2-type (or 2×4-type) configuration and each sharing pixel unit 35 has four amplification transistors AMP, two selection transistors SEL, and two reset transistors RST, as pixel transistors. For example, the configuration examples 4 and 5 depicted in FIG. 25 and FIG. 26 can be applied to the modification examples 4-1 to 4-6 and 5-1 to 5-3 (or the modification examples 7-1 to 7-10) described above.

### Configuration Examples 6 to 9

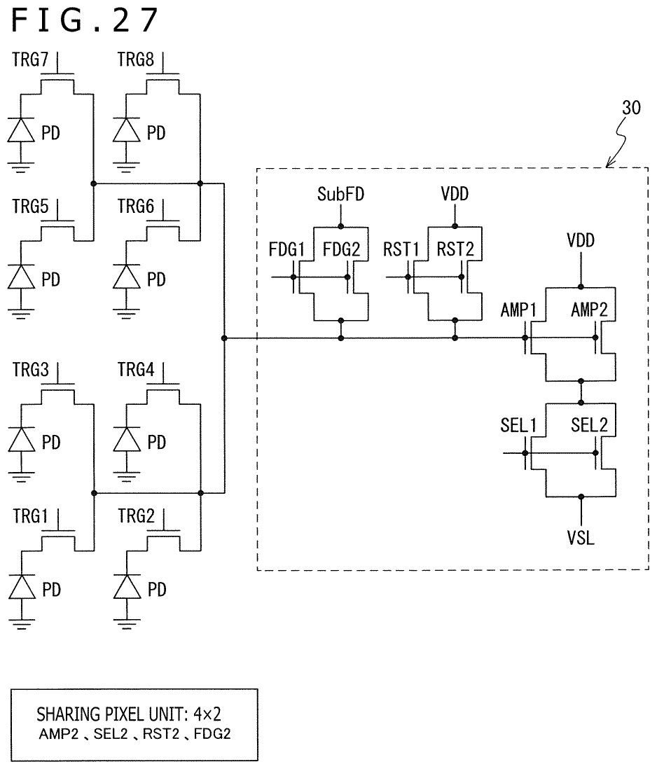

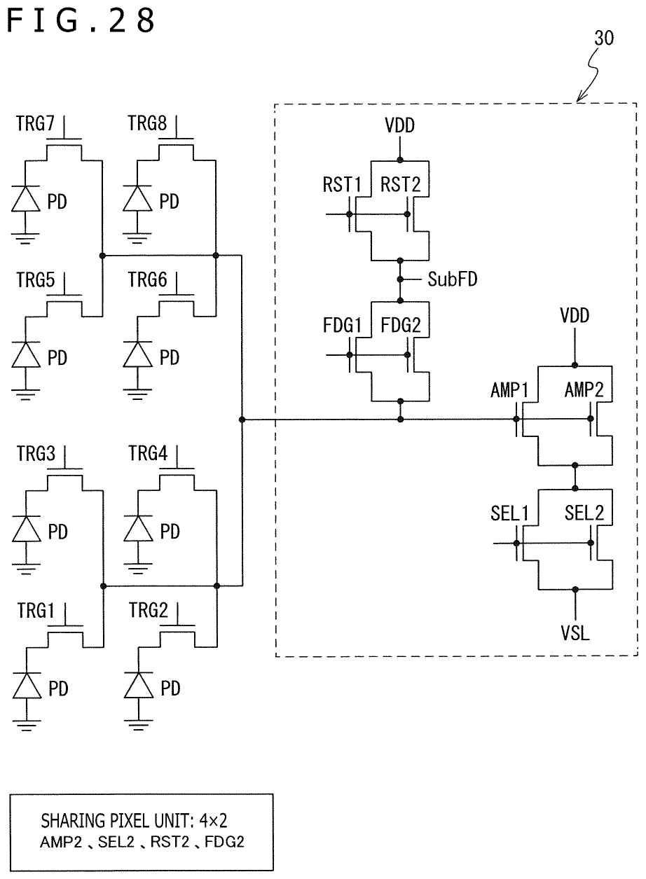

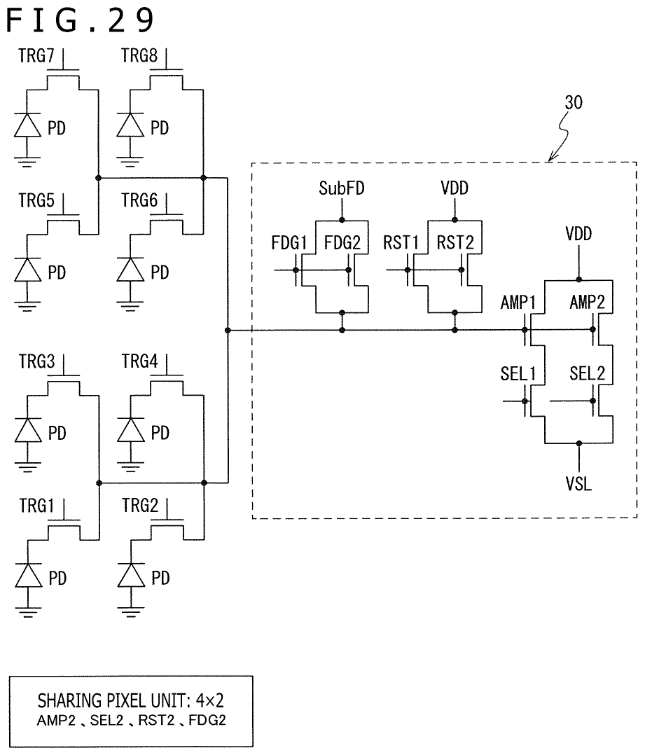

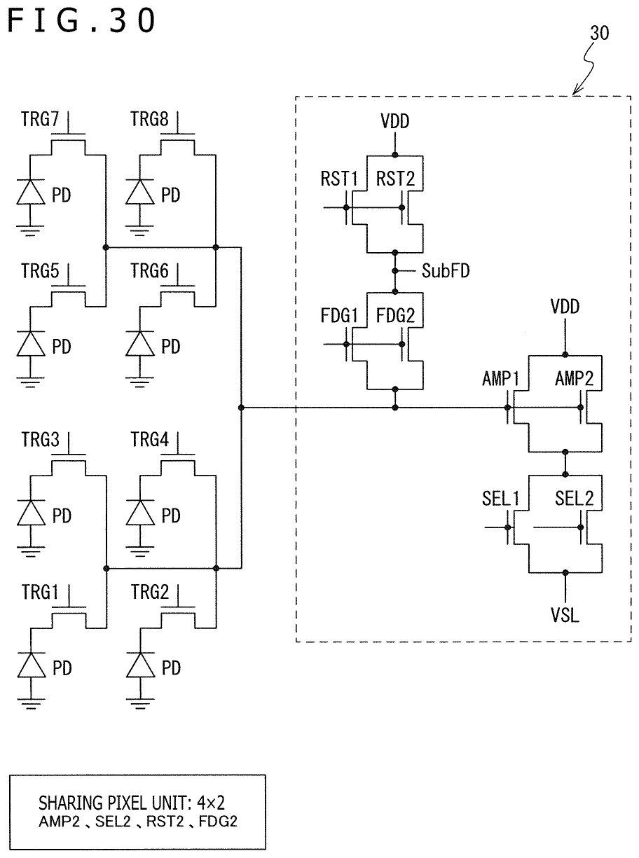

FIG. 27 to FIG. 30 are circuit diagrams depicting configuration examples 6 to 9 of the readout circuit 30 according to the fifth embodiment of the present disclosure. The configuration examples 6 to 9 of the readout circuit 30 depicted in FIG. 27 to FIG. 30 are applied to a case where the configuration of each sharing pixel unit 35 is a 4×2-type configuration and each sharing pixel unit 35 has two amplification transistors AMP, two selection transistors SEL, two reset transistors RST, and two switch transistors FDG, as pixel transistors. For example, the configuration examples 6 to 9 depicted in FIG. 27 to FIG. 30 can be applied to the modification examples 6-1 and 6-2 described above.

### Configuration Examples 10 to 13

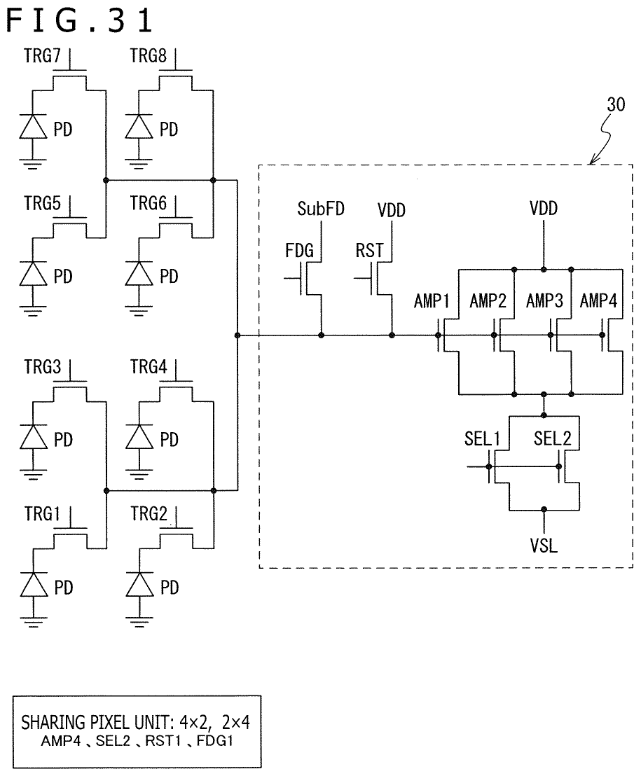

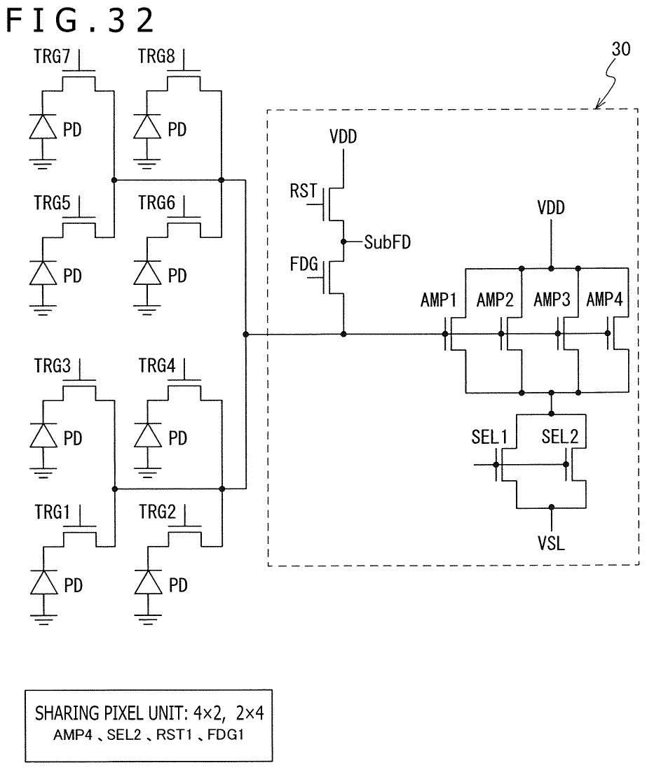

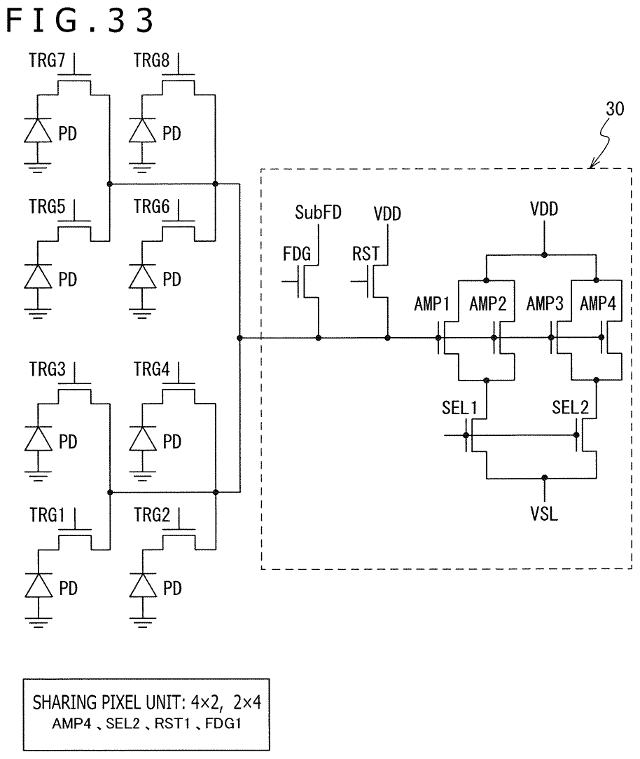

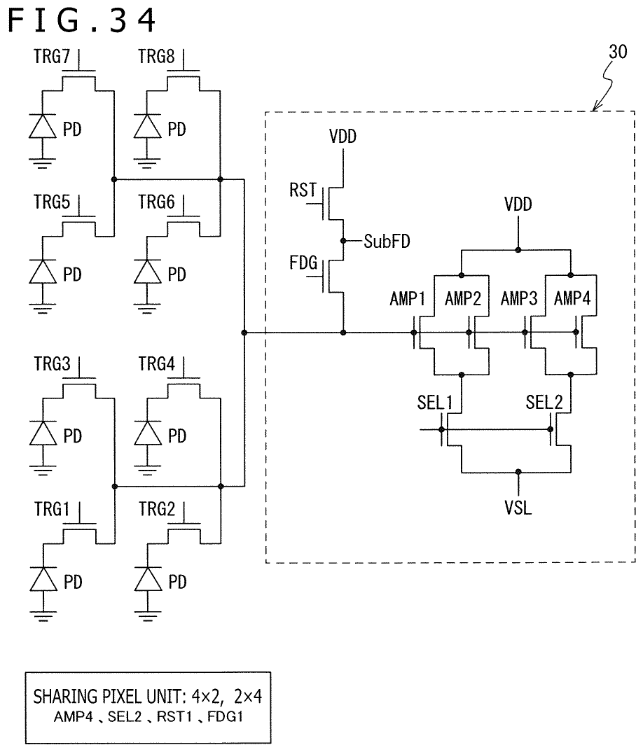

FIG. 31 to FIG. 34 are circuit diagrams depicting configuration examples 10 to 13 of the readout circuit 30 according to the fifth embodiment of the present disclosure. The configuration examples 10 to 13 of the readout circuit 30 depicted in FIG. 31 to FIG. 34 are applied to a case where the configuration of each sharing pixel unit 35 is a 4×2-type (or 2×4-type) configuration and each sharing pixel unit 35 has four amplification transistors AMP, two selection transistors SEL, one reset transistor RST, and one switch transistor FDG, as pixel transistors. For example, the configuration examples 10 to 13 depicted in FIG. 31 to FIG. 34 can be applied to the modification examples 6-3 to 6-6 (or the third embodiment, the modification examples 8-1 to 8-9) described above.

### Configuration Example 14

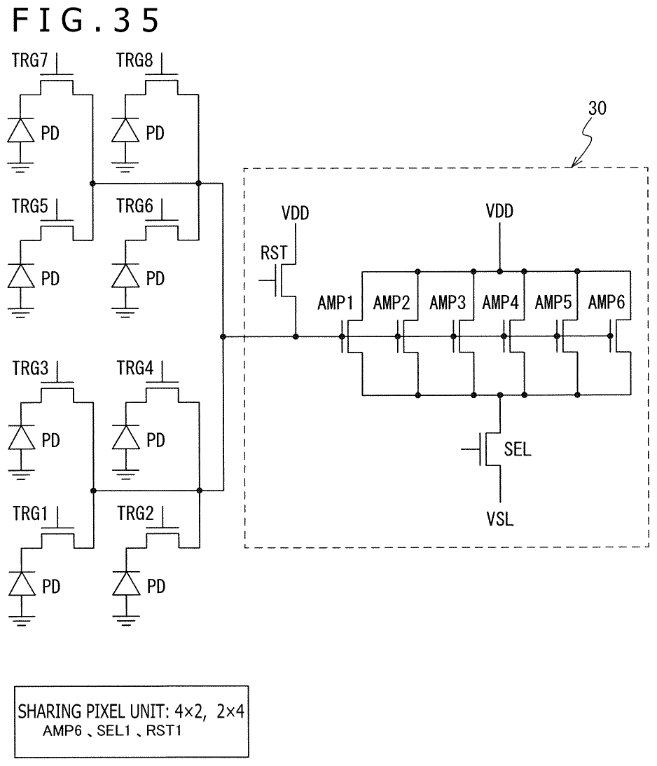

FIG. 35 is a circuit diagram depicting a configuration example 14 of the readout circuit 30 according to the fifth embodiment of the present disclosure. The configuration example 14 of the readout circuit 30 depicted in FIG. 35 is applied to a case where the configuration of each sharing pixel unit 35 is a 4×2-type (or 2×4-type) configuration and each sharing pixel unit 35 has six amplification transistors AMP, one selection transistor SEL, one reset transistor RST, and one switch transistor FDG, as pixel transistors. For example, the configuration example 14 depicted in FIG. 35 can be applied to the fourth embodiment described above.

### Sixth Embodiment

Pixel transistors (e.g., at least one or more of amplification transistors AMP, selection transistors SEL, reset transistors RST, and switch transistors FDG) according to embodiments of the present disclosure are not limited to those having a planar gate structure like the one depicted in FIG. 7. The pixel transistors may be FinFETs (Fin Field Effect Transistors) in which semiconductor substrates or semiconductor layers on which channels are formed are formed in fin shapes. Hereinbelow, a case where amplification transistors AMP are FinFETs as an example of pixel transistors is depicted.

### Configuration Example 1

FIG. 36 is a cross-sectional view depicting an image-capturing apparatus 1A according to a configuration example 1 of a sixth embodiment of the present disclosure. As depicted in FIG. 36, in the image-capturing apparatus 1A according to the sixth embodiment, the first amplification transistor AMP1 and the second amplification transistor AMP2 are FinFETs.

For example, fin-shaped semiconductor layers 110 are provided on the front surface 11a of the semiconductor substrate 11. The semiconductor layers 110 are monocrystal semiconductors formed by an epitaxial growth method on the front surface 11a of the semiconductor substrate 11, and are formed by performing patterning into a fin shape by photolithography or etching technologies. For example, the fin shape is a rectangular parallelepiped shape which is long in the gate length direction but short in the gate width direction orthogonal to the gate length direction. The top sides of the semiconductor layers 110 are positioned above the front surface 11a of the semiconductor substrate 11.

As depicted in FIG. 36, the gate electrodes G1 and G2 are provided to continuously cover the top sides and both the left and right sides of the semiconductor layers 110 with a gate insulating film (not depicted) being interposed therebetween. According to this configuration, the gate electrodes G1 and G2 can simultaneously apply a gate voltage to the top sides and both the left and right sides of the semiconductor layers 110. That is, the gate electrodes G1 and G2 can simultaneously apply a gate voltage to the semiconductor layers 110 from three directions in total, from the top sides and both the left and right sides. Accordingly, for example, the gate electrodes G1 and G2 can make the semiconductor layers 110 completely depleted or almost completely depleted, and can enhance controllability of channel areas. In addition, the gate electrodes G1 and G2 make it possible to increase the gate widths of the first amplification transistor AMP1 and the second amplification transistor AMP2 while preventing increase of the areas in a plan view.

In addition, since the gate electrodes G1 and G2 that are adjacent to each other in the X-axis direction are integrated also in the image-capturing apparatus 1A as depicted in FIG. 36, parasitic capacitance generated between vias 62 and between wires 61 can be reduced, and deterioration of the performance of the image-capturing apparatus 1 can be reduced.

### Configuration Example 2

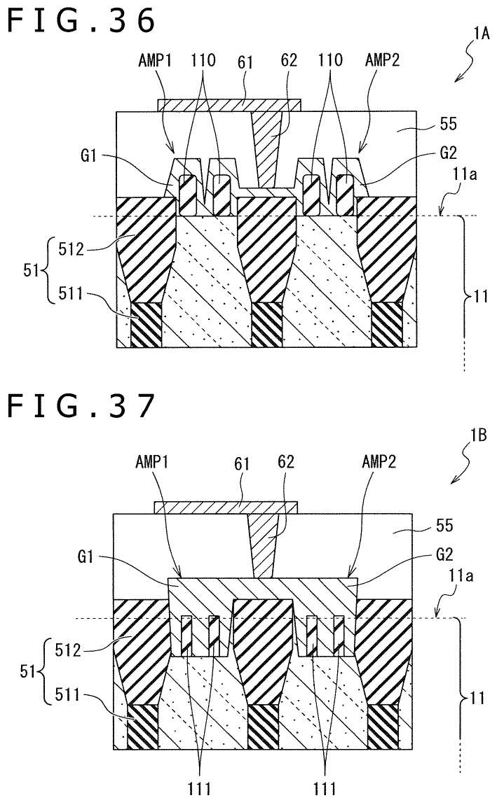

FIG. 37 is a cross-sectional view depicting an image-capturing apparatus 1B according to a configuration example 2 of the sixth embodiment of the present disclosure. As depicted in FIG. 37, in the image-capturing apparatus 1B according to the sixth embodiment, the first amplification transistor AMP1 and the second amplification transistor AMP2 are FinFETs.

For example, fin-shaped semiconductor areas 111 are provided on the side of the front surface 11a of the semiconductor substrate 11. The semiconductor areas 111 are formed by performing patterning, into a fin shape, of the front surface 11a of the semiconductor substrate 11 by photolithography and etching technologies. The top sides of the semiconductor areas 111 are at a height matching or almost matching the height of the front surface 11a of the semiconductor substrate 11.

Also in the image-capturing apparatus 1B, the gate electrodes G1 and G2 can simultaneously apply a gate voltage to the top sides and both the left and right sides of the semiconductor layers 110. That is, the gate electrodes G1 and G2 can simultaneously apply a gate voltage to the semiconductor layers 110 from three directions in total, from the top sides and both the left and right sides. As a result, advantages similar to those of the image-capturing apparatus 1A depicted in FIG. 36 are achieved.

In addition, since the gate electrodes G1 and G2 that are adjacent to each other in the X-axis direction are integrated also in the image-capturing apparatus 1B as depicted in FIG. 37, parasitic capacitance generated between vias 62 and between wires 61 can be reduced, and deterioration of the performance of the image-capturing apparatus 1 can be reduced.

### Other Embodiments

Whereas, as described above, the present disclosure has been described with use of the embodiments and the modification examples, statements and figures forming part of this disclosure should not be understood as limiting the present disclosure.

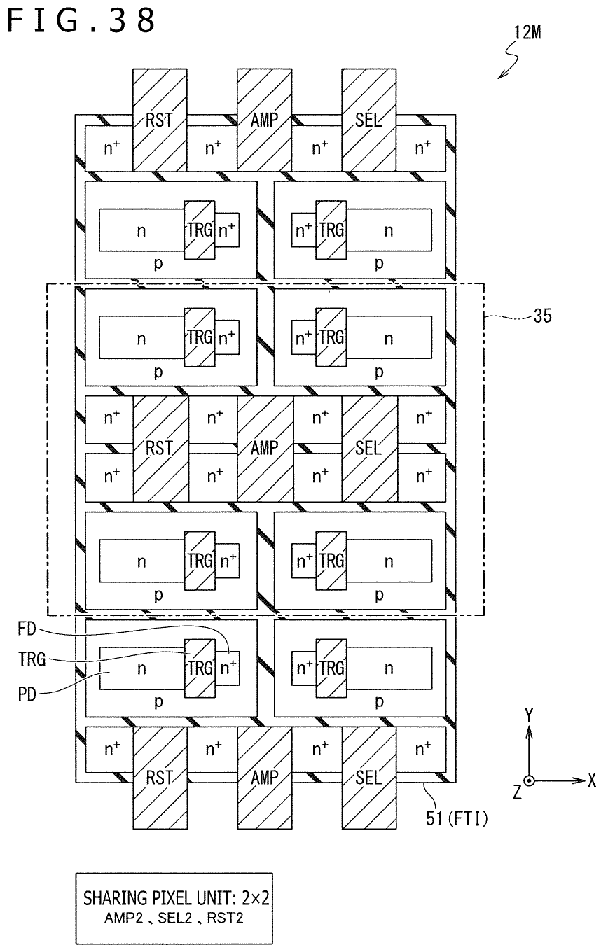

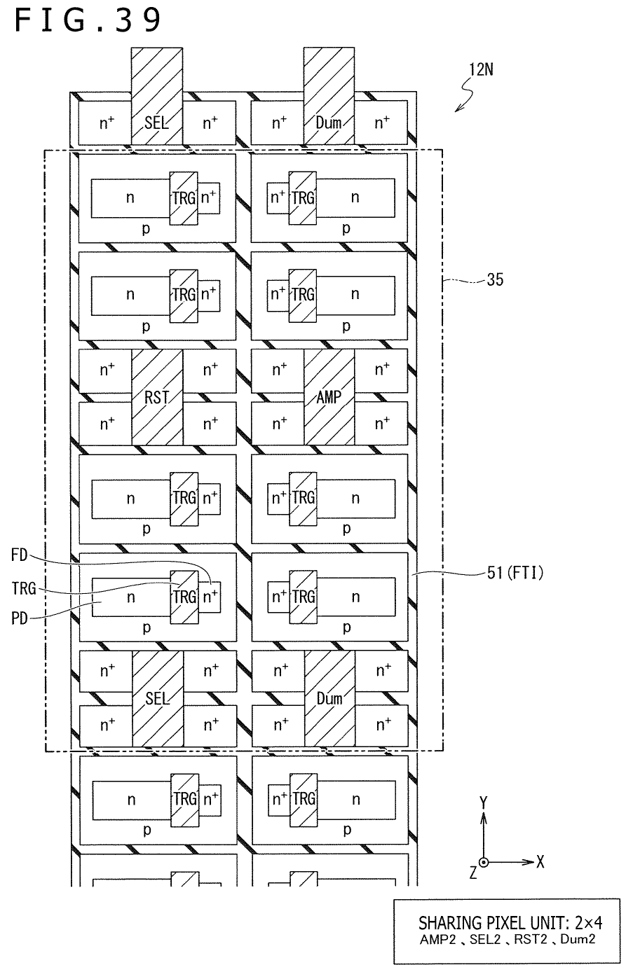

Various alternative embodiments, implementation examples, and operational technologies will be apparent to those skilled in the art from this disclosure. For example, embodiments of the present disclosure may include an aspect depicted in FIG. 38 or FIG. 39.

FIG. 38 is a plan view schematically depicting a pixel area 12M according to a configuration example 1 of another embodiment of the present disclosure. As depicted in FIG. 38, for example, the configuration of each sharing pixel unit 35 in the pixel area 12M is a 2×2-type configuration. Two reset transistors RST, two amplification transistors AMP, and two selection transistors SEL are arranged at a central section of each sharing pixel unit 35. The gate electrodes of each pair of pixel transistors (each pair of reset transistors RST, each pair of amplification transistors AMP, each pair of selection transistors SEL) that are adjacent to each other in the Y-axis direction are integrated.

FIG. 39 is a plan view schematically depicting a pixel area 12N according to a configuration example 2 of another embodiment of the present disclosure. As depicted in FIG. 39, the pixel area 12N has a dummy transistor Dum as part of pixel transistors. For example, the dummy transistor Dum is not connected to another element, and does not output signals.

For example, the configuration of each sharing pixel unit 35 in the pixel area 12N is a 2×4-type configuration. Two reset transistors RST and two amplification transistors AMP are arranged at a central section of each sharing pixel unit 35. One selection transistor SEL and one dummy transistor Dum are arranged at one end of each sharing pixel unit 35 in the Y-axis direction. One selection transistor SEL and one dummy transistor Dum are arranged also at another end of each sharing pixel unit 35 in the Y-axis direction. The gate electrodes of each pair of pixel transistors (each pair of reset transistors RST, each pair of amplification transistors AMP, each pair of selection transistors SEL, each pair of dummy transistors Dum) that are adjacent to each other in the Y-axis direction are integrated.

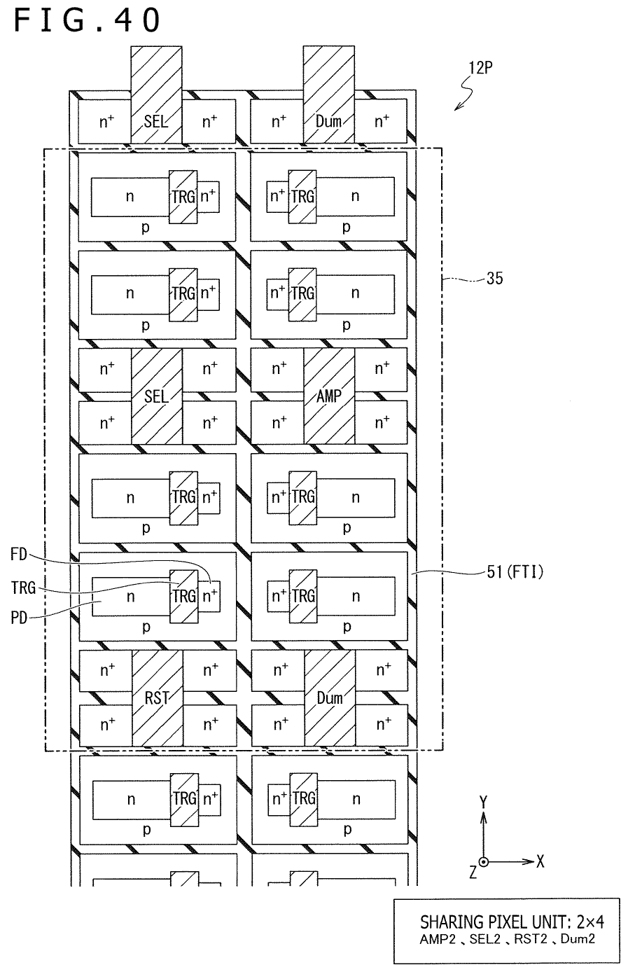

FIG. 40 is a plan view schematically depicting a pixel area 12P according to a configuration example 3 of another embodiment of the present disclosure. The pixel area 12P in this aspect depicted in FIG. 40 is obtained by replacing a reset transistor RST and a selection transistor SEL in the configuration of the pixel area 12N depicted in FIG. 39 with each other. In respects other than this, the configuration of the pixel area 12P depicted in FIG. 40 is the same as that of the pixel area 12N depicted in FIG. 39.

In any of the pixel area 12M depicted in FIG. 38, the pixel area 12N depicted in FIG. 39, and the pixel area 12P depicted in FIG. 40, pixel transistors may be MOSFETs with planar gate structures or may be FinFETs. Some of the pixel transistors may be MOSFETS with planar gate structures, and some of the others of the pixel transistors may be FinFETs.

In any of the pixel area 12M depicted in FIG. 38, the pixel area 12N depicted in FIG. 39, and the pixel area 12P depicted in FIG. 40, gate electrodes that are adjacent to each other in the Y-axis direction are integrated. Accordingly, parasitic capacitance generated between vias and between wires can be reduced. As a result, deterioration of the performance of the image-capturing apparatus 1 can be reduced.

As described above, needless to say, the present technology includes various embodiments and the like not described here. Within the scope not departing from the gist of the embodiments and modification examples described above, at least one of various types of omission, replacement, and modification of constituent elements can be performed. In addition, advantages described in the present specification are merely illustrated as examples, advantages of the present disclosure are not limited to them, and there may be other advantages.

Note that the present disclosure can also adopt configurations like the ones below.

1

An image-capturing apparatus including:
a semiconductor layer;
multiple pixels provided on the semiconductor layer;
an inter-pixel separating section that is provided on the semiconductor layer and separates one pixel and another pixel that are adjacent to each other in the multiple pixels; and
pixel transistors connected to the multiple pixels, in which
   the pixel transistors include a first transistor and a second transistor adjacent to the first transistor with the inter-pixel separating section being interposed therebetween, and
   a gate electrode of the first transistor and a gate electrode of the second transistor are integrated via an upper portion of the inter-pixel separating section.
      2

The image-capturing apparatus according to (1) above, in which
one transistor included in the pixel transistors is arranged in each of the multiple pixels when seen in a plan view as seen in a thickness direction of the semiconductor layer.
   3

The image-capturing apparatus according to (1) or (2) above, in which
the multiple pixels form sharing pixel units sharing the pixel transistors.
   4

The image-capturing apparatus according to (3) above, in which
a first sharing pixel unit and a second sharing pixel unit adjacent to the first sharing pixel unit are included as the sharing pixel units, and
the gate electrode of the first transistor included in the first sharing pixel unit and the gate electrode of the second transistor included in the first sharing pixel unit are integrated via an upper portion of the inter-pixel separating section.
   5

The image-capturing apparatus according to (4) above, in which
the first transistor included in the first sharing pixel unit is arranged at a position overlapping, when seen in a plan view as seen in a thickness direction of the semiconductor layer, one pixel of the multiple pixels included in the first sharing pixel unit, and
the second transistor included in the first sharing pixel unit is arranged at a position overlapping, when seen in the plan view, one pixel of the multiple pixels included in the second sharing pixel unit.
   6

The image-capturing apparatus according to (4) or (5) above, in which,
assuming that the integrated gate electrodes of the first transistor and the second transistor in the first sharing pixel unit are a first gate electrode and that the integrated gate electrodes of the first transistor and the second transistor in the second sharing pixel unit are a second gate electrode,
the first gate electrode and the second gate electrode are adjacent to each other with the inter-pixel separating section being interposed therebetween,
the first sharing pixel unit has a first via provided on the first gate electrode and connected to the first gate electrode,
the second sharing pixel unit has a second via provided on the second gate electrode and connected to the second gate electrode, and
a direction of a shortest distance between the first via and the second via crosses a direction of a shortest distance between the first gate electrode and the second gate electrode.
   7

The image-capturing apparatus according to any one of (1) to (6) above, in which
each of the multiple pixels has
   a photoelectric converting section,
   a floating diffusion, and
   a transfer transistor that transfers a charge generated by the photoelectric converting section to the floating diffusion, and
the first transistor and the second transistor are amplification transistors that amplify a signal at a level according to a charge stored in the floating diffusion.
   8

The image-capturing apparatus according to any one of (1) to (7) above, in which
the inter-pixel separating section includes a trench isolation.
   9

The image-capturing apparatus according to any one of (1) to (8) above, in which
the first transistor and the second transistor are FinFETs.

### Reference Signs List

1, 1A, 1B: Image-capturing apparatus
11: Semiconductor substrate
11a: Front surface
11b: Back surface
12, 12A-1 to 12A-3, 12B-1 to 12B 4, pixel area, 12C-1, 12C-2, 12D-1 to 12D-6, 12E-1 to 12E-3, 12F-1 to 12F-6, 12G, 12H-1 to 12H-9, 12I, 12J-1 to 12J-9, 12K, 12L-1 to 12L-3, 12M, 12N, 12P: Pixel area
13: Vertical drive circuit
14: Column signal processing circuit
15: Horizontal drive circuit
16: Output circuit
17: Control circuit
21: Pixel (first pixel, second pixel, third pixel, fourth pixel)
22: Horizontal signal line
23: Vertical signal line
24: Data output signal line
30: Readout circuit
35: Sharing pixel unit
35-1: First sharing pixel unit
35-2: Second sharing pixel unit
35-3: Third sharing pixel unit
51: Inter-pixel separating section
52: Well area
53: Channel section
55: Interlayer dielectric film
61, 63: Wire
62: Via
62-1: First via
62-2: Second via
110: Semiconductor layer
111: Semiconductor area
511: First trench isolation
512: Second trench isolation
AA: Active area
AMP: Amplification transistor
AMP1: First amplification transistor
AMP2: Second amplification transistor
Dum: Dummy transistor
FD: Floating diffusion
FDG: Switch transistor
G1, G2: Gate electrode
Le: Shortest distance
Lv: Shortest distance
PD: Photodiode
RST: Reset transistor
SEL: Selection transistor
TR: Transfer transistor
TRG: Gate electrode (of transfer transistor)
VDD: Power supply potential

1. An image-capturing apparatus comprising:
a semiconductor layer;
multiple pixels provided on the semiconductor layer;
an inter-pixel separating section that is provided on the semiconductor layer and separates one pixel and another pixel that are adjacent to each other in the multiple pixels; and
pixel transistors connected to the multiple pixels, wherein
the pixel transistors include a first transistor and a second transistor adjacent to the first transistor with the inter-pixel separating section being interposed therebetween, and
a gate electrode of the first transistor and a gate electrode of the second transistor are integrated via an upper portion of the inter-pixel separating section.

2. The image-capturing apparatus according to claim 1, wherein
one transistor included in the pixel transistors is arranged in each of the multiple pixels when seen in a plan view as seen in a thickness direction of the semiconductor layer.

3. The image-capturing apparatus according to claim 1, wherein
the multiple pixels form sharing pixel units sharing the pixel transistors.

4. The image-capturing apparatus according to claim 3, wherein
a first sharing pixel unit and a second sharing pixel unit adjacent to the first sharing pixel unit are included as the sharing pixel units, and
the gate electrode of the first transistor included in the first sharing pixel unit and the gate electrode of the second transistor included in the first sharing pixel unit are integrated via an upper portion of the inter-pixel separating section.

5. The image-capturing apparatus according to claim 4, wherein
the first transistor included in the first sharing pixel unit is arranged at a position overlapping, when seen in a plan view as seen in a thickness direction of the semiconductor layer, one pixel of the multiple pixels included in the first sharing pixel unit, and
the second transistor included in the first sharing pixel unit is arranged at a position overlapping, when seen in the plan view, one pixel of the multiple pixels included in the second sharing pixel unit.

6. The image-capturing apparatus according to claim 4, wherein,
assuming that the integrated gate electrodes of the first transistor and the second transistor in the first sharing pixel unit are a first gate electrode and that the integrated gate electrodes of the first transistor and the second transistor in the second sharing pixel unit are a second gate electrode,
the first gate electrode and the second gate electrode are adjacent to each other with the inter-pixel separating section being interposed therebetween,
the first sharing pixel unit has a first via provided on the first gate electrode and connected to the first gate electrode,
the second sharing pixel unit has a second via provided on the second gate electrode and connected to the second gate electrode, and
a direction of a shortest distance between the first via and the second via crosses a direction of a shortest distance between the first gate electrode and the second gate electrode.

7. The image-capturing apparatus according to claim 1, wherein
each of the multiple pixels has
a photoelectric converting section,
a floating diffusion, and
a transfer transistor that transfers a charge generated by the photoelectric converting section to the floating diffusion, and
the first transistor and the second transistor are amplification transistors that amplify a signal at a level according to a charge stored in the floating diffusion.

8. The image-capturing apparatus according to claim 1, wherein
the inter-pixel separating section includes a trench isolation.

9. The image-capturing apparatus according to claim 1, wherein
the first transistor and the second transistor are FinFETs.
